(19) United States
(12) Patent Application Publication
(10) Pub. No.: US 2025/0101300 A1
(43) Pub. Date: Mar. 27, 2025

(54) QUANTUM DOT, METHOD OF PREPARING THE SAME, LIGHT-EMITTING DEVICE INCLUDING THE QUANTUM DOT, ELECTRONIC APPARATUS INCLUDING THE LIGHT-EMITTING DEVICE, AND ELECTRONIC EQUIPMENT INCLUDING THE ELECTRONIC APPARATUS

(71) Applicant: Samsung Display Co., Ltd., Yongin-si (KR)

(72) Inventors: Bitna Yoon, Yongin-si (KR); Sungjae Kim, Yongin-si (KR); Youngsik Kim, Yongin-si (KR); Hongrae Kim, Yongin-si (KR); Donghee Lee, Yongin-si (KR); Junehyuk Jung, Yongin-si (KR)

(73) Assignee: Samsung Display Co., Ltd., Yongin-si (KR)

(21) Appl. No.: 18/887,385

(22) Filed: Sep. 17, 2024

(30) Foreign Application Priority Data
Sep. 20, 2023 (KR) 10-2023-0125857
Jun. 10, 2024 (KR) 10-2024-0075284

(51) Int. Cl. C09K 11/64; C09K 11/58; C09K 11/62

(52) U.S. Cl. CPC C09K 11/641; C09K 11/582; C09K 11/621

(57) ABSTRACT

Provided is a quantum dot including a quaternary core including a first-first Group I element, a first-second Group III element, and a first-third Group VI element and not including Se, and a ternary shell surrounding at least a portion of the quaternary core.

### CROSS-REFERENCE TO RELATED APPLICATIONS

This application claims priority to and benefits of Korean Patent Application Nos. 10-2023-0125857, filed on Sep. 20, 2023, and 10-2024-0075284, filed on Jun. 10, 2024, under 35 U.S.C. § 119, in the Korean Intellectual Property Office (KIPO), the entire contents of which are incorporated herein by reference.

### BACKGROUND

### 1. Technical Field

Embodiments relate to a quantum dot, a method of preparing the same, a light-emitting device including the quantum dot, an electronic apparatus including the light-emitting device, and electronic equipment including the electronic apparatus.

### 2. Description of the Related Art

Quantum dots may be used as materials that perform various optical functions (e.g., a light conversion function, a light emission function, etc.) in electronic apparatuses. Depending on the size and/or composition of the quantum dots, the quantum dots may have different energy band gaps and emit light of different wavelengths. Regarding quantum dots that have a specific energy band gap and emit light of a specific wavelength, there is a need to adjust the size and/or composition of the quantum dots so that the quantum dots have high color purity, high efficiency, and high stability.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a quantum dot having an excellent blue light absorption rate, a narrow emission full width at half maximum (FWHM), an improved photoluminescence quantum yield (PLQY), a long decay time, and high stability, a method of preparing the quantum dot, an electronic apparatus including the quantum dot and having excellent display quality, and high-quality electronic equipment including the electronic apparatus.

Additional aspects will be set forth in part in the description which follows and, in part, will be apparent from the description, or may be learned by practice of the embodiments of the disclosure.

According to an embodiment, a quantum dot may include a quaternary core including a first-first Group I element, a first-second Group II element, and a first-third Group VI element and not including Se, and a ternary shell surrounding at least a portion of the quaternary core.

In an embodiment, the quaternary core may further include a first-fourth Group II element, and the first-second Group II element and the first-fourth Group II element in the quaternary core may be different from each other.

In an embodiment, the quaternary core may not include Ag.

In an embodiment, the ternary shell may include a second-first Group I element, a second-second Group II element, and a second-third Group VI element.

In an embodiment, the first-first Group I element of the quaternary core and the second-first Group I element of the ternary shell may be identical to each other.

In an embodiment, the first-second Group III element of the quaternary core and the second-second Group II element of the ternary shell may be different from each other.

In an embodiment, the ternary shell may include Al.

In an embodiment, the quantum dot may absorb blue light and emit light having a wavelength in a range of about 520 nm to about 750 nm.

In an embodiment, the quantum dot may further include a surface layer surrounding at least a portion of the ternary shell.

In an embodiment, the surface layer may be a binary layer including a third-first Group II element and a third-second Group VI element.

In an embodiment, the surface layer may include an oxide of a third-first Group II element.

In an embodiment, a sum of a thickness of the ternary shell and a thickness of the surface layer may be in a range of about 0.1 nm to about 4.0 nm.

In an embodiment, the second-second Group III element in the ternary shell and the third-first Group II element in the surface layer may be identical to each other.

In an embodiment, a value obtained by dividing a sum of a number of moles of the second-second Group II element included in the ternary shell and a number of moles of the third-first Group II element included in the surface layer by a number of moles of the first-second Group II element included in the quaternary core may be in a range of about 0.05 to about 8.0.

According to an embodiment, a method of preparing a quantum dot may include mixing a first-first precursor including a first-first Group I element, a first-second precursor including a first-second Group II element, a first-third precursor including a first-third Group VI element, and a first solvent to obtain a mixture, heating the mixture to a first temperature to obtain a quaternary core, mixing the quaternary core with a second-first precursor including a second-first Group I element, a second-second precursor including a second-second Group II element, a second-third precursor including a second-third Group VI element, and a second solvent, and heating the quaternary core and a shell surrounding at least a portion of the quaternary core to a second temperature to obtain a ternary shell. The first-second Group III element included in the first-second precursor may not include Se.

In an embodiment, the method may further include exposing the ternary shell to air.

In an embodiment, a number of moles of the second-second precursor may be in a range of about 0.1 mmol to about 5.0 mmol.

According to an embodiment, a light-emitting device may include a first electrode, a second electrode facing the first electrode, an interlayer arranged between the first electrode and the second electrode and including an emission layer, and the quantum dot.

According to an embodiment, an electronic apparatus may include the light-emitting device, and a thin-film transistor electrically connected to the light-emitting device.

According to an embodiment, electronic equipment may include the electronic apparatus. The electronic equipment may be one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, and a signboard.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a light-emitting device according to an embodiment;

FIG. 2 is a schematic cross-sectional view of an electronic apparatus according to an embodiment;

FIG. 3 is a schematic cross-sectional view of an electronic apparatus according to another embodiment;

FIG. 4 is a schematic perspective view of electronic equipment including a light-emitting device according to an embodiment;

FIG. 5 is a schematic perspective view of an exterior of a vehicle as electronic equipment including a light-emitting device according to an embodiment;

FIGS. 6A to 6C are each a schematic diagram of an interior of a vehicle of FIG. 5;

FIG. 7 is a graph showing results according to Evaluation Example 1-2;

FIG. 8A is a graph showing results according to Evaluation Example 3-2 based on a photoluminescence (PL) spectrum for Example 6; and

FIG. 8B is a graph showing results according to Evaluation Example 3-2 based on a PL spectrum for Comparative Example 3.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

In the specification, the x-axis, y-axis, and z-axis are not limited to three axes in an orthogonal coordinate system, and may be interpreted in a broad sense including these axes. For example, the x-axis, y-axis, and z-axis may refer to axes which are orthogonal to each other, or may refer to axes which are in different directions that are not orthogonal to each other.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, 10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The term “Group I element” may be an element of Group 11 of the Periodic Table of Elements, and examples thereof may include copper (Cu), silver (Ag), gold (Au), or any combination thereof.

The term “Group II element” may be an element of Group 2 or Group 12 of the Periodic Table of Elements, and examples thereof may include magnesium (Mg), calcium (Ca), zinc (Zn), cadmium (Cd), mercury (Hg), or any combination thereof.

The term “Group III element” may be an element of Group 13 of the Periodic Table of Elements, and examples thereof may include aluminum (AI), gallium (Ga), indium (In), thallium (TI), or any combination thereof.

The term “Group IV element” may be an element of Group 14 of the Periodic Table of Elements, and examples thereof may include silicon (Si), germanium (Ge), tin (Sn), lead (Pb), or any combination thereof.

The term “Group V element” may be an element of Group 15 of the Periodic Table of Elements, and examples thereof may include nitrogen (N), phosphorus (P), arsenic (As), antimony (Sb), or any combination thereof.

The term “Group VI element” may be an element of Group 16 of the Periodic Table of Elements, and examples thereof may include oxygen (O), sulfur (S), selenium (Se), tellurium (Te), or any combination thereof.

The term “Group I-III-VI element” may be a combination of at least one Group I element, at least one Group III element, and at least one Group VI element, and an example thereof may be a combination of Cu as a Group I element, In and Ga as Group II elements, and S as a Group VI element.

The term “binary” may include two different types of elements.

The term “ternary” may include three different types of elements.

The term “quaternary” may include four different types of elements.

### [Quantum Dot]

According to an embodiment, a quantum dot may include a quaternary core including a first-first Group I element, a first-second Group II element, and a first-third Group VI element and not including Se, and a ternary shell surrounding at least a portion of the quaternary core. For example, the first-third Group VI element included in the quaternary core may not be Se. The ternary shell may entirely surround the quaternary core. By including the Group I-III-VI element, the quantum dot may have a high absorption rate of blue light. The quantum dot may be clearly different from a quantum dot including a core including a Group II-VI element, a core including a Group II-V element, a core including a Group II-VI element, or a core including a Group IV-VI element. The quantum dot may be clearly different from a quantum dot including a binary core, such as InP, or a ternary core, such as CulnS₂.

In an embodiment, the quantum dot may further include a surface layer surrounding at least a portion of the ternary shell. The surface layer may entirely surround the ternary shell.

A diameter of the quaternary core may be in a range of about 2 nm to about 10 nm. For example, the diameter of the quaternary core may be about 4 nm. A thickness of the ternary shell and a thickness of the surface layer may each be in a range of about 0.1 nm to about 4.0 nm. A quantum dot including the quaternary core and the ternary shell, and a quantum dot including the quaternary core, the ternary shell, and the surface layer may each have a diameter in a range of about 4 nm to about 15 nm. For example, a quantum dot including the quaternary core and the ternary shell, and a quantum dot including the quaternary core, the ternary shell, and the surface layer may each have a diameter in a range of about 6 nm to about 8 nm.

The quantum dot may have a chalcopyrite crystal structure.

In an embodiment, the quaternary core may include a first-fourth Group II element different from the first-second Group II element. Since the core is a quaternary core, the quaternary core may include one type of Group I element, two types of Group II elements, and one type of Group VI element. At least one of the Group III elements included in the quaternary core may be Ga. At least one of the Group III elements included in the quaternary core may be In.

In an embodiment, the quaternary core may not include Ag nor Au. For example, the first-first Group I element included in the quaternary core may not be Ag nor Au. For example, the first-first Group I element included in the quaternary core may be Cu.

The quaternary core may not include Al nor TI as a Group III element. For example, the first-second Group III element included in the quaternary core may not be Al nor TI. The quaternary core may include In as the first-second Group III element. The quaternary core may include Ga as the first-second Group III element. The core may include both In and Ga as Group III elements (the first-second Group III element and the first-fourth Group II element).

The quaternary core may not include O, Se, nor Te as a Group VI element. For example, the first-third Group VI element included in the quaternary core may not be O, Se, nor Te. For example, the first-third Group VI element included in the quaternary core may be S.

A value obtained by dividing a number of moles of the first-second Group III element included in the quaternary core by a number of moles of the first-first Group I element included in the core may be in a range of about 1 to about 10. For example, a value obtained by dividing the number of moles of the first-second Group II element included in the quaternary core by the number of moles of the first-first Group I element included in the quaternary core may be in a range of about 1 to about 5. For example, in case that the quaternary core includes X_{III} and Y_{III} as different Group II elements (the first-second Group II element and the first-fourth Group II element) and Z_{I} as the first-first Group I element, a value obtained by dividing a number of moles of X_{III} by a number of moles of Z_{I} may be in a range of about 1 to about 10. For example, a value obtained by dividing the number of moles of X_{III} by the number of moles of Z_{I} may be in a range of about 1 to about 5. A value obtained by dividing a number of moles of Y_{III} by a number of moles of Z_{I} may be in a range of about 1 to about 10. For example, a value obtained by dividing the number of moles of Y_{III} by the number of moles of Z_{I} may be in a range of about 1 to about 5. A value obtained by dividing a number of moles of X_{III} by a number of moles of Y_{III} may be in a range of about 0.05 to about 20. For example, a value obtained by dividing the number of moles of X_{III} by the number of moles of Y_{III} may be in a range of about 0.1 to about 10. For example, a value obtained by dividing the number of moles of X_{III} by the number of moles of Y_{III} may be in a range of about 0.8 to about 1.2. For example, the quaternary core may satisfy Equations 1-1 to 1-3:

$$1 \leq {X}_{III} / {Z}_{I} \leq 10 \qquad [ Equation 1 - 1 ]$$

$$1 \leq {Y}_{III} / {Z}_{I} \leq 10 \qquad [ Equation 1 - 2 ]$$

$$0.05 \leq {X}_{III} / {Y}_{III} \leq 20 \qquad [ Equation 1 - 3 ]$$

In Equations 1-1 to 1-3,

X_{III} may be a number of moles of one of the Group II elements (e.g. the first-second Group II element) included in the core,

Y_{III} may be different from X_{III} and may be a number of moles of another one of the Group II elements (e.g. the first-fourth Group II element) included in the core, and

Z_{I} may be a number of moles of the first-first Group I element included in the core.

In an embodiment, the ternary shell may include a second-first Group I element, a second-second Group II element, and a second-third Group VI element. Since the shell is a ternary shell, the shell may include one type of Group I element, one type of Group II element, and one type of Group VI element.

In an embodiment, the first-first Group I element of the quaternary core and the second-first Group I element of the ternary shell may be identical to each other. For example, the quantum dot may be different from a quantum dot including a core including Ag as a Group I element and a shell including Cu as a Group I element. For example, each of the core and the shell may include Cu.

In an embodiment, the first-second Group III element of the quaternary core and the second-second Group II element of the ternary shell may be different from each other. Both of the two types of Group III elements (i.e. the first-second Group II element and the first-fourth Group II element) included in the quaternary core may be different from the type of the second-second Group II element included in the ternary shell. For example, the quantum dot may be different from a quantum dot including a core including Ga as a Group II element and a shell including Ga as a Group III element.

In an embodiment, the ternary shell may include Al. For example, the quantum dot may be different from a quantum dot including a shell including Ga as a Group III element.

In an embodiment, the surface layer may be a binary layer including a third-first Group II element and a third-second Group VI element. For example, the surface layer may include one type of Group II element and one type of Group VI element. The third-first Group III element of the surface layer may be different from the first-second Group II element of the quaternary core. The third-first Group III element included in the ternary surface layer may be different from both of the two types of Group III elements (i.e. the first-second Group III element and the first-fourth Group III element) included in the quaternary core.

In an embodiment, a sum of a thickness of the ternary shell and a thickness of the surface layer may be in a range of about 0.1 nm to about 4.0 nm. For example, the quantum dot may satisfy Equation 2:

$$0.1 nm \leq {T}_{S} + {T}_{L} \leq 4. nm \qquad [ Equation 2 ]$$

In Equation 2, T_{S} may be a thickness of the ternary shell, and T_{L} may be a thickness of the surface layer. For example, the sum of the thickness of the ternary shell and the thickness of the surface layer may be in a range of about 0.2 nm to about 3.5 nm. For example, the sum of the thickness of the ternary shell and the thickness of the surface layer may be in a range of about 0.3 nm to about 2.8 nm.

In an embodiment, the ternary shell may include the second-second Group III element identical to the third-first Group III element included in the surface layer. For example, the quantum dot may be different from a quantum dot including a shell including Ga as a Group II element and a surface layer including Al as a Group II element. For example, each of the ternary shell and the surface layer may include Al as a Group III element.

The surface layer may not include S, Se, nor Te as a Group VI element.

In an embodiment, the surface layer may include an oxide of the third-first Group II element. For example, the surface layer may include O as the third-second Group VI element.

In an embodiment, a value obtained by dividing a sum of a number of moles of the second-second Group II element included in the ternary shell and a number of moles of the third-first Group II element included in the surface layer by a number of moles of the first-second Group II element included in the quaternary core may be in a range of about 0.05 to about 8.0. For example, the quantum dot may satisfy Equation 3:

$$0.05 \leq ( {A}_{III} + {B}_{III} ) / {X}_{III} \leq 8.0 \qquad [ Equation 3 ]$$

In Equation 3, A_{III} may be a number of moles of the second-second Group III element included in the ternary shell, B_{III} may be a number of moles of the third-first Group II element included in the surface layer, and X_{III} may be a number of moles of the first-second Group II element included in the quaternary core.

In case that the quaternary core includes two different types of Group II elements (i.e. the first-second Group II element and the first-fourth Group II element), Equation 3 may be expressed as Equation 3-1:

$$0.05 \leq [ ( {A}_{III} + {B}_{III} ) / ( {X}_{III} + {Y}_{III} ) ] \leq 8.0 \qquad [ Equation 3 - 1 ]$$

In Equation 3-1, A_{III} may be a number of moles of the second-second Group III element included in the ternary shell, B_{III} may be a number of moles of the third-first Group II element included in the surface layer, X_{III} may be a number of moles of one of the Group II elements (e.g. the first-second Group II element) included in the quaternary core, and Y_{III} may be a number of moles of another one of the Group II elements (e.g. the first-fourth Group II element) included in the quaternary core.

For example, a value obtained by dividing a sum of the number of moles of the second-second Group II element included in the ternary shell and a number of moles of the third-first Group II element included in the surface layer by a number of moles of a Group II element included in the quaternary core may be in a range of about 0.07 to about 7.0. For example, the value obtained by dividing the sum of the number of moles of the second-second Group II element included in the ternary shell and the number of moles of the third-first Group II element included in the surface layer by the number of moles of a Group II element included in the quaternary core may be in a range of about 0.08 to about 6.5. For example, the value obtained by dividing the sum of the number of moles of the second-second Group II element included in the ternary shell and the number of moles of the third-first Group II element included in the surface layer by the number of moles of a Group II element included in the quaternary core may be in a range of about 0.09 to about 6.4.

In an embodiment, the quantum dot may absorb blue light and emit light having a wavelength in a range of about 520 nm to about 750 nm. For example, the quantum dot may absorb blue light to emit light having a wavelength in a range of about 520 nm to about 700 nm, about 520 nm to about 650 nm, about 520 nm to about 630 nm, about 550 nm to about 750 nm, about 550 nm to about 700 nm, about 550 nm to about 650 nm, or about 550 nm to about 630 nm. For example, the quantum dot may emit light having a maximum emission wavelength in a range of about 550 nm to about 700 nm. For example, the quantum dot may emit light having a maximum emission wavelength in a range of about 600 nm to about 650 nm. The maximum emission wavelength may be measured according to Evaluation Example 1-1 or 3-1 to be described below. The blue light may have a wavelength in a range of about 450 nm to about 460 nm.

The quantum dot may have an emission full width at half maximum (FWHM) of less than or equal to about 95 nm. For example, the quantum dot may have an emission FWHM of less than or equal to about 90 nm, less than or equal to about 80 nm, less than or equal to about 70 nm, less than or equal to about 69 nm, less than or equal to about 68 nm, less than or equal to about 67 nm, less than or equal to about 66 nm, or less than or equal to about 65 nm. The emission FWHM may be measured according to Evaluation Example 1-1 or 3-1 to be described below.

The quantum dot may have a photoluminescence quantum yield (PLQY) of greater than or equal to about 50%. For example, the quantum dot may have a PLQY of greater than or equal to about 55%, greater than or equal to about 60%, greater than or equal to about 65%, greater than or equal to about 70%, greater than or equal to about 75%, greater than or equal to about 76%, greater than or equal to about 77%, greater than or equal to about 78%, greater than or equal to about 79%, or greater than or equal to about 80%. The PLQY may be measured according to Evaluation Example 1-1 or 3-1 to be described below.

The quantum dot may have a decay time of longer than or equal to about 60 ns. For example, the quantum dot may have a decay time of longer than or equal to about 70 ns, longer than or equal to about 80 ns, longer than or equal to about 90 ns, longer than or equal to about 100 ns, longer than or equal to about 110 ns, longer than or equal to about 120 ns, longer than or equal to about 130 ns, longer than or equal to about 140 ns, or longer than or equal to about 150 ns. The decay time may be an average decay time calculated based on three or more decay times. The decay time may be measured according to Evaluation Example 3-2 to be described below.

The quaternary core may include CulnGaS, the ternary shell may include CuAlS₂, and the surface layer may include AIOₓ. By including the quaternary core described above, the quantum dot may have a high absorption rate of blue light. The combination of the quaternary core and the ternary shell described above may have a relatively small lattice mismatch, and thus, defects on a surface of the quantum dot may be reduced. As a result, the quantum dot may have a relatively high PLQY of greater than or equal to about 75%, and may simultaneously have a relatively small emission FWHM of less than or equal to about 70 nm and a relatively long decay time of longer than or equal to about 100 ns. By further including the surface layer in the combination of the core and shell, the quantum dot may have a high PLQY retention rate over time, thereby having high stability.

### [Method of Preparing Quantum Dot]

Another aspect provides a method of preparing a quantum dot, the method including: mixing a first-first precursor including a first-first Group I element, a first-second precursor including a first-second Group II element, a first-third precursor including a first-third Group VI element, and a first solvent; heating the mixture to a first temperature to obtain a quaternary core to obtain a mixture; mixing the core with a second-first precursor including a second-first Group I element, a second-second precursor including a second-second Group III element, a second-third precursor including a second-third Group VI element, and a second solvent; and heating the core and a shell surrounding at least a portion of the core to a second temperature to obtain a ternary shell, wherein the first-second Group II element included in the first-second precursor may not include Se.

In an embodiment, the method may further include exposing the shell to air. For example, the exposing of the shell to the air may be performed after the obtaining of the ternary shell. By exposing the shell to the air, a surface layer surrounding at least a portion of the shell may be formed.

The first-first Group I element included in the first-first precursor may not be Ag nor Au. The first-first precursor may not include Ag nor Au. The first-first Group I element included in the first-first precursor may be Cu. The first-first precursor may further include a halogen, such as —F, —Cl, —Br, or —I. For example, the first-first precursor may be CuF, CuCl, CuBr, or Cul.

In an embodiment, two types of precursors each including a Group II element may be used in the mixture in the heating of the mixture to obtain the core. For example, the mixture may further include a first-fourth precursor including a first-fourth Group II element, in addition to the first-second precursor including first-second Group III element. The first-second Group III element included in the first-second precursor and the first-fourth Group III element included in the first-fourth precursor may be different from each other.

The first-second Group III element included in each of the first-second precursor and the first-fourth precursor may not be Al nor TI. Each of the first-second precursor and the first-fourth precursor may not include Al nor TI. The first-second Group III element included in each of the first-second precursor and the first-fourth precursor may be one of In and Ga.

For example, the first-second Group III element included in the first-second precursor may be In, and the first-fourth Group II element included in the first-fourth precursor may be Ga. In another embodiment, the first-second Group II element included in the first-second precursor may be Ga, and the first-fourth Group II element included in the first-fourth precursor may be In.

Each of the first-second precursor and the first-fourth precursor may further include a halogen, such as —F, —Cl, —Br, or —I. For example, the first-second precursor and the first-fourth precursor may each independently be GaF₃, GaCl₃, GaBr₃, Gal₃, InF₃, InCl₃, InBrs, or Inks.

The first-third Group VI element included in the first-third precursor may not be O, Se, nor Te. The first-third precursor may not include O, Se, nor Te. The first-third Group VI element included in the first-third precursor may be S. The first-third precursor may be sulfur-containing oleylamine (S-oleylamine), sulfur-containing octadecene (S-ODE), or bis(trimethylsilyl)sulfide.

The first solvent may be an insoluble solvent. The first solvent may include oleylamine and/or the like.

The mixture may include the first-fourth precursor, in addition to the first-first precursor to the first-third precursor and the first solvent, and may further include an additive. Examples of the additive may include trioctylphosphine, trioctylphosphine oxide, trioctylamine, octadecene, and the like.

The second-first Group I element included in the second-first precursor may not be Ag nor Au. The second-first precursor may not include Ag nor Au. The second-first Group I element included in the second-first precursor may be Cu. The second-first precursor may further include a halogen, such as —F, —Cl, —Br, or —I. For example, the second-first precursor may be CuF₃, CuCl₃, CuBr₃, or Cul₃.

The second-second Group III element included in the second-second precursor may not be Ga, In, nor TI. The second-second precursor may not include Ga, In, nor TI. The second-second Group III element included in the second-second precursor may be Al. The second-second precursor may further include a C₁-C₃₀ alkyl group bonded to the second-second Group III element. For example, the second-second precursor may be aluminum isopropoxide (AI(O—i—Pr)₃).

The second-third Group VI element included in the second-third precursor may not be O, Se, nor Te. The second-third precursor may not include O, Se, nor Te. The second-third Group VI element included in the second-third precursor may be S. The second-third precursor may be S-oleylamine.

The second solvent may be an insoluble solvent. The second solvent may be subjected to vacuum treatment at high temperature to substantially contain no moisture. The second solvent may include oleylamine and/or the like.

The first temperature may be in a range of about 200° C. to about 400° C. The second temperature may be in a range of about 200° C. to about 500° C. The second temperature may be equal to or higher than the first temperature.

In an embodiment, a number of moles of the first-first precursor may be in a range of about 0.008 mmol to about 20 mmol. A number of moles of the first-second precursor may be in a range of about 0.01 mmol to about 25 mmol. A number of moles of the first-fourth precursor may be in a range of about 0.008 mmol to about 20 mmol. A number of moles of the second-first precursor may be in a range of about 0.008 mmol to about 20 mmol.

Each of the first-third precursor and the second-third precursor may be a solution containing a Group VI element to increase the reactivity of the Group VI element. Each of the first-third precursor and the second-third precursor may be used at a concentration in a range of about 0.5 M to about 2 M and in an amount in a range of about 1 mL to about 4 mL.

In an embodiment, a number of moles of the second-second precursor may be in a range of about 0.1 mmol to about 5.0 mmol based on the total amount of the obtained core. In case that the amount of each of the first-first precursor, the first-second precursor, the first-third precursor, the second-first precursor, and the second-third precursor satisfies the range described above, the second-second precursor may be used with a number of moles in a range of about 0.1 mmol to about 5.0 mmol, and thus, the color purity, efficiency, stability, and decay time of the prepared quantum dot may be effectively improved.

### [Light-Emitting Device]

Another aspect provides a light-emitting device including: a first electrode; a second electrode facing the first electrode; an interlayer arranged between the first electrode and the second electrode and including an emission layer; and the quantum dot described above.

The light-emitting device may further include a capping layer arranged outside the first electrode and/or the second electrode. For example, the capping layer may be a first capping layer arranged outside the first electrode. In another embodiment, the capping layer may be a second capping layer arranged outside the second electrode. In another embodiment, the capping layer may include a first capping layer arranged outside the first electrode and a second capping layer arranged outside the second electrode. For example, the light-emitting device may have: a structure including a first capping layer, a first electrode, a hole transport region, an emission layer, an electron transport region, and a second electrode; a structure including a first electrode, a hole transport region, an emission layer, an electron transport region, a second electrode, and a second capping layer; or a structure including a first capping layer, a first electrode, a hole transport region, an emission layer, an electron transport region, a second electrode, and a second capping layer, wherein constituent layers of each structure are sequentially arranged.

In an embodiment, the interlayer may include the quantum dot. For example, the emission layer may include the quantum dot.

In an embodiment, the capping layer may include the quantum dot. For example, the first capping layer may include the quantum dot. In another embodiment, the second capping layer may include the quantum dot. In another embodiment, each of the first capping layer and the second capping layer may include the quantum dot.

In an embodiment, each of the emission layer and the capping layer may include the quantum dot.

### [Electronic Apparatus]

Another aspect provides an electronic apparatus including the light-emitting device described above and a thin-film transistor electrically connected to the light-emitting device.

The electronic apparatus may further include a color filter, a color conversion layer, a touch screen layer, a polarizing layer, or any combination thereof.

The color conversion layer may include the quantum dot.

### [Electronic Equipment]

Another aspect provides an electronic equipment including the electronic apparatus described above, wherein the electronic equipment may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

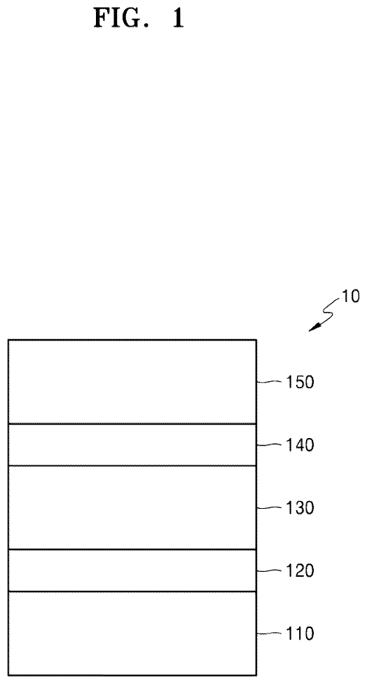

### [Description of FIG. 1]

FIG. 1 is a schematic cross-sectional view of a light-emitting device 10 according to an embodiment. The light-emitting device 10 may include a first electrode 110, an interlayer, and a second electrode 150. The interlayer may include a hole transport region 120, an emission layer 130, and an electron transport region 140.

Hereinafter, the structure of the light-emitting device 10 according to an embodiment and a method of manufacturing the light-emitting device 10 will be described with reference to FIG. 1.

[First electrode 110]

In FIG. 1, a substrate may be further included under the first electrode 110 or on the second electrode 150. In an embodiment, the substrate may be a glass substrate or a plastic substrate. The substrate may be a flexible substrate. For example, the substrate may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by depositing or sputtering a material for forming the first electrode 110 on the substrate. In case that the first electrode 110 is an anode, a high-work function material that facilitates injection of holes may be used as a material for forming the first electrode 110.

The first electrode 110 may be a reflective electrode, a transflective electrode, or a transmissive electrode. In case that the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In case that the first electrode 110 is a transflective electrode or a reflective electrode, a material for forming the first electrode 110 may include magnesium (Mg), silver (Ag), aluminum (AI), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. For example, the first electrode 110 may have a three-layer structure of ITO/Ag/ITO.

### [Interlayer]

The interlayer may be arranged on the first electrode 110. The interlayer may include the hole transport region 120, the emission layer 130, and the electron transport region 140.

The interlayer may include various organic materials, a metal-containing compound, such as an organometallic compound, an inorganic material, such the quantum dot described above, and the like.

In an embodiment, the interlayer may include two or more emitting units sequentially stacked between the first electrode 110 and the second electrode 150 and a charge generation layer arranged between the two or more emitting units. In case that the interlayer includes the emitting units and the charge generation layer as described above, the light-emitting device 10 may be a tandem light-emitting device.

[Hole transport region 120]

The hole transport region 120 may have a structure consisting of a layer consisting of a single material, a structure consisting of a layer including multiple materials, or a structure including multiple layers including multiple materials.

The hole transport region 120 may include a hole injection layer, a hole transport layer, an emission auxiliary layer, an electron blocking layer, or any combination thereof.

In an embodiment, the hole transport region 120 may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure may be stacked from the first electrode 110 in its respective stated order, but the structure of the hole transport region is not limited thereto.

The hole transport region 120 may include a compound represented by Formula 201, a compound represented by Formula 202, or any combination thereof:

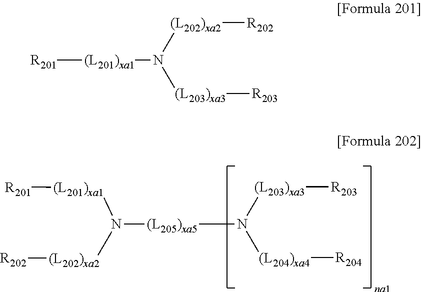

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, etc.) unsubstituted or substituted with at least one R₁₀ₐ (e.g., Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In an embodiment, the compound represented by Formula 201 and the compound represented by Formula 202 may each independently include at least one of groups represented by Formulae CY201 to CY217.

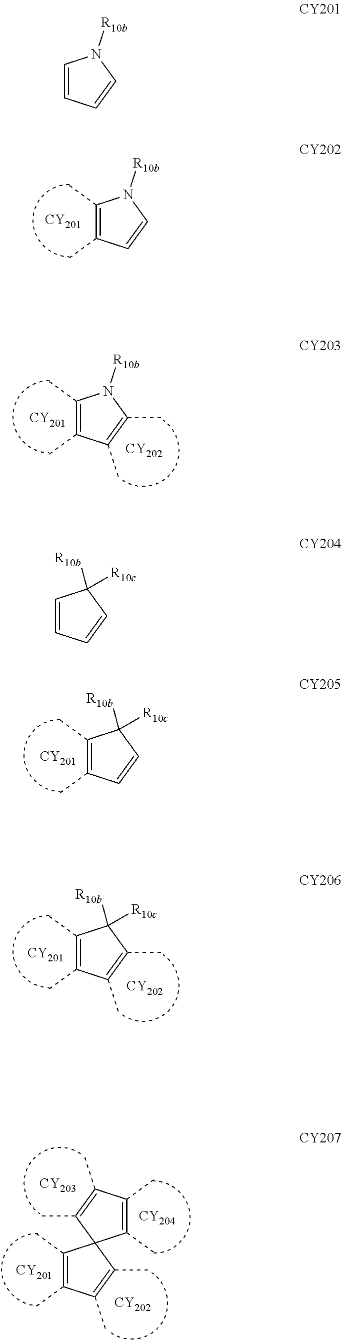

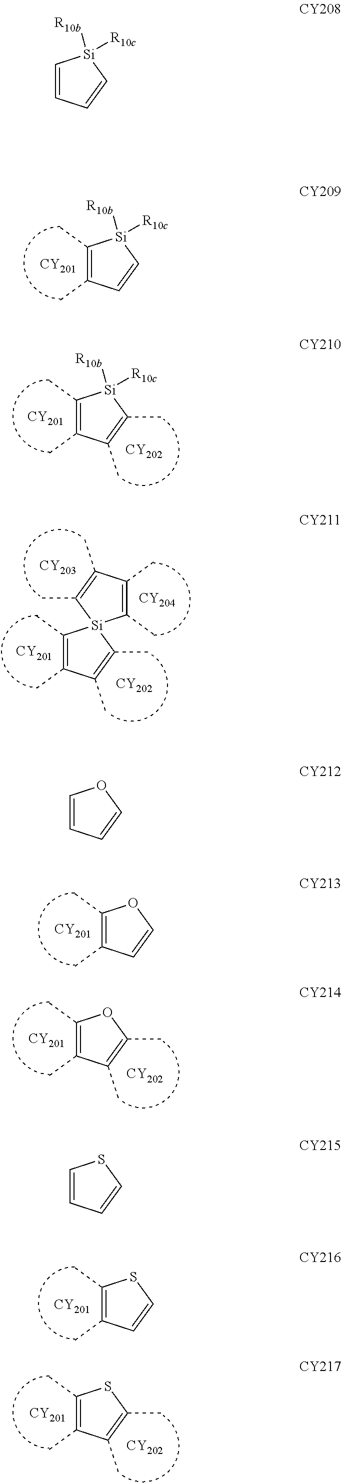

In Formulae CY201 to CY217, R_{10b} and R_{10c} may each independently be the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY₂₀₁ to ring CY₂₀₄ may each independently be a benzene group, a naphthalene group, a phenanthrene group, or an anthracene group.

In an embodiment, the compound represented by Formula 201 and the compound represented by Formula 202 may each independently include at least one of groups represented by Formulae CY201 to CY203.

In an embodiment, the compound represented by Formula 201 may include at least one of groups represented by Formulae CY201 to CY203 and at least one of groups represented by Formulae CY204 to CY217.

In an embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

In an embodiment, the compound represented by Formula 201 and the compound represented by Formula 202 may each not include groups represented by Formulae CY201 to CY203.

In an embodiment, the compound represented by Formula 201 and the compound represented by Formula 202 may each not include groups represented by Formulae CY201 to CY203, and may each independently include at least one of groups represented by Formulae CY204 to CY217.

In an embodiment, each of Formulae 201 and 202 may not include groups represented by Formulae CY201 to CY217.

In an embodiment, the hole transport region 120 may include one of Compounds HT1 to HT46, m-MTDATA, TDATA, 2-TNATA, NPB(NPD), β-NPB, TPD, spiro-TPD, spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof.

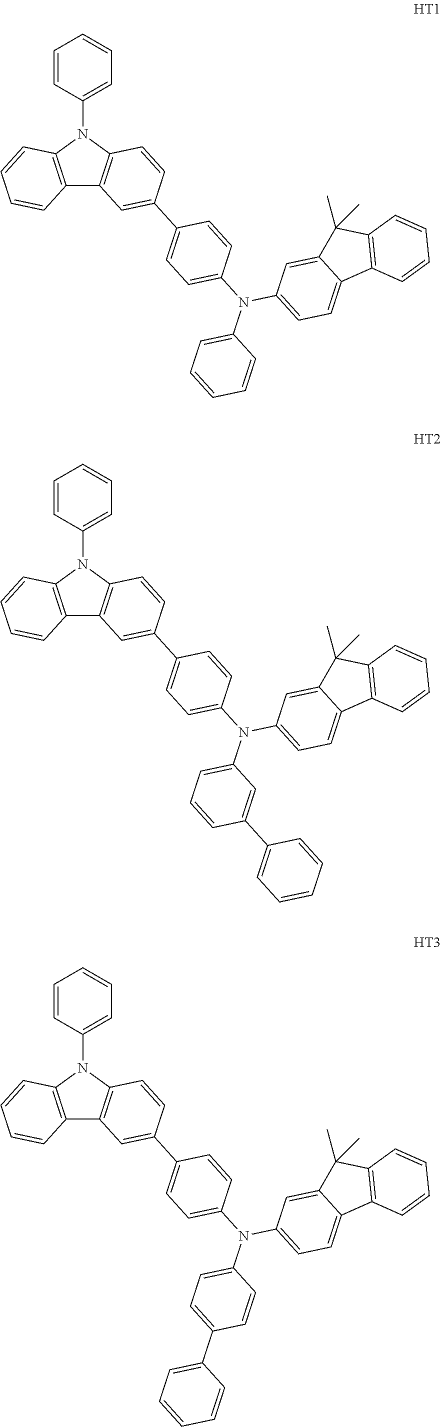 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

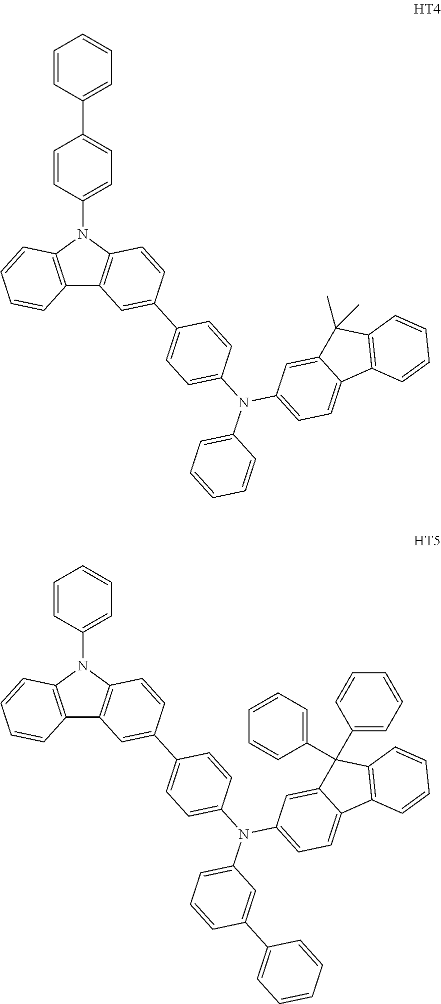 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2cccc(N(c3ccc(-c4ccc5c(c4)c4ccccc4n5-c4ccccc4)cc3)c3ccc4c(c3)C(c3ccccc3)(c3ccccc3)c3ccccc3-4)c2)cc1]

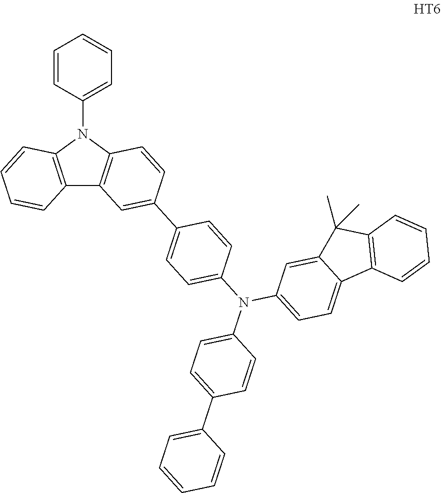 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

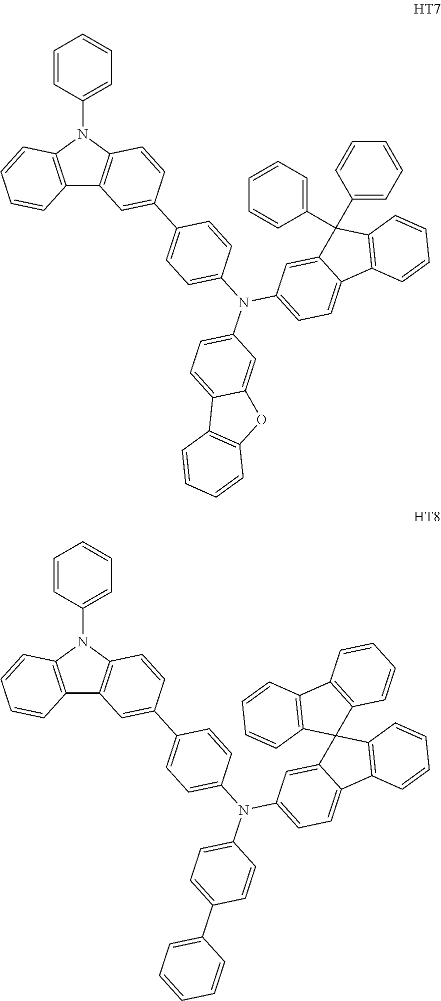 [SMILES: c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

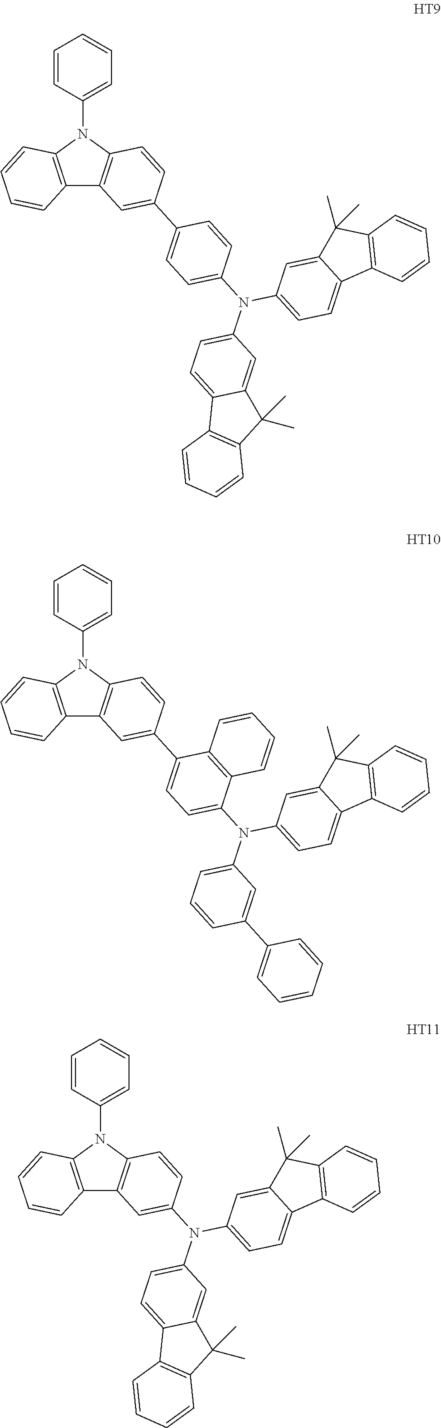 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

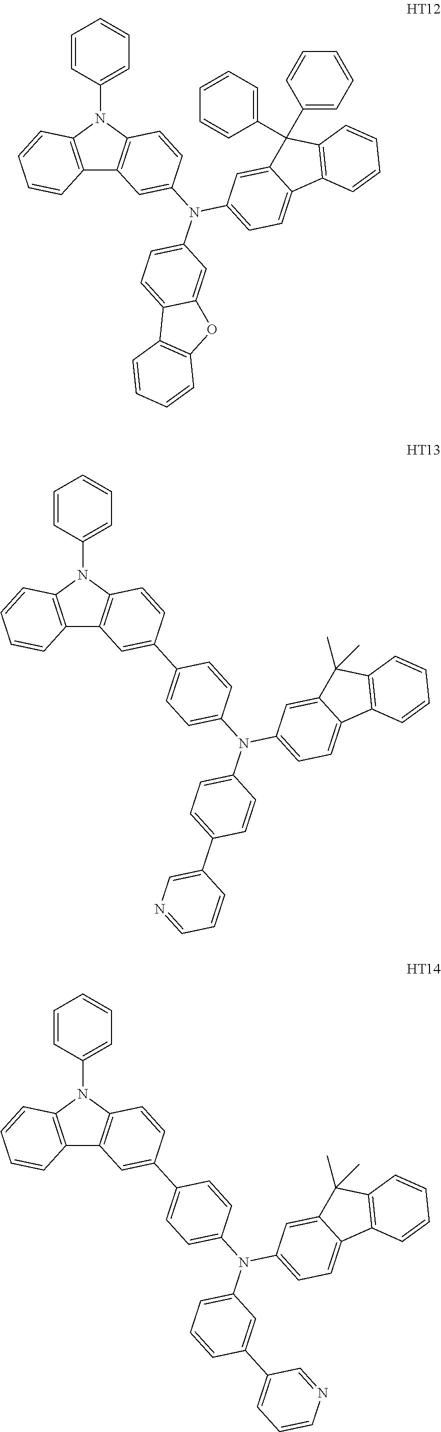 [SMILES: c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

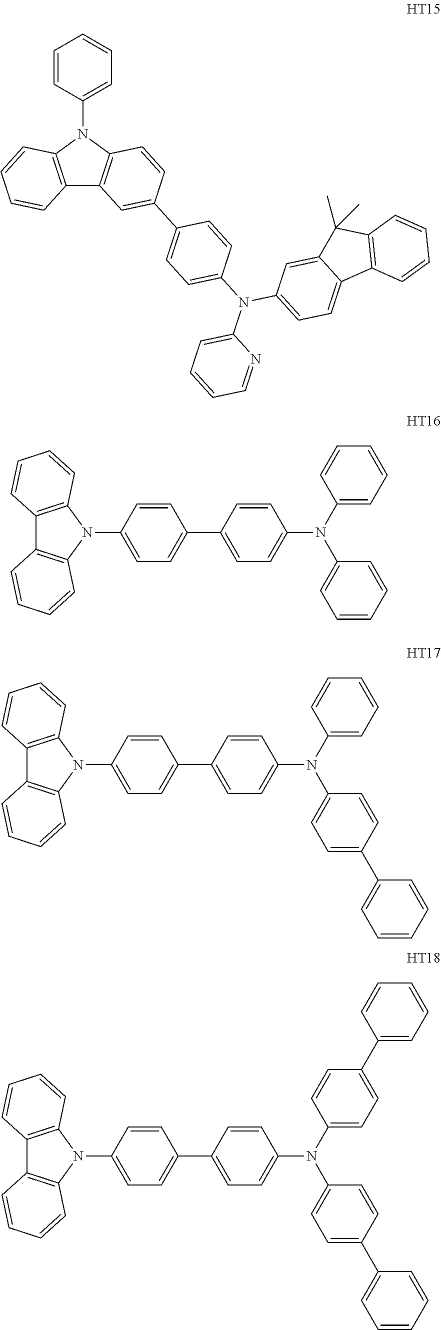

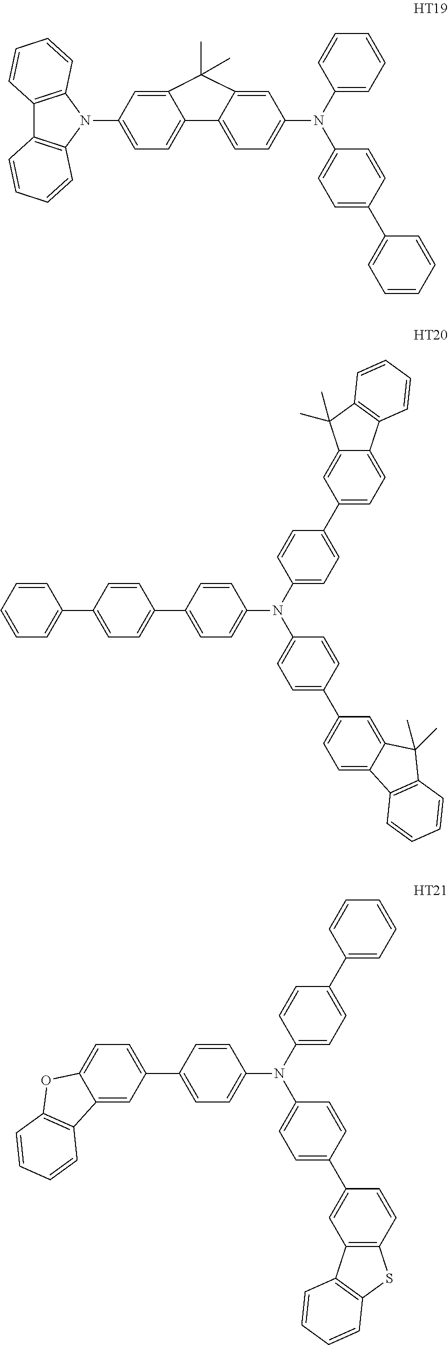 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1]

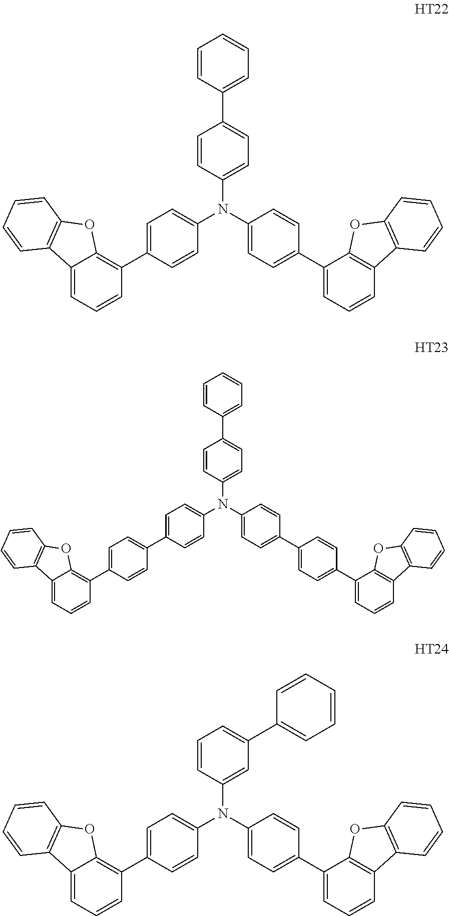 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1]

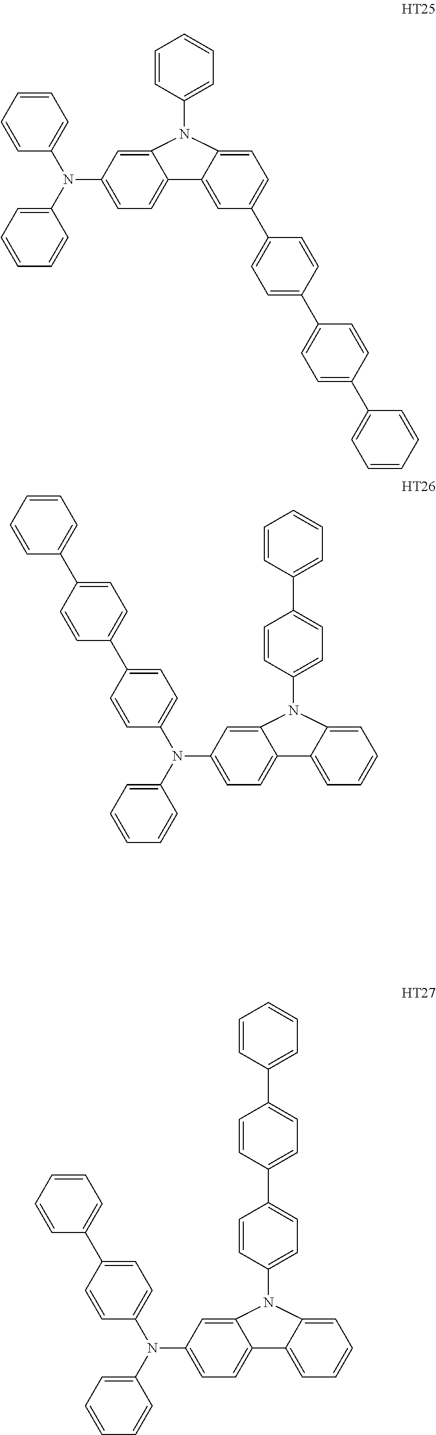 [SMILES: c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

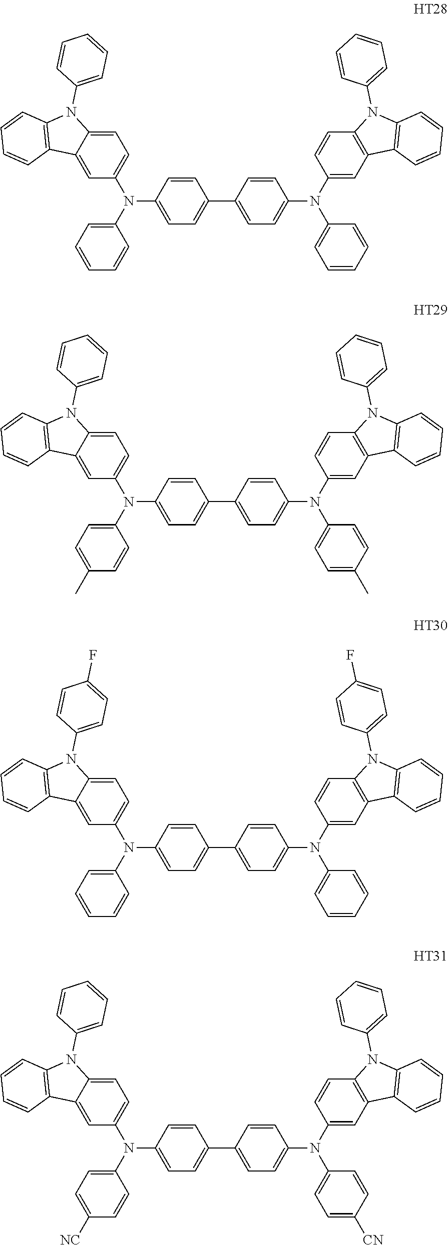 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

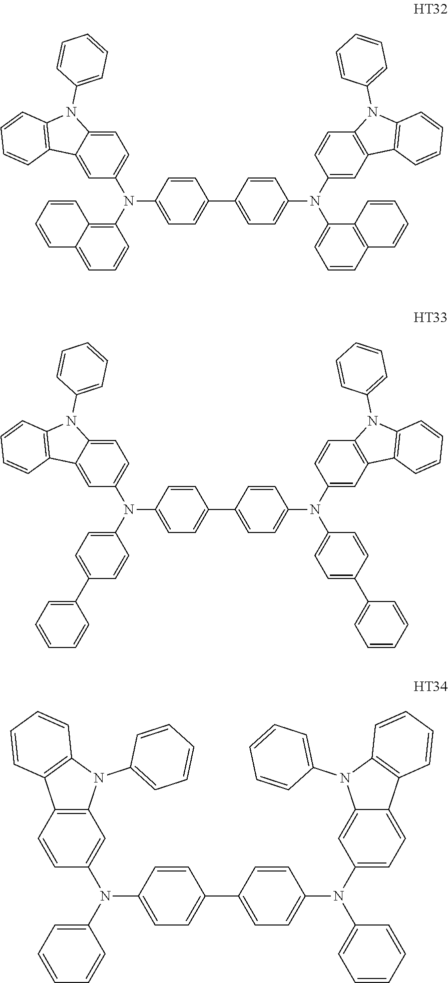 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1]

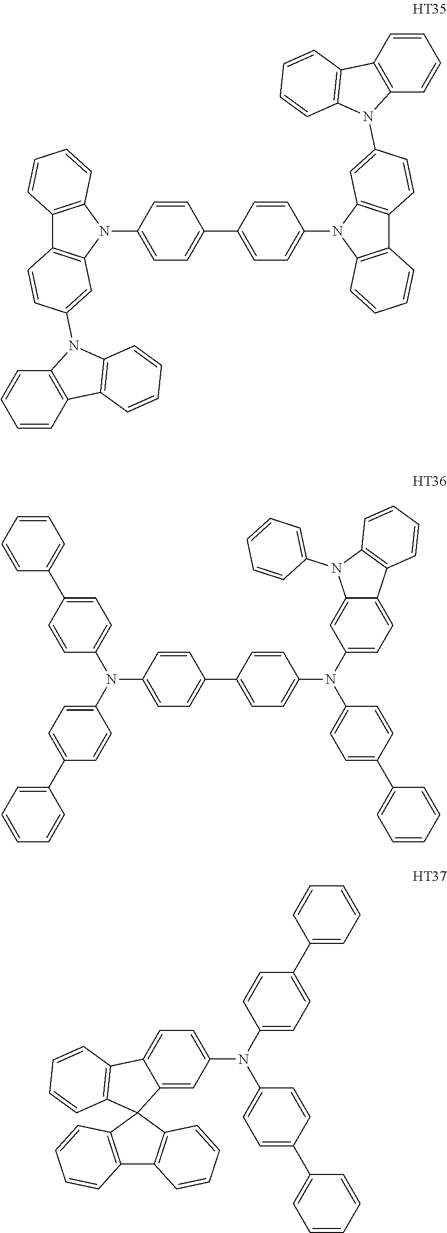 [SMILES: c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1 ; c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1]

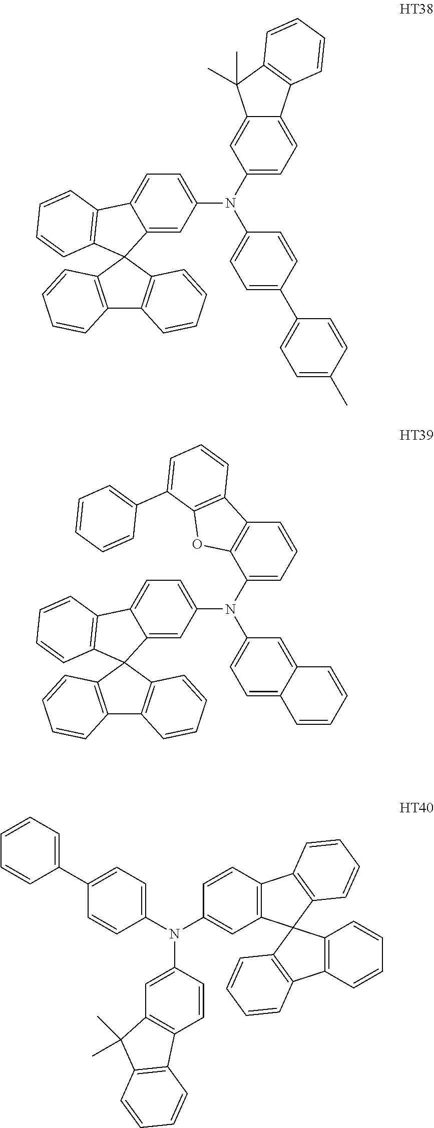 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc5c(c4)C4(c6ccccc6-c6ccccc64)c4ccccc4-5)c4ccc5ccccc5c4)cccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21]

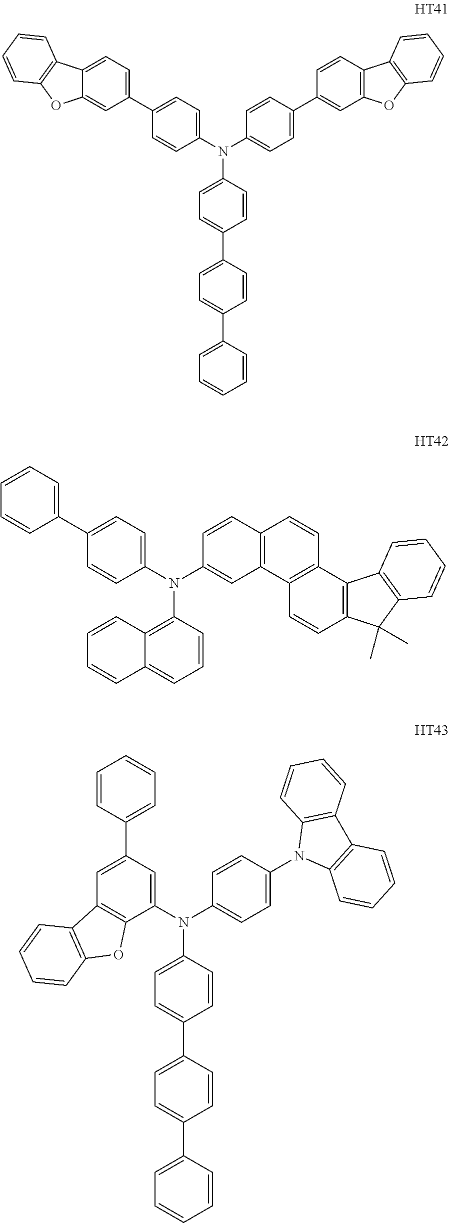 [SMILES: c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1 ; CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

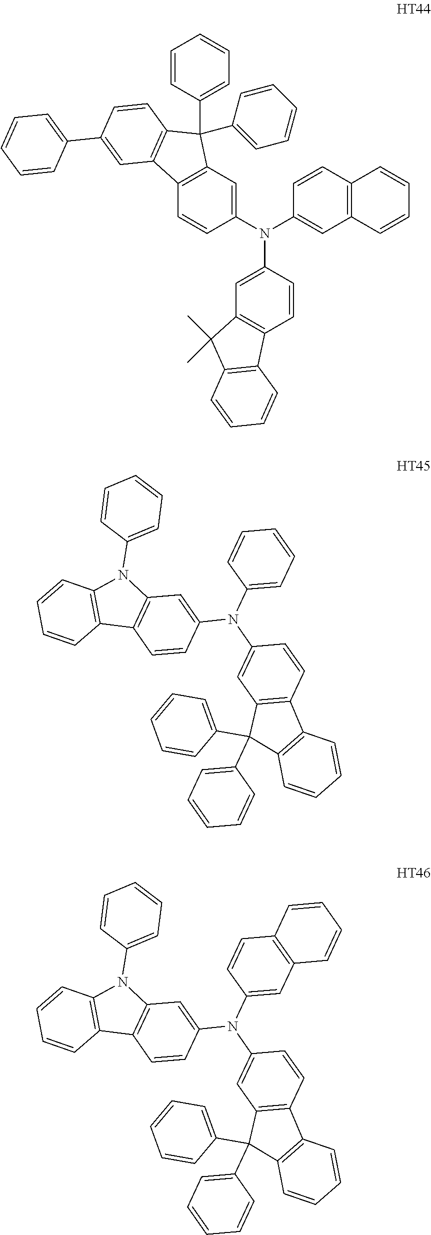 [SMILES: CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-n2c3ccccc3c3ccc(N(c4ccc5c(c4)C(c4ccccc4)(c4ccccc4)c4ccccc4-5)c4ccc5ccccc5c4)cc32)cc1]

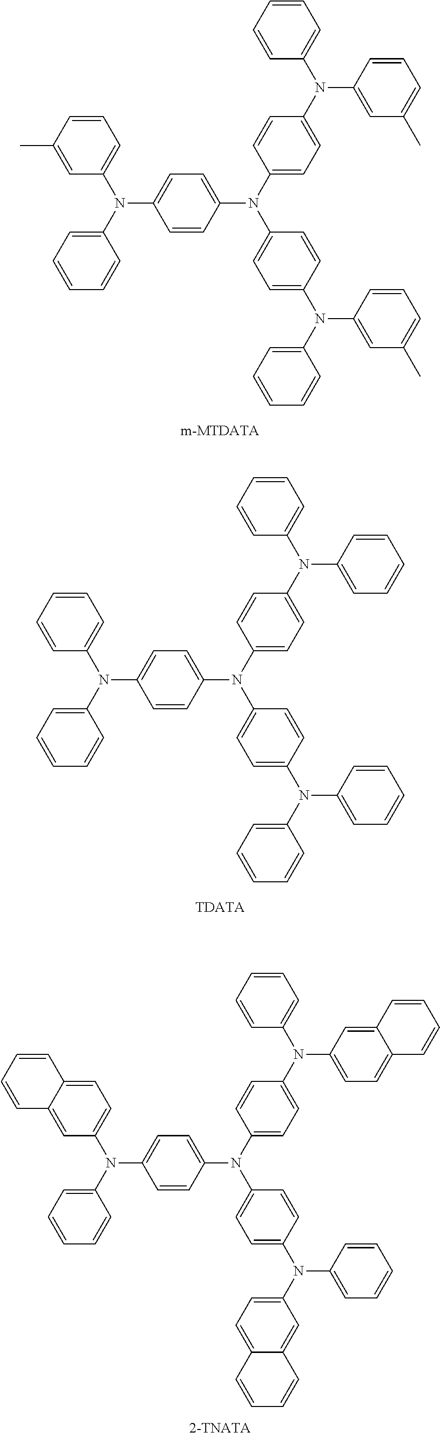

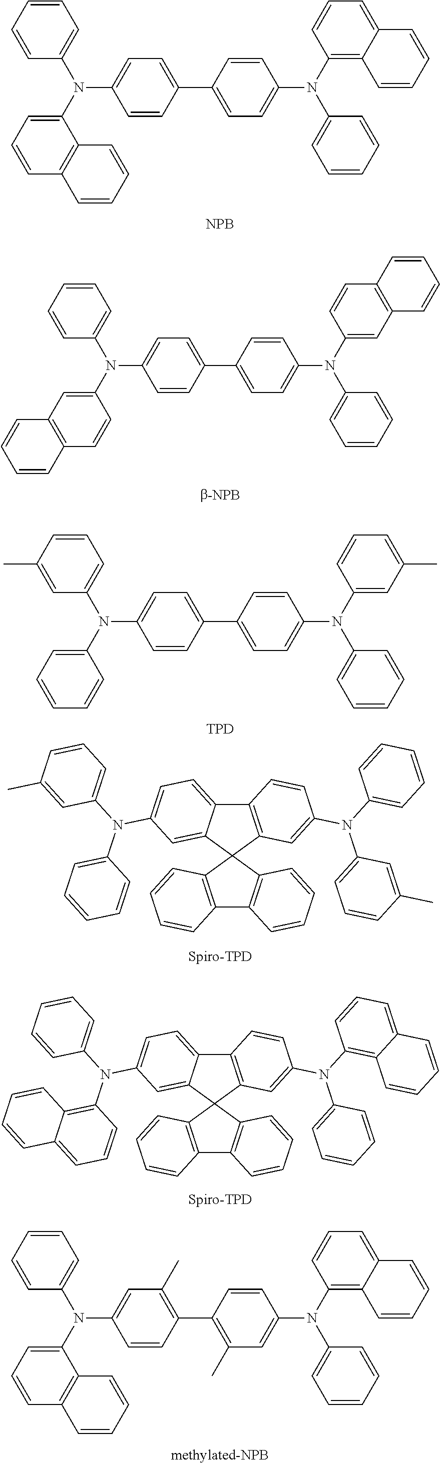

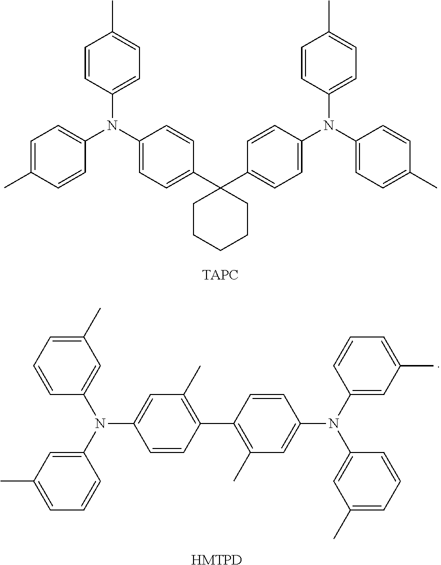

The thickness of the hole transport region 120 may be in a range of about 50 Å to about 10,000 Å. For example, the thickness of the hole transport region 120 may be in a range of about 100 Å to about 4,000 Å. In case that the hole transport region 120 includes a hole injection layer, a hole transport layer, or any combination thereof, the thickness of the hole injection layer may be in a range of about 100 Å to about 9,000 Å. For example, the thickness of the hole injection layer may be in a range of about 100 Å to about 1,000 Å. A thickness of the hole transport layer may be in a range of about 50 Å to about 2,000 Å. For example, the thickness of the hole transport layer may be in a range of about 100 Å to about 1,500 Å. In case that the thicknesses of the hole transport region 120, the hole injection layer, and the hole transport layer are within the ranges described above, satisfactory hole transporting characteristics may be obtained without a substantial increase in driving voltage.

The emission auxiliary layer may serve to increase light-emission efficiency by compensating for an optical resonance distance according to the wavelength of light emitted by the emission layer 130. The electron blocking layer may serve to prevent electron leakage from the emission layer 130 to the hole transport region 120. Materials that may be included in the hole transport region 120 may be included in the emission auxiliary layer and the electron blocking layer.

[p-Dopant]

The hole transport region 120 may include, in addition to the materials described above, a charge-generation material for the improvement of conductive properties. The charge-generation material may be uniformly or non-uniformly dispersed in the hole transport region 120 (e.g., in the form of a single layer consisting of a charge-generation material).

The charge-generation material may be, for example, a p-dopant.

In an embodiment, the p-dopant may have a lowest unoccupied molecular orbital (LUMO) energy level of less than or equal to about −3.5 eV.

In an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

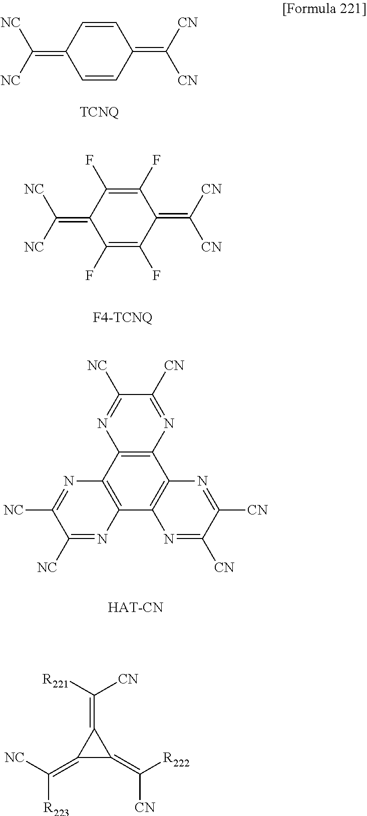

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (e.g., lithium (Li), sodium (Na), potassium (K), rubidium (Rb), cesium (Cs), etc.); an alkaline earth metal (e.g., beryllium (Be), magnesium (Mg), calcium (Ca), strontium (Sr), barium (Ba), etc.); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (e.g., zinc (Zn), indium (In), tin (Sn), etc.); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of a metalloid may include silicon (Si), antimony (Sb), tellurium (Te), and the like.

Examples of a non-metal may include oxygen (O), a halogen (e.g., F, Cl, Br, I, etc.), and the like.

Examples of a compound including element EL1 and element EL2 may include a metal oxide, a metal halide (e.g., a metal fluoride, a metal chloride, a metal bromide, a metal iodide, etc.), a metalloid halide (e.g., a metalloid fluoride, a metalloid chloride, a metalloid bromide, a metalloid iodide, etc.), a metal telluride, or any combination thereof.

Examples of a metal oxide may include a tungsten oxide (e.g., WO, W₂O₃, WO₂, WO₃, W₂O₅, etc.), a vanadium oxide (e.g., VO, V₂O₃, VO₂, V₂O₅, etc.), a molybdenum oxide (e.g., MoO, Mo₂O₃, MoO₂, MoO₃, Mo₂O₅, etc.), a rhenium oxide (e.g., ReO₃, etc.), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, Lil, Nal, KI, Rbl, Csl, and the like.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, Bel₂, Mgl₂, Cal₂, Srl₂, Bal₂, and the like.

Examples of a transition metal halide may include a titanium halide (e.g., TiF₄, TiCl₄, TiBr₄, Til₄, etc.), a zirconium halide (e.g., ZrF₄, ZrCl₄, ZrBr₄, Zrl₄, etc.), a hafnium halide (e.g., HfF₄, HfCl₄, HfBr₄, Hfl₄, etc.), a vanadium halide (e.g., VF₃, VCl₃, VBr₃, Vl₃, etc.), a niobium halide (e.g., NbF₃, NbCl₃, NbBr₃, Nbl₃, etc.), a tantalum halide (e.g., TaF₃, TaCl₃, TaBr₃, Tal₃, etc.), a chromium halide (e.g., CrF₃, CrO₃, CrBr₃, Crl₃, etc.), a molybdenum halide (e.g., MoF₃, MoCl₃, MoBr₃, Mol₃, etc.), a tungsten halide (e.g., WF₃, WCl₃, WBr₃, WI₃, etc.), a manganese halide (e.g., MnF₂, MnCl₂, MnBr₂, Mnl₂, etc.), a technetium halide (e.g., TcF₂, TcCl₂, TcBr₂, Tcl₂, etc.), a rhenium halide (e.g., ReF₂, ReCl₂, ReBr₂, Rel₂, etc.), an iron halide (e.g., FeF₂, FeCl₂, FeBr₂, Fel₂, etc.), a ruthenium halide (e.g., RuF₂, RuCl₂, RuBr₂, Rul₂, etc.), an osmium halide (e.g., OsF₂, OsCl₂, OsBr₂, Osl₂, etc.), a cobalt halide (e.g., CoF₂, COCl₂, CoBr₂, Col₂, etc.), a rhodium halide (e.g., RhF₂, RhCl₂, RhBr₂, Rhl₂, etc.), an iridium halide (e.g., IrF₂, IrCl₂, IrBr₂, Irl₂, etc.), a nickel halide (e.g., NiF₂, NiCl₂, NiBr₂, Nil₂, etc.), a palladium halide (e.g., PdF₂, PdCl₂, PdBr₂, Pdl₂, etc.), a platinum halide (e.g., PtF₂, PtCl₂, PtBr₂, Ptl₂, etc.), a copper halide (e.g., CuF, CuCl, CuBr, Cul, etc.), a silver halide (e.g., AgF, AgCl, AgBr, Agl, etc.), a gold halide (e.g., AuF, AuCl, AuBr, Aul, etc.), and the like.

Examples of a post-transition metal halide may include a zinc halide (e.g., ZnF₂, ZnCl₂, ZnBr₂, Znl₂, etc.), an indium halide (e.g., Ink₃, etc.), a tin halide (e.g., Snl₂, etc.), and the like.

Examples of a lanthanide metal halide may include YbF, YbF₂, YbF₃, SmF₃, YbCl, YbCl₂, YbCl₃, SmCl₃, YbBr, YbBr₂, YbBr₃, SmBr₃, Ybl, Ybl₂, Ybl₃, Sml₃, and the like.

Examples of a metalloid halide may include an antimony halide (e.g., SbCl₅, etc.) and the like.

Examples of a metal telluride may include an alkali metal telluride (e.g., Li₂Te, Na₂Te, K₂Te, Rb₂Te, Cs₂Te, etc.), an alkaline earth metal telluride (e.g., BeTe, MgTe, CaTe, SrTe, BaTe, etc.), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (e.g., ZnTe, etc.), a lanthanide metal telluride (e.g., LaTe, CeTe, PrTe, NdTe, PmTe, EuTe, GdTe, TbTe, DyTe, HoTe, ErTe, TmTe, YbTe, LuTe, etc.), and the like.

### [Emission Layer 130]

In case that the light-emitting device 10 is a full-color light-emitting device, the emission layer 130 may be patterned into a red emission layer, a green emission layer, and/or a blue emission layer, according to a subpixel. In an embodiment, the emission layer 130 may have a stacked structure of two or more layers of a red emission layer, a green emission layer, and a blue emission layer, in which the two or more layers contact each other or are separated from each other, to emit white light. In an embodiment, the emission layer 130 may include two or more materials of a red light-emitting material, a green light-emitting material, and a blue light-emitting material, in which the two or more materials may be mixed with each other in a single layer, to emit white light.

The emission layer 130 may include a host and a dopant. The dopant may include a phosphorescent dopant, a fluorescent dopant, or any combination thereof.

An amount of the dopant in the emission layer 130 may be in a range of about 0.01 part by weight to about 15 parts by weight, based on 100 parts by weight of the host.

In an embodiment, the emission layer 130 may include the quantum dot described above.

In an embodiment, the emission layer 130 may include a delayed fluorescence material. The delayed fluorescence material may act as a host or a dopant in the emission layer.

A thickness of the emission layer 130 may be in a range of about 100 Å to about 1,000 Å. For example, the thickness of the emission layer 130 may be in a range of about 200 Å to about 600 Å. In case that the thickness of the emission layer 130 is within the range described above, excellent luminescence characteristics may be obtained without a substantial increase in driving voltage.

### [Host]

The host may include a compound represented by Formula 301:

[Ar₃₀₁]_{xb11}—[(L₃₀₁)_{xb1}—R₃₀₁]_{xb21} [Formula 301]

In Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to 0303 may each independently be the same as described in connection with Q₁.

In an embodiment, in Formula 301 in case that xb11 is 2 or more, two or more of Ar₃₀₁ may be linked to each other via a single bond.

In an embodiment, the host may include a compound represented by Formula 301-1, a compound represented by Formula 301-2, or any combination thereof:

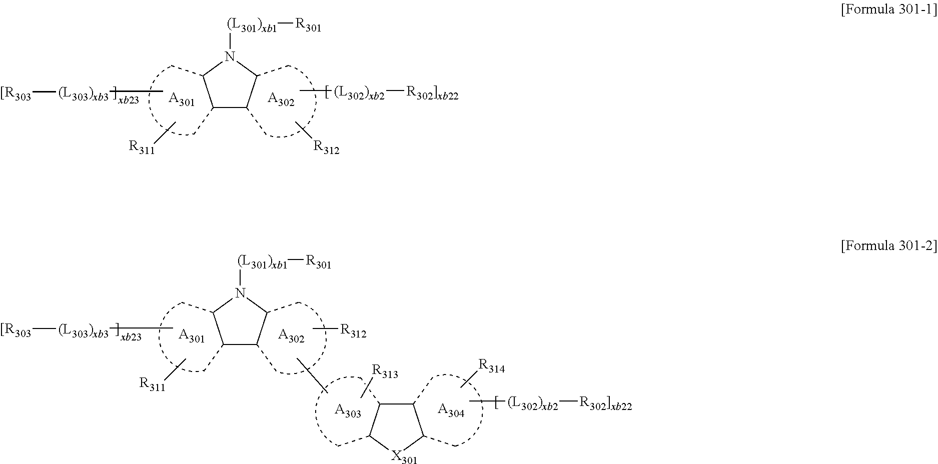

In Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N—[(L₃₀₄)_{xb4}—R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ are each the same as described herein,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, the host may include an alkali earth metal complex, a post-transition metal complex, or any combination thereof. For example, the host may include a Be complex (e.g., Compound H55), a Mg complex, a Zn complex, or any combination thereof.

In an embodiment, the host may include one of Compounds H1 to H128, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di(carbazol-9-yl)benzene (mCP), 1,3,5-tri(carbazol-9-yl)benzene (TCP), or any combination thereof:

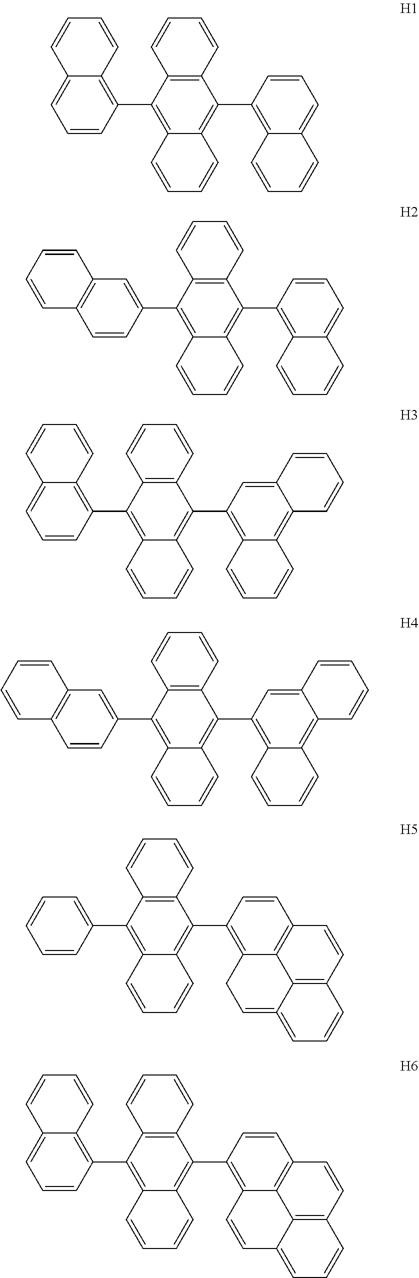

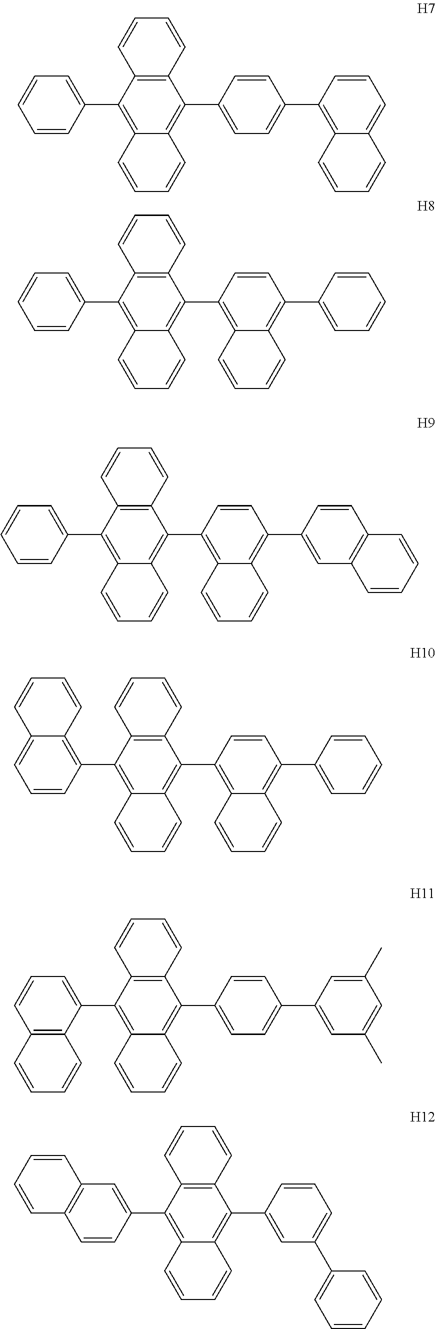

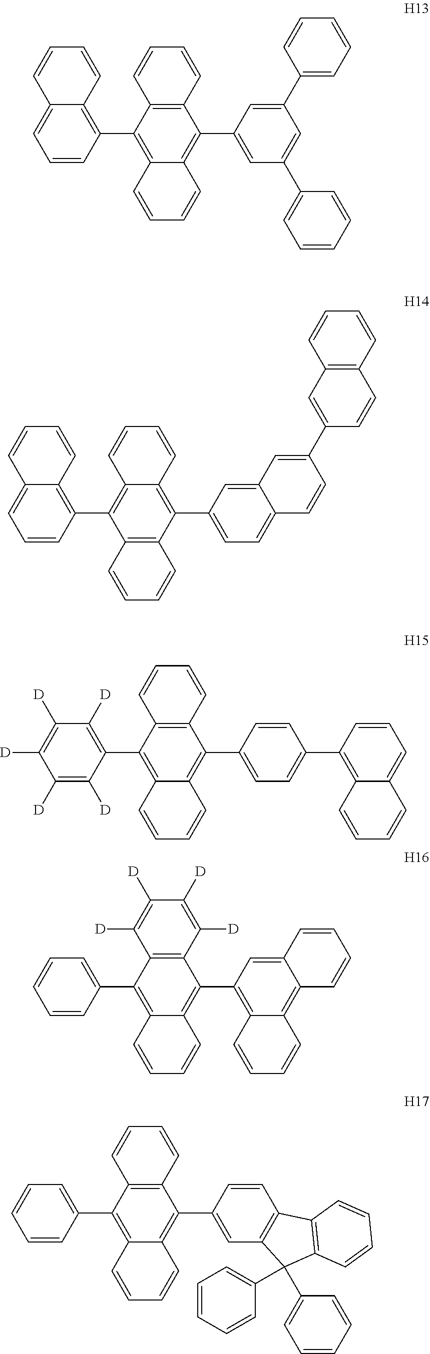

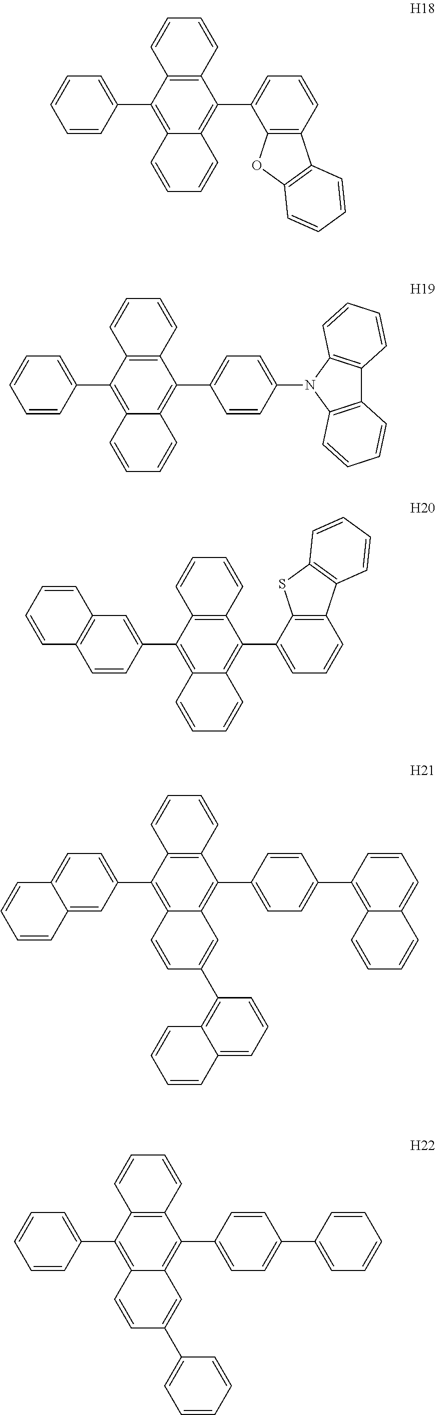

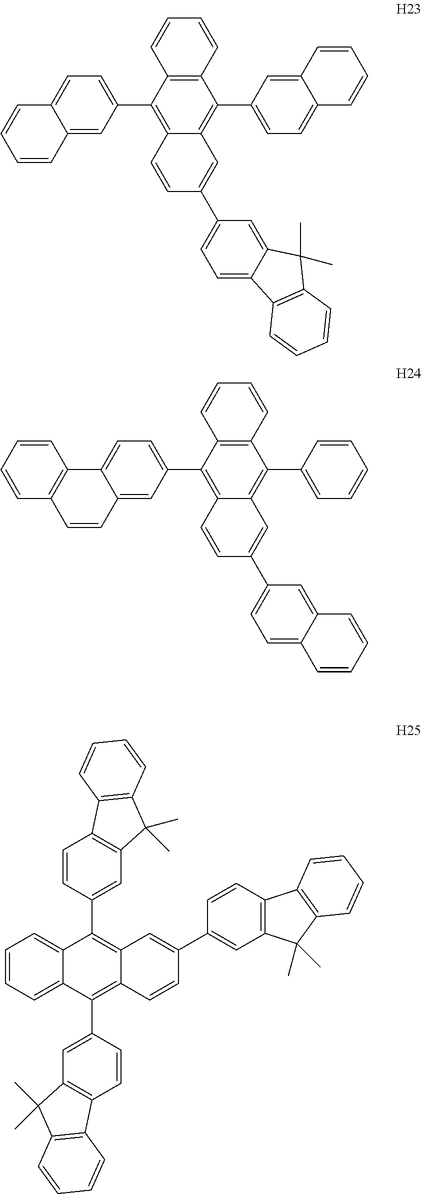

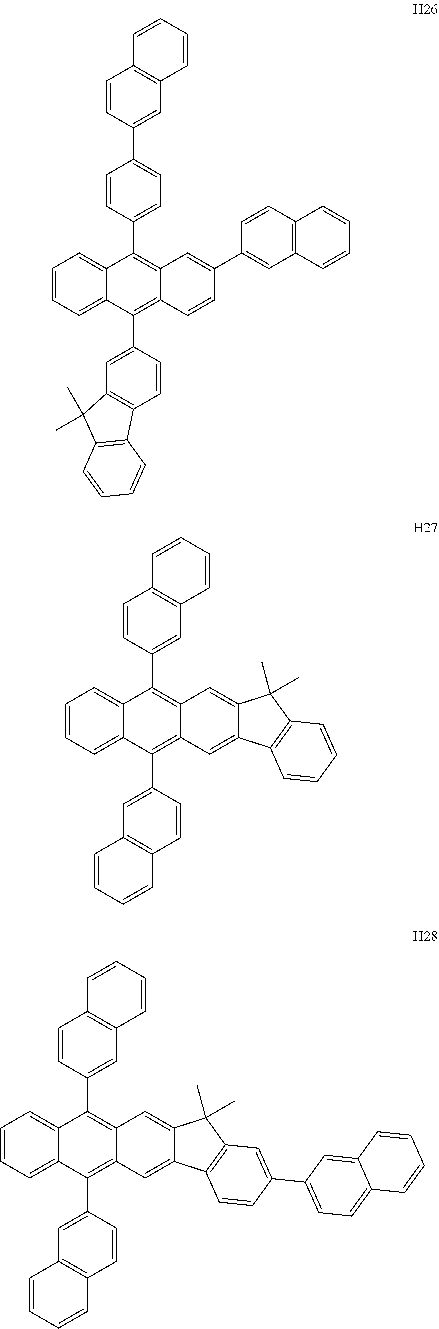

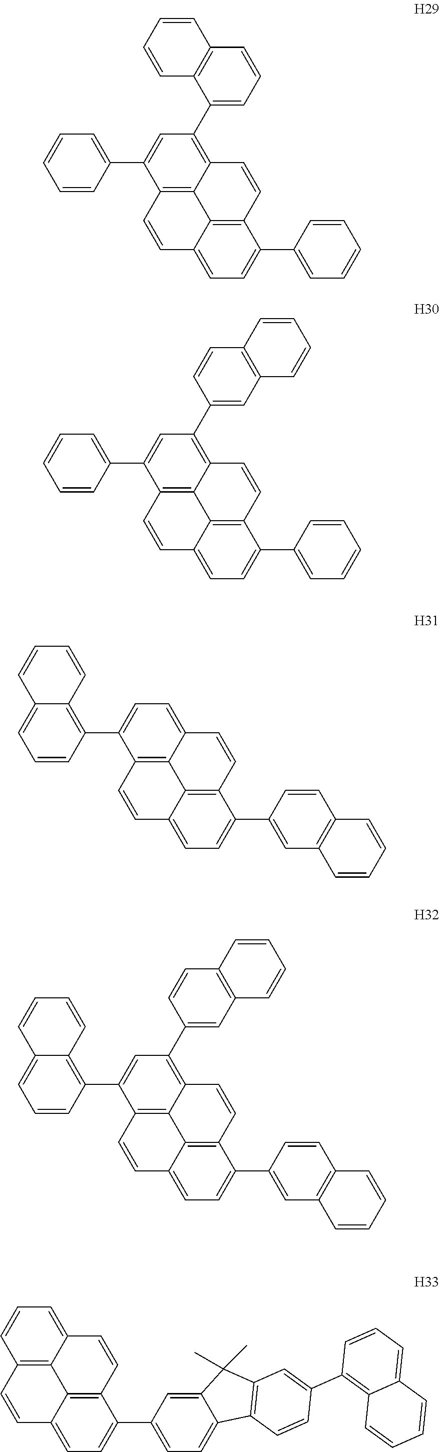

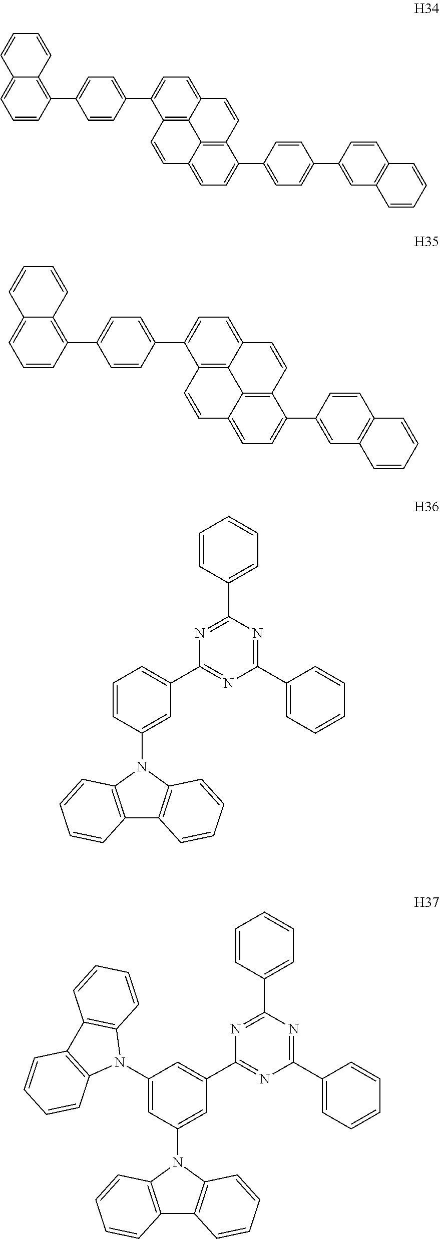

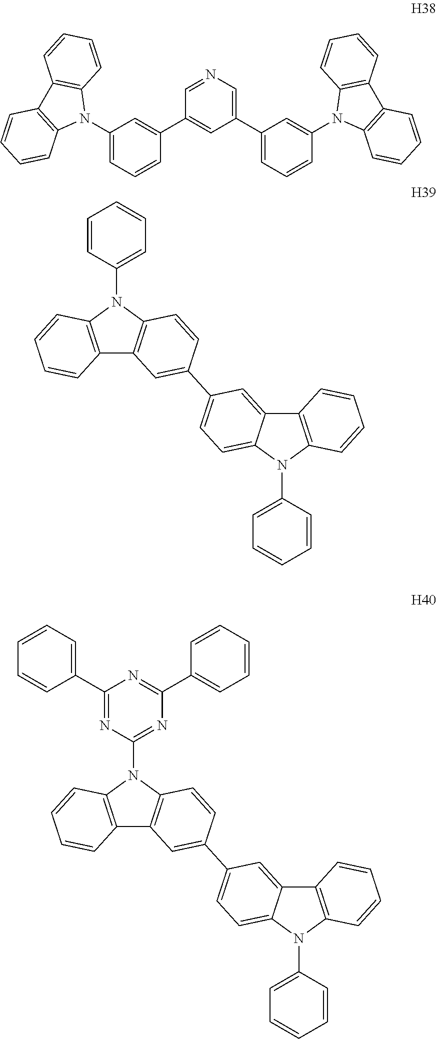

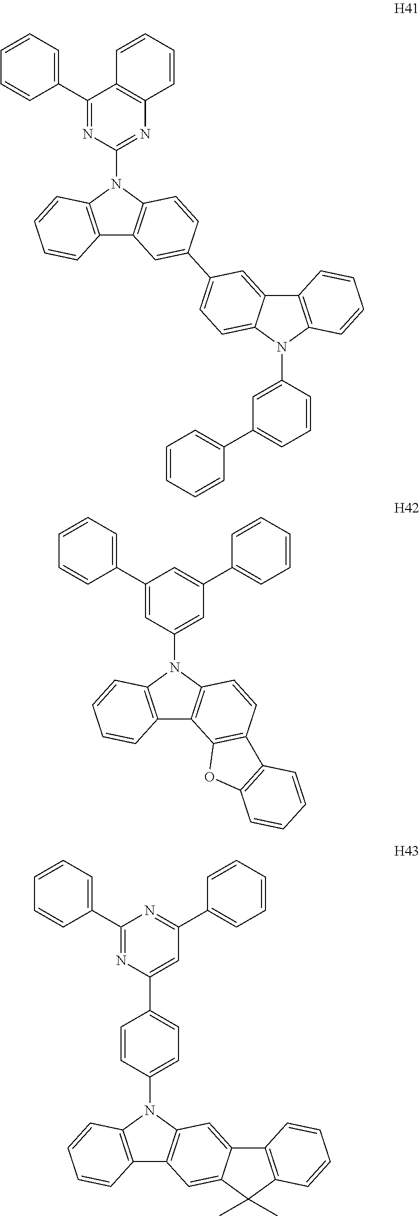

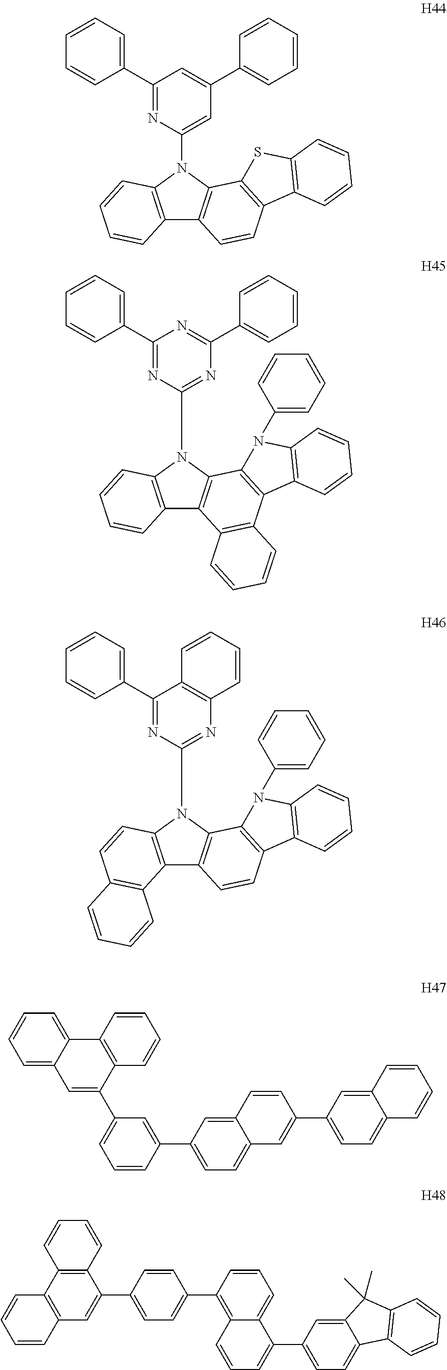

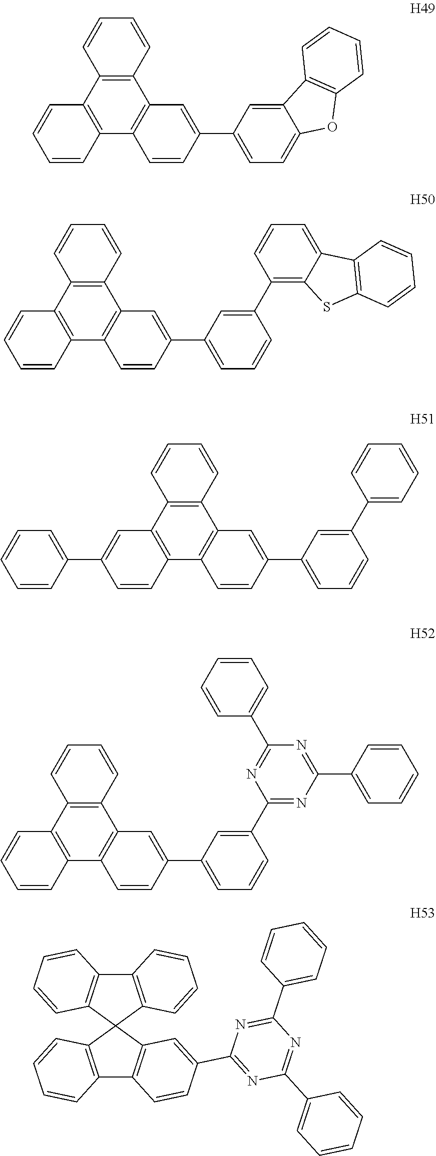

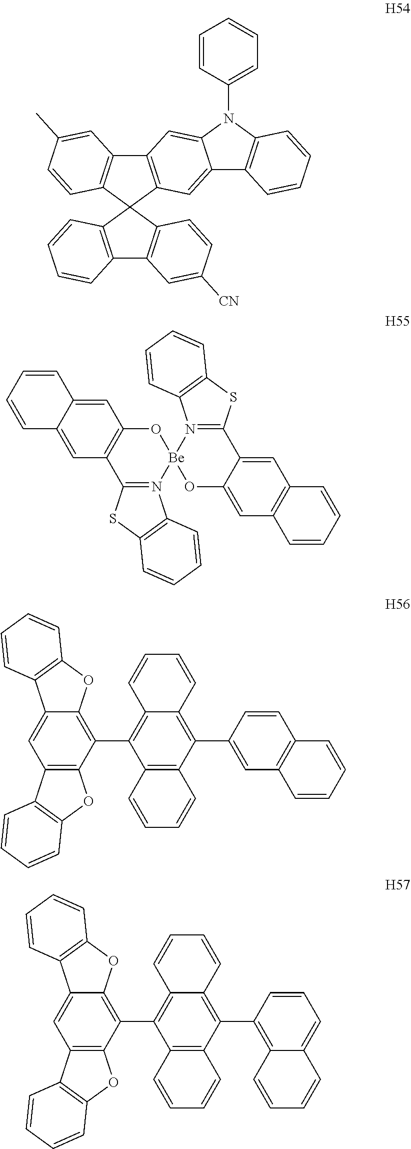

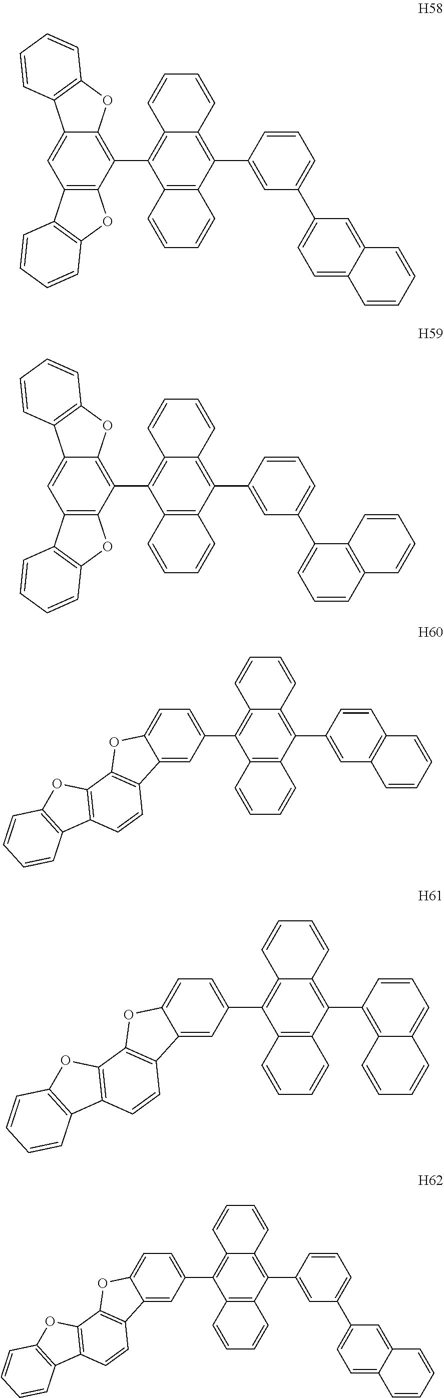 [SMILES: c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1]

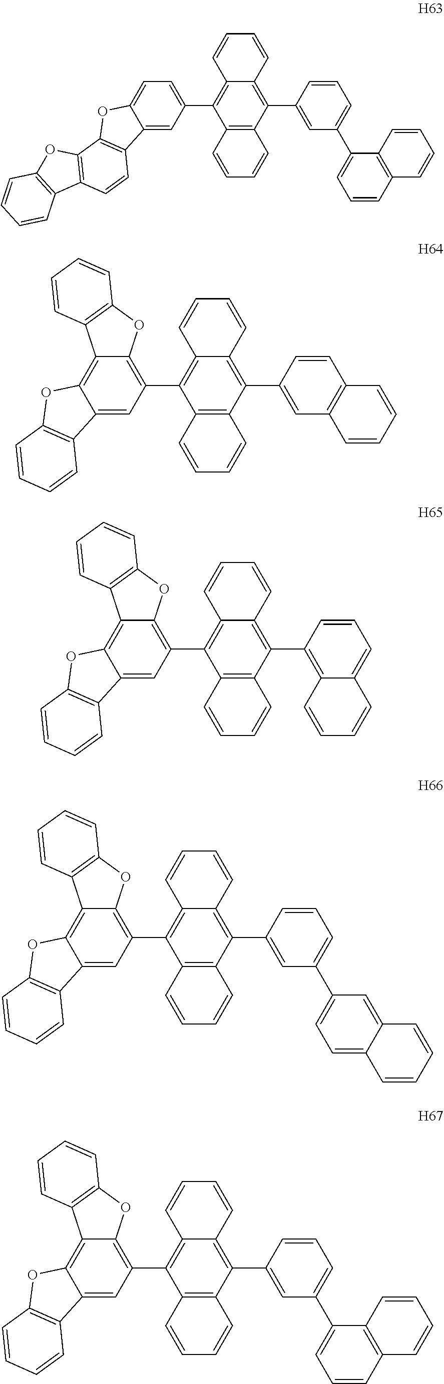 [SMILES: c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1]

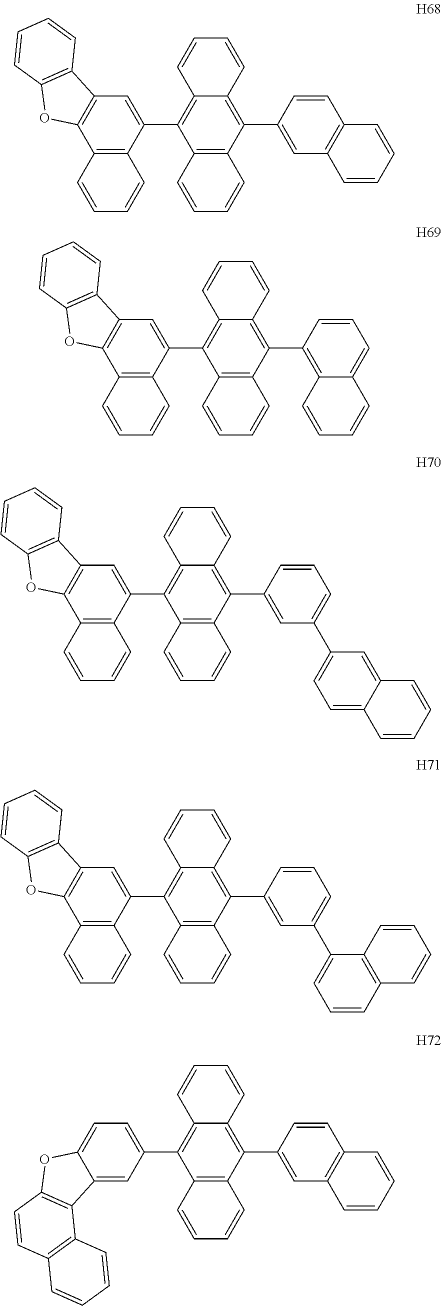

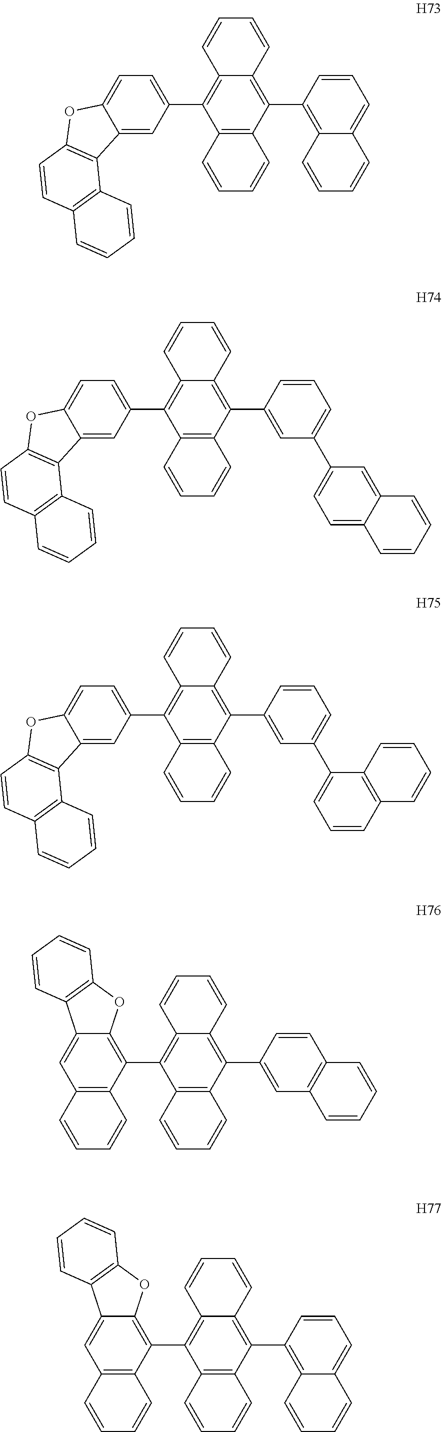 [SMILES: c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1]

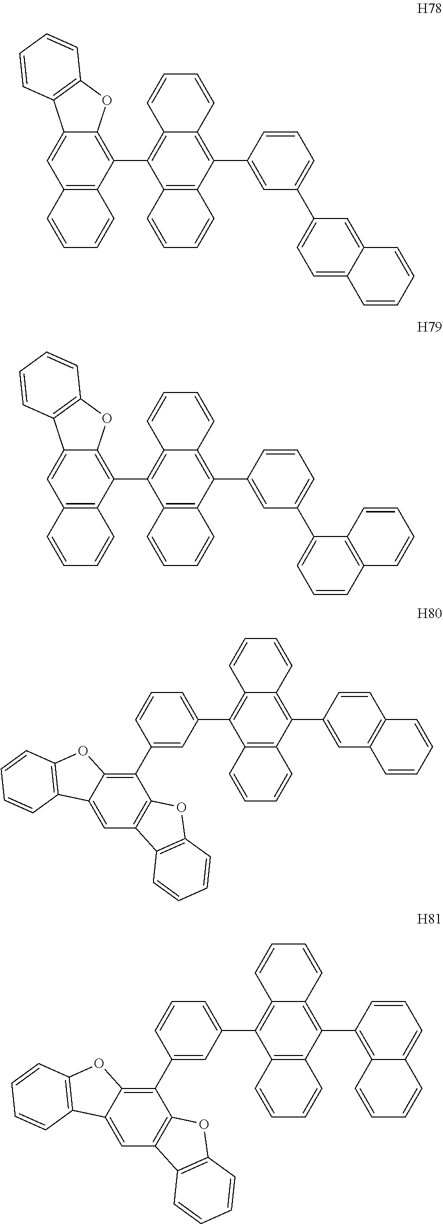 [SMILES: c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1]

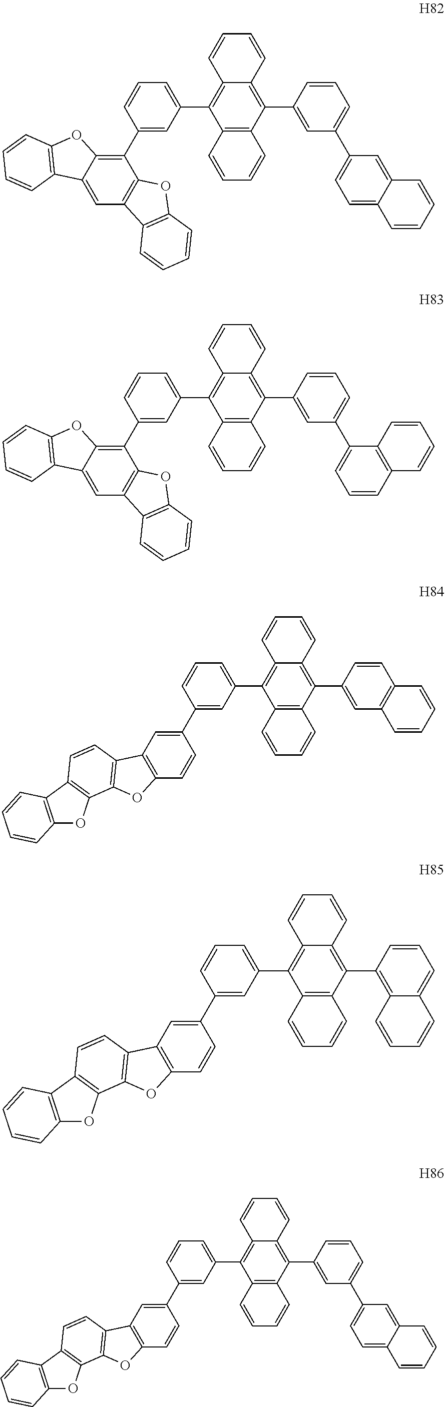 [SMILES: c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1]

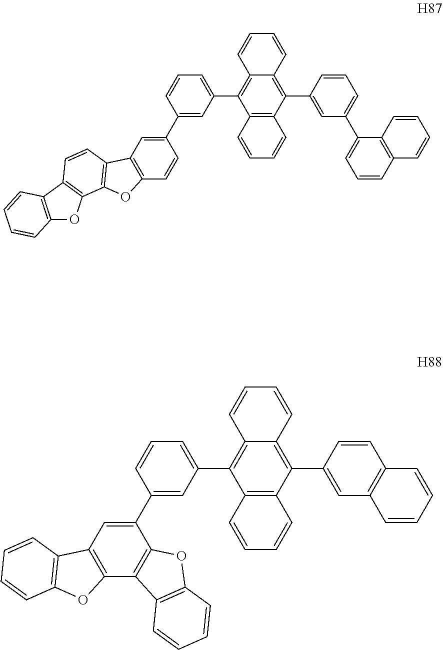 [SMILES: c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1]

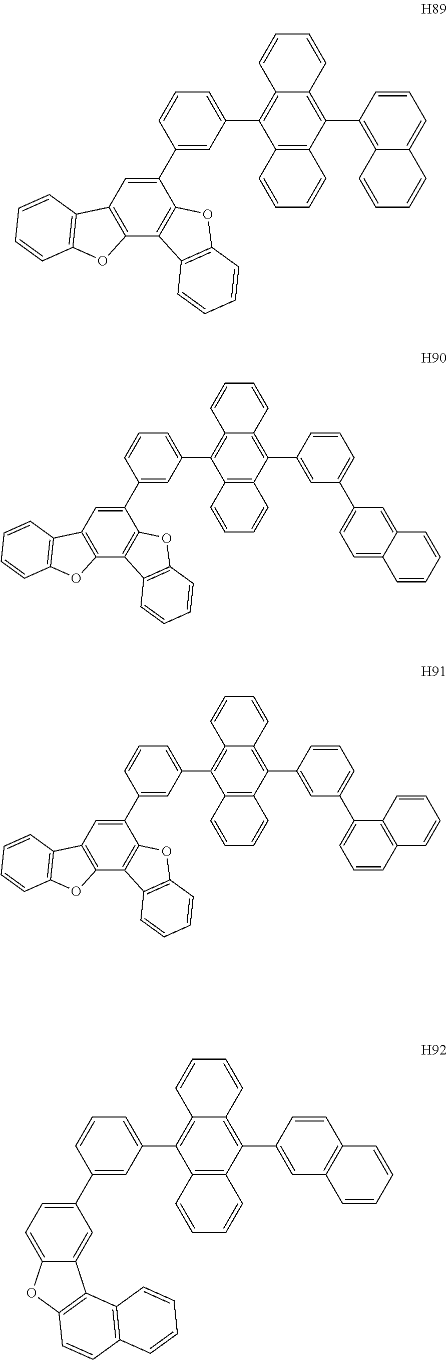 [SMILES: c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1]

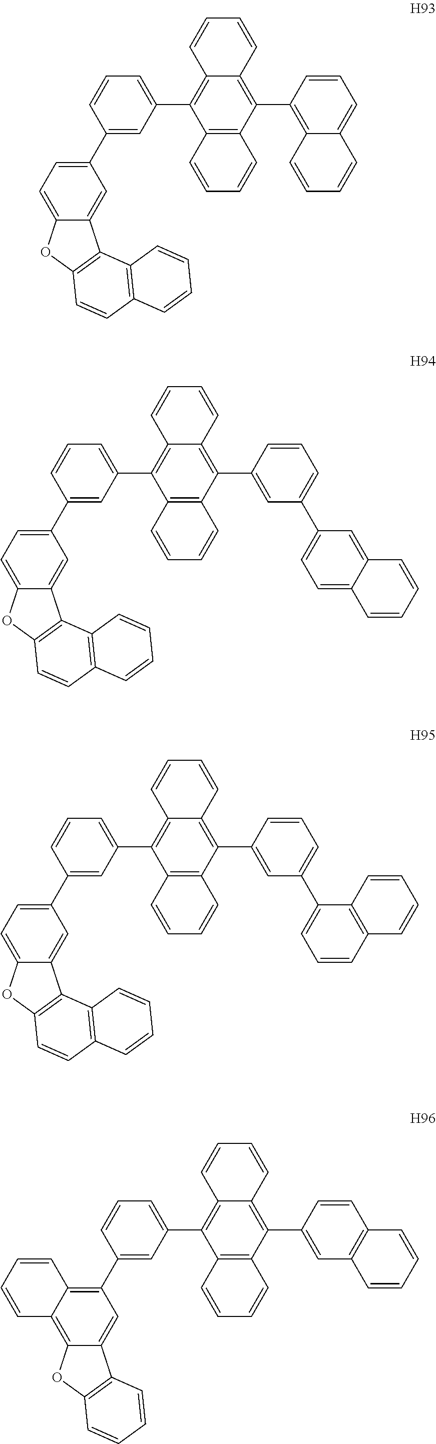 [SMILES: c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1]

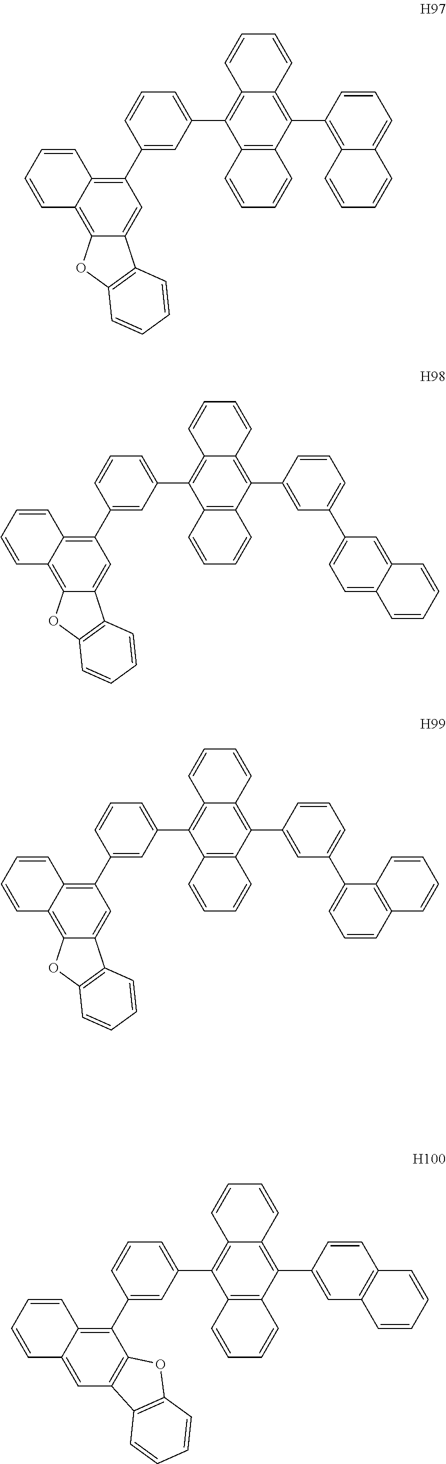 [SMILES: c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1]

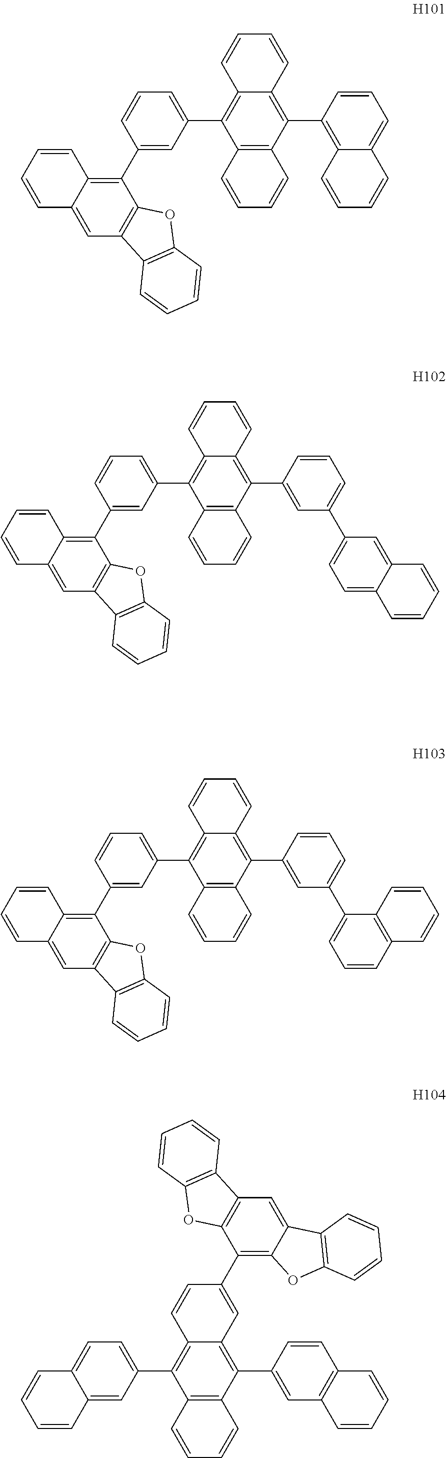 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

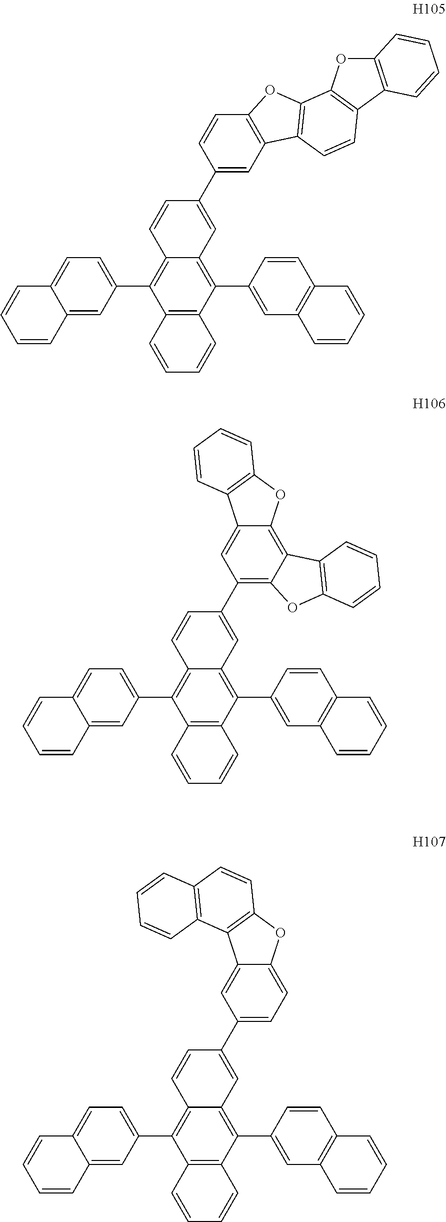 [SMILES: c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1]

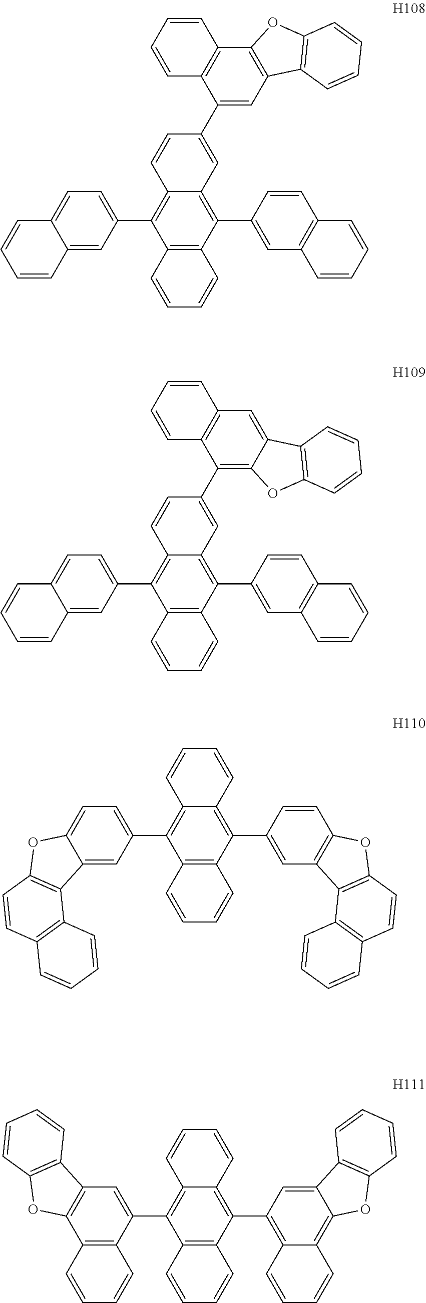 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

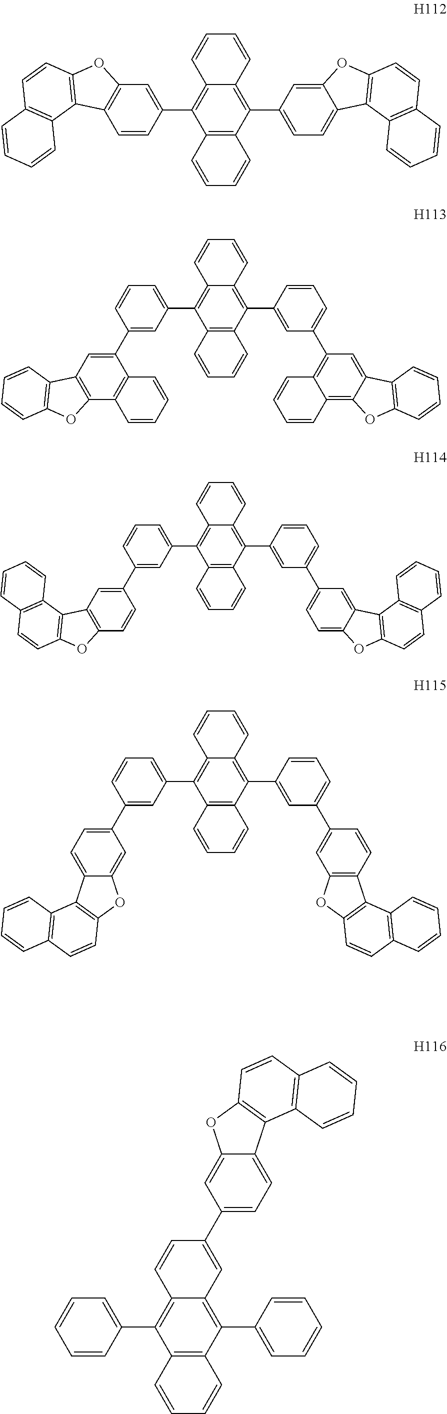 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

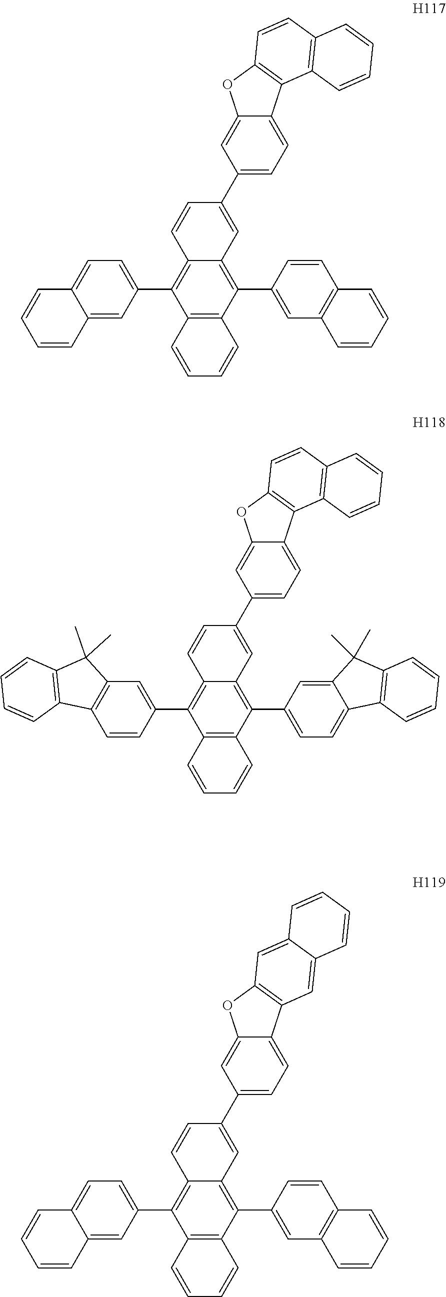 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1]

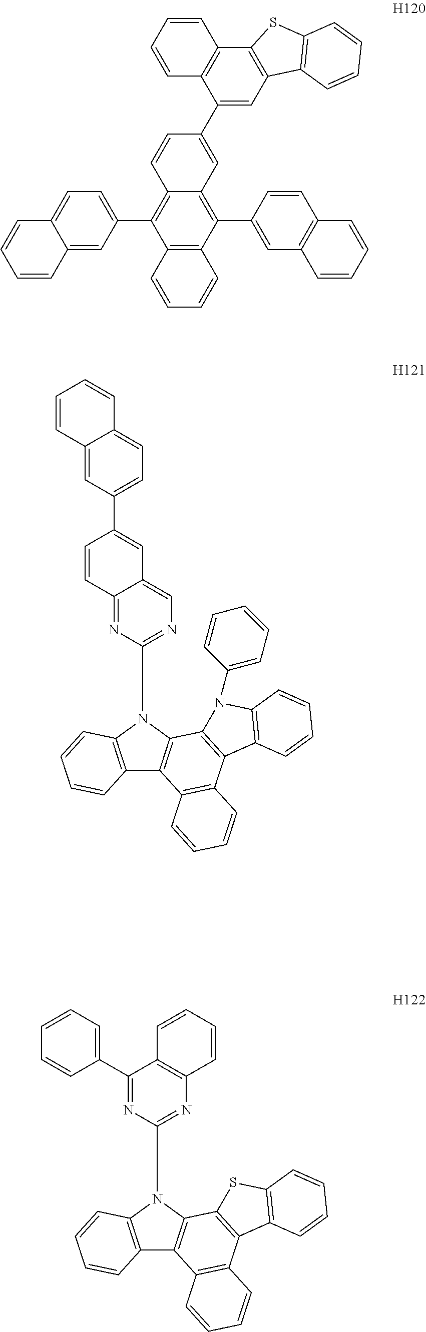 [SMILES: c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1]

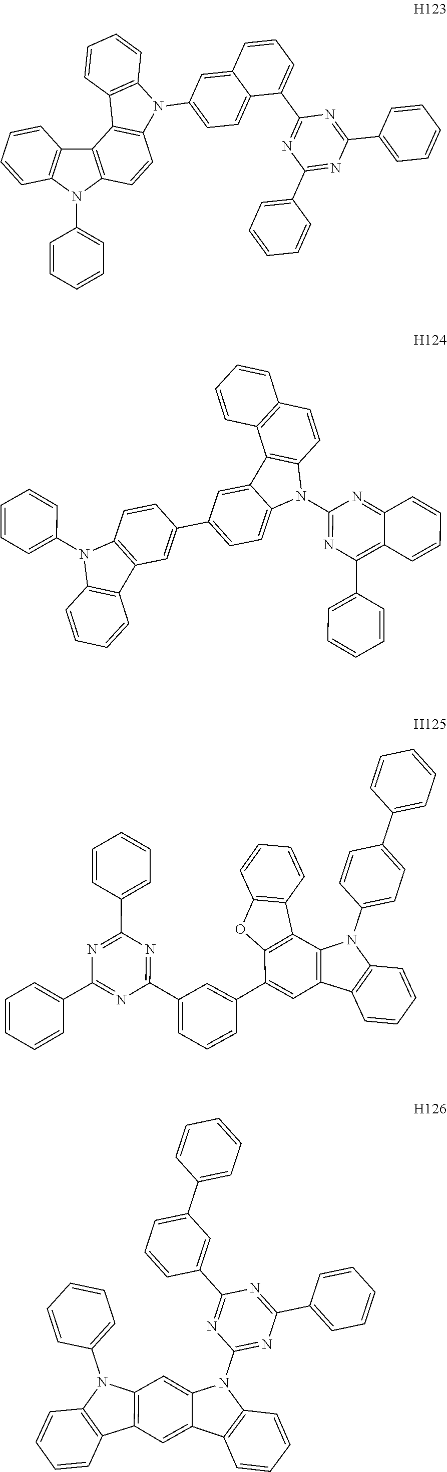 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1]

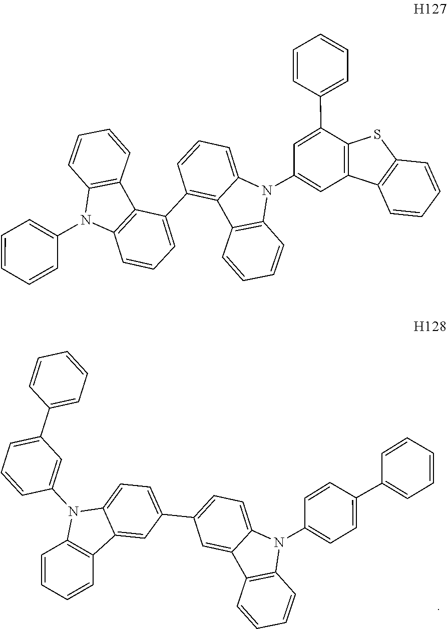 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

M(L₄₀₁)_{xc1}(L₄₀₂)_{xc2} [Formula 401]

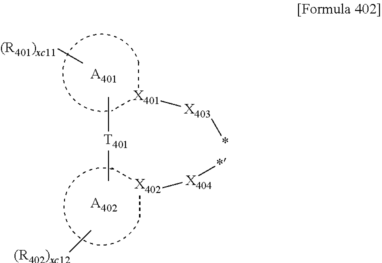

In Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, in case that xc1 is 2 or more, two or more of L₄₀₁ may be identical to or different from each other,
L₄₀₂ may be an organic ligand, and xc2 may be 0, 1, 2, 3, or 4, wherein, in case that xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)—*′, *—C(Q₄₁₁)(Q₄₁₂)—*′, *—C(Q₄₁₁)═C(Q₄₁₂)—*′, *—C(Q₄₁₁)═*′, or *═C═*′,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described in connection with Q₁,
xc11 and xc12 may each independently be an integer from 0 to 10, and
the symbols * and *′ in Formula 402 may each indicate a binding site to M in Formula 401.

In an embodiment, in Formula 402, X₄₀₁ may be nitrogen and X₄₀₂ may be carbon, or X₄₀₁ and X₄₀₂ may each be nitrogen.

In an embodiment, in Formula 401, in case that xc1 is 2 or more, two of ring A₄₀₁ among two or more of L₄₀₁ may optionally be linked to each other via T₄₀₂, which is a linking group, and two of ring A₄₀₂ among two or more of L₄₀₁ may optionally be linked to each other via T₄₀₃, which is a linking group (see Compounds PD1 to PD4 and PD7). T₄₀₂ and T₄₀₃ may each independently be the same as described in connection with T₄₀₁.

in Formula 401, L₄₀₂ may be an organic ligand. For example, L₄₀₂ may include a halogen group, a diketone group (e.g., an acetylacetonate group), a carboxylic acid group (e.g., a picolinate group), —C(═O), an isonitrile group, a —CN group, a phosphorus group (e.g., a phosphine group, a phosphite group, etc.), or any combination thereof.

The phosphorescent dopant may include, for example, one of Compounds PD1 to PD39, or any combination thereof:

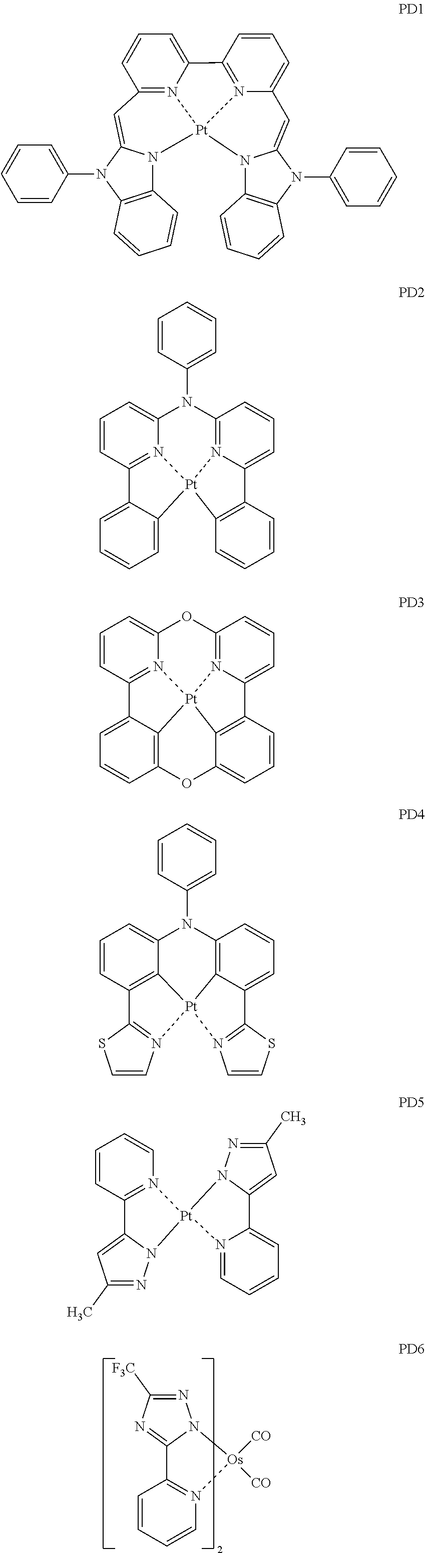

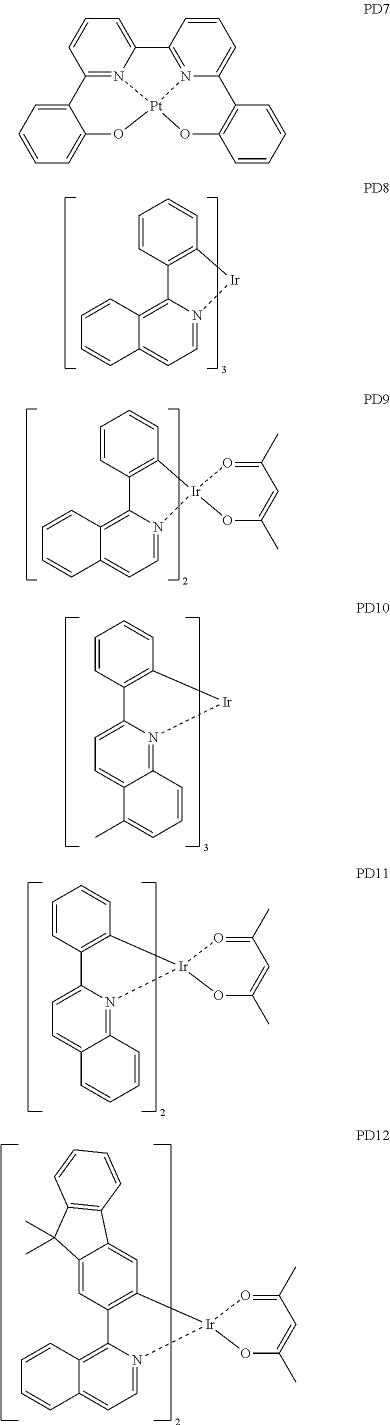

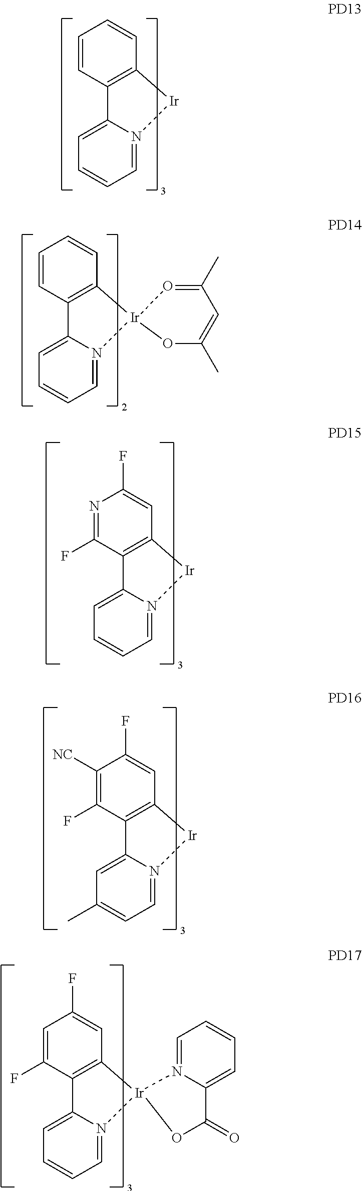

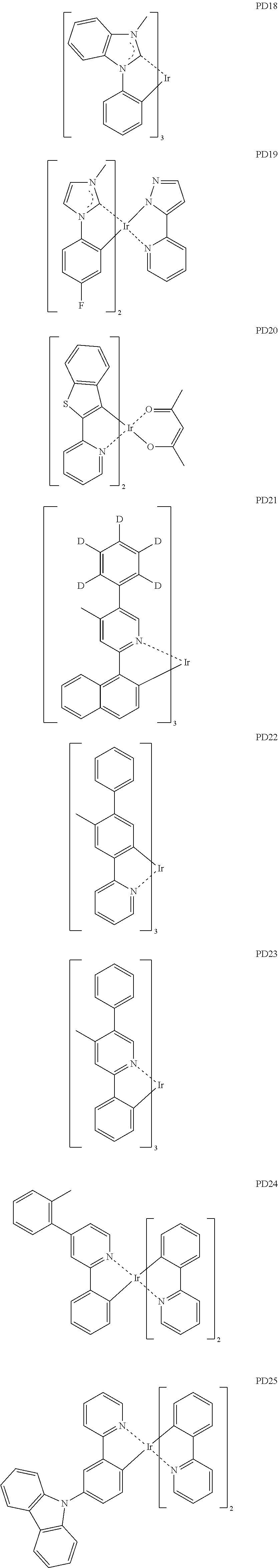

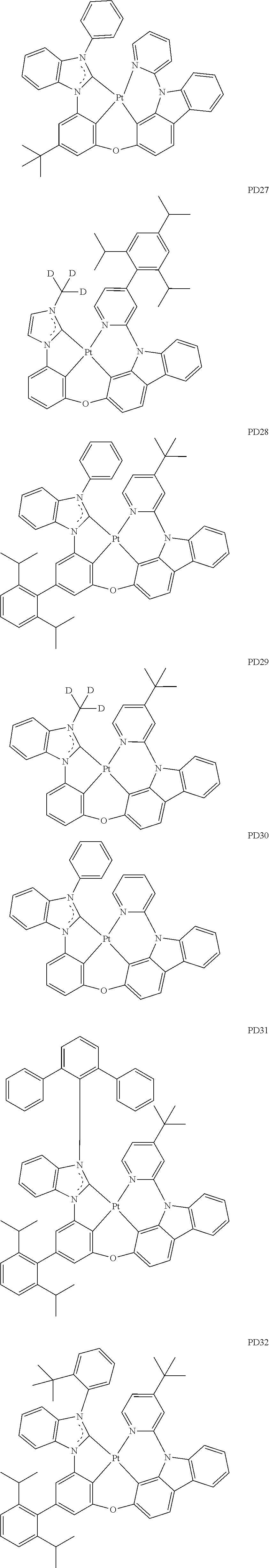

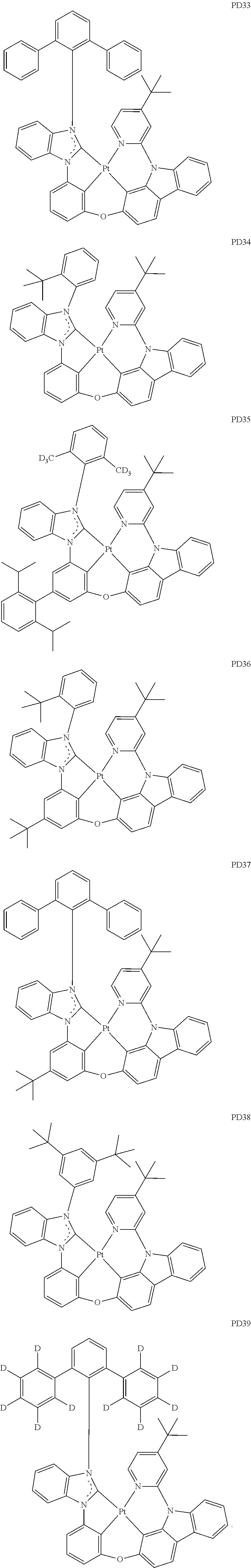

### [Fluorescent Dopant]

The fluorescent dopant may include an amine group-containing compound, a styryl group-containing compound, or any combination thereof.

In an embodiment, the fluorescent dopant may include a compound represented by Formula 501:

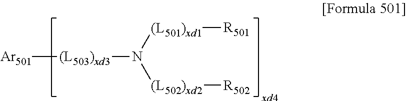

In Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In an embodiment, in Formula 501, Ar₅₀₁ may be a condensed cyclic group (e.g., an anthracene group, a chrysene group, a pyrene group, etc.) in which three or more monocyclic groups are condensed with each other.

In an embodiment, in Formula 501, xd4 may be 2.

In an embodiment, the fluorescent dopant may include: one of Compounds FD1 to FD37; DPVBi; DPAVBi; or any combination thereof:

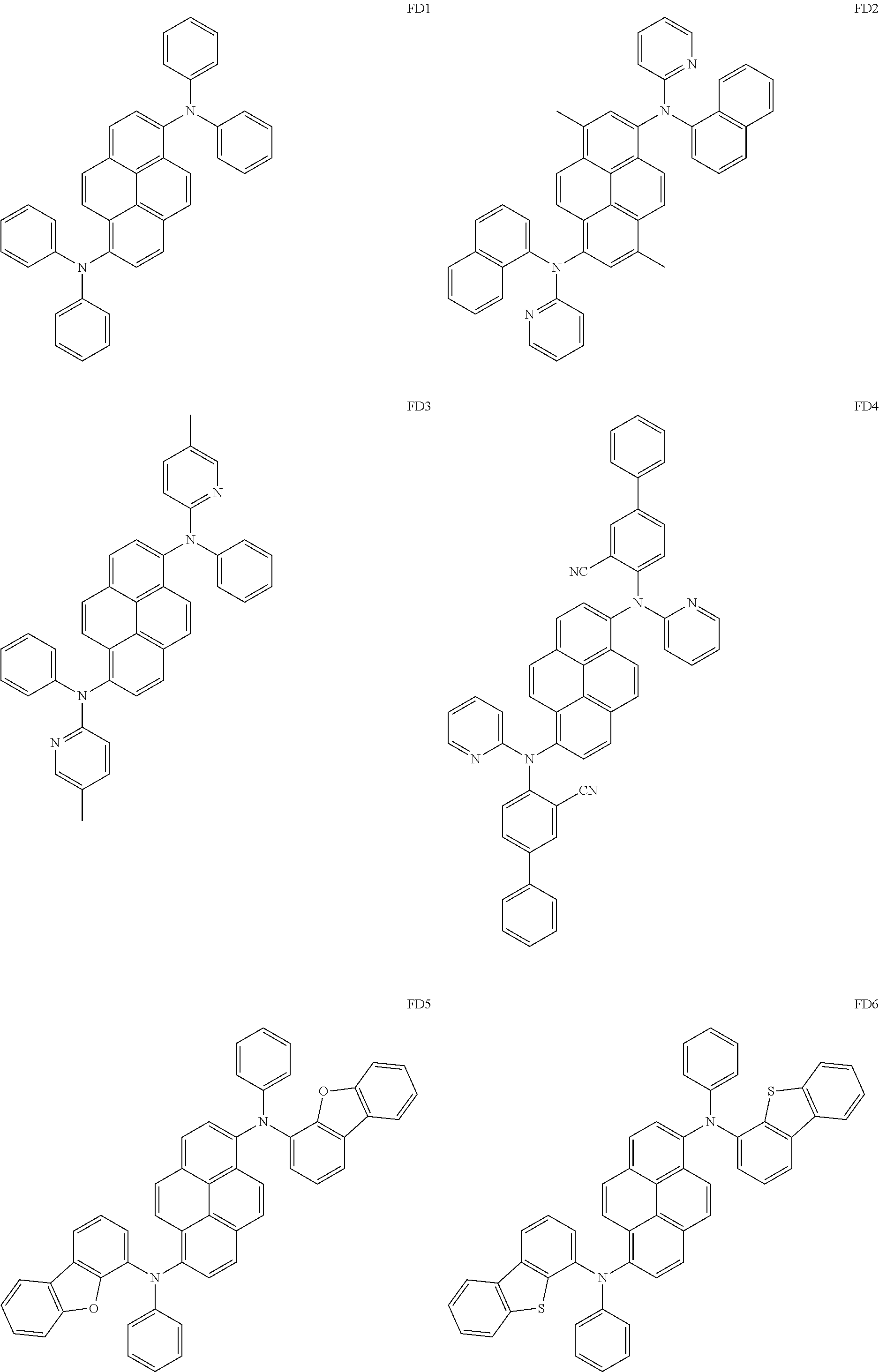

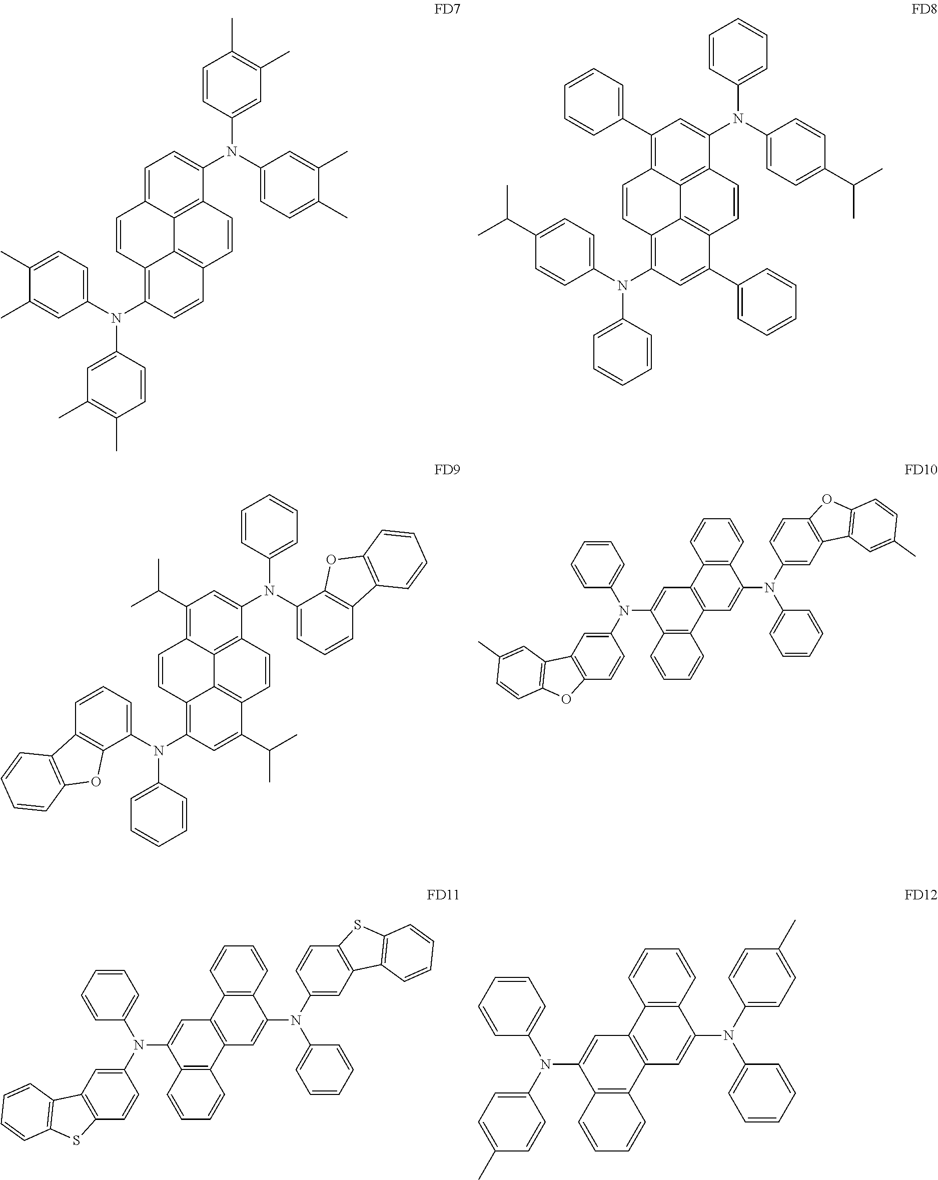

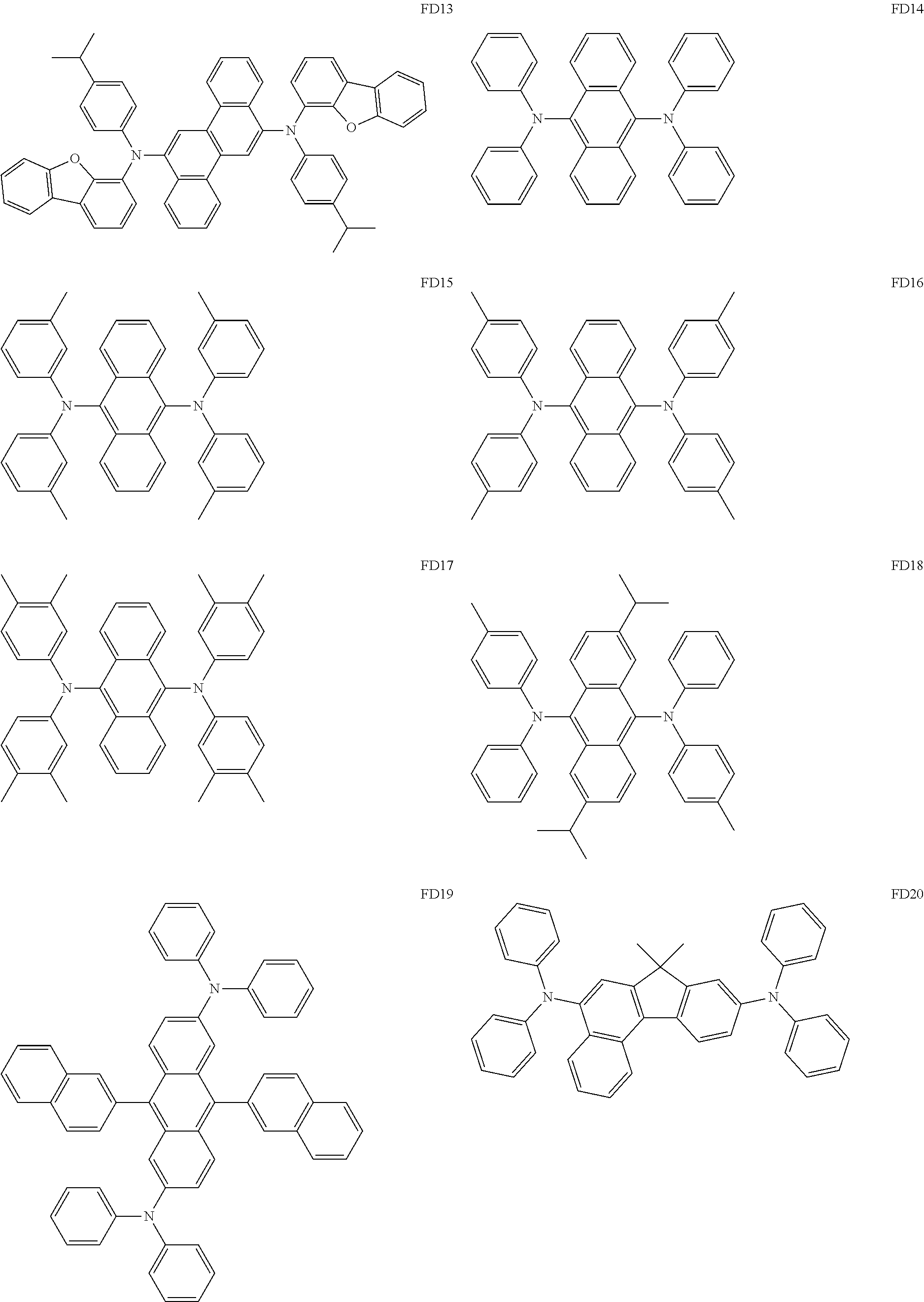

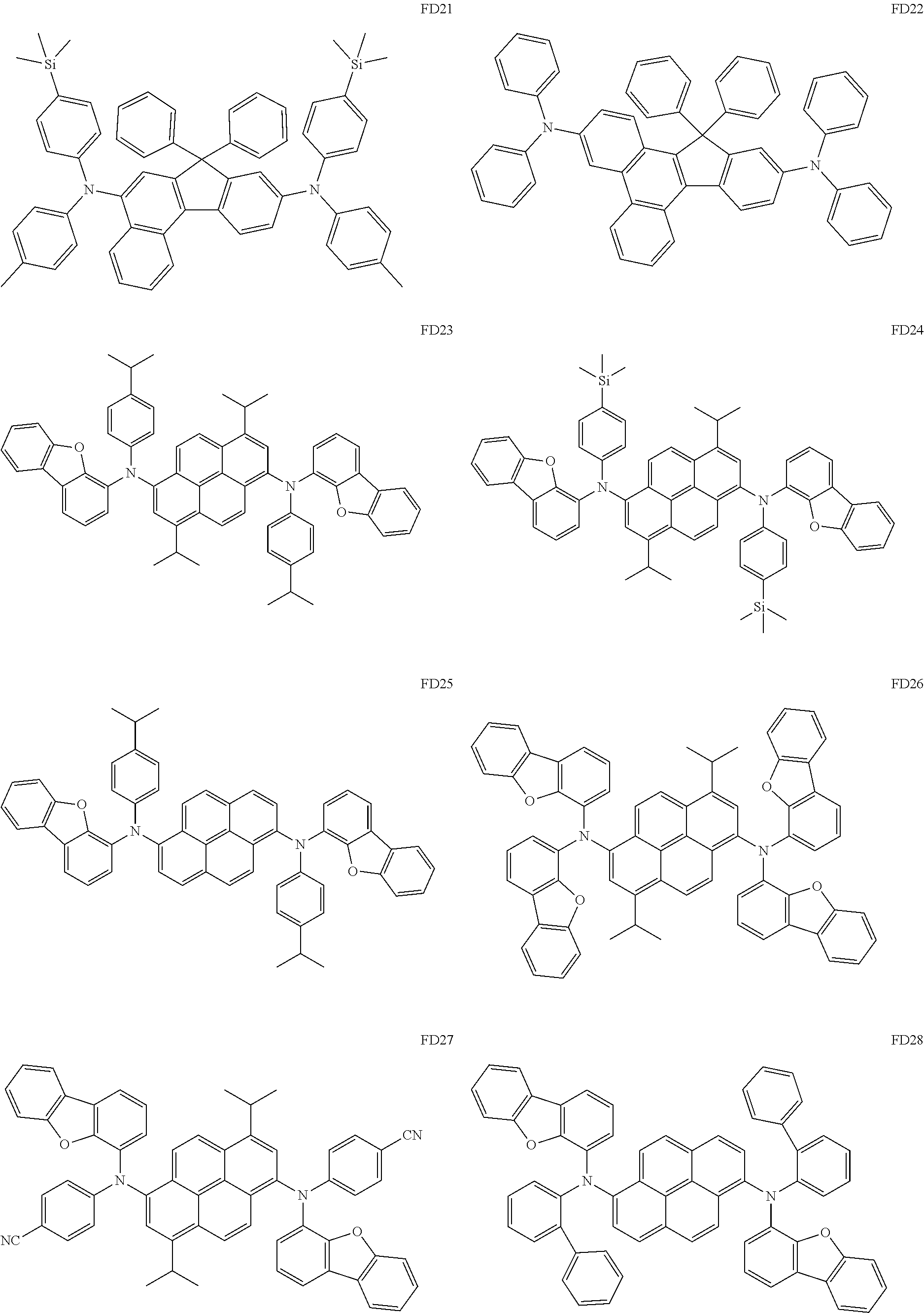

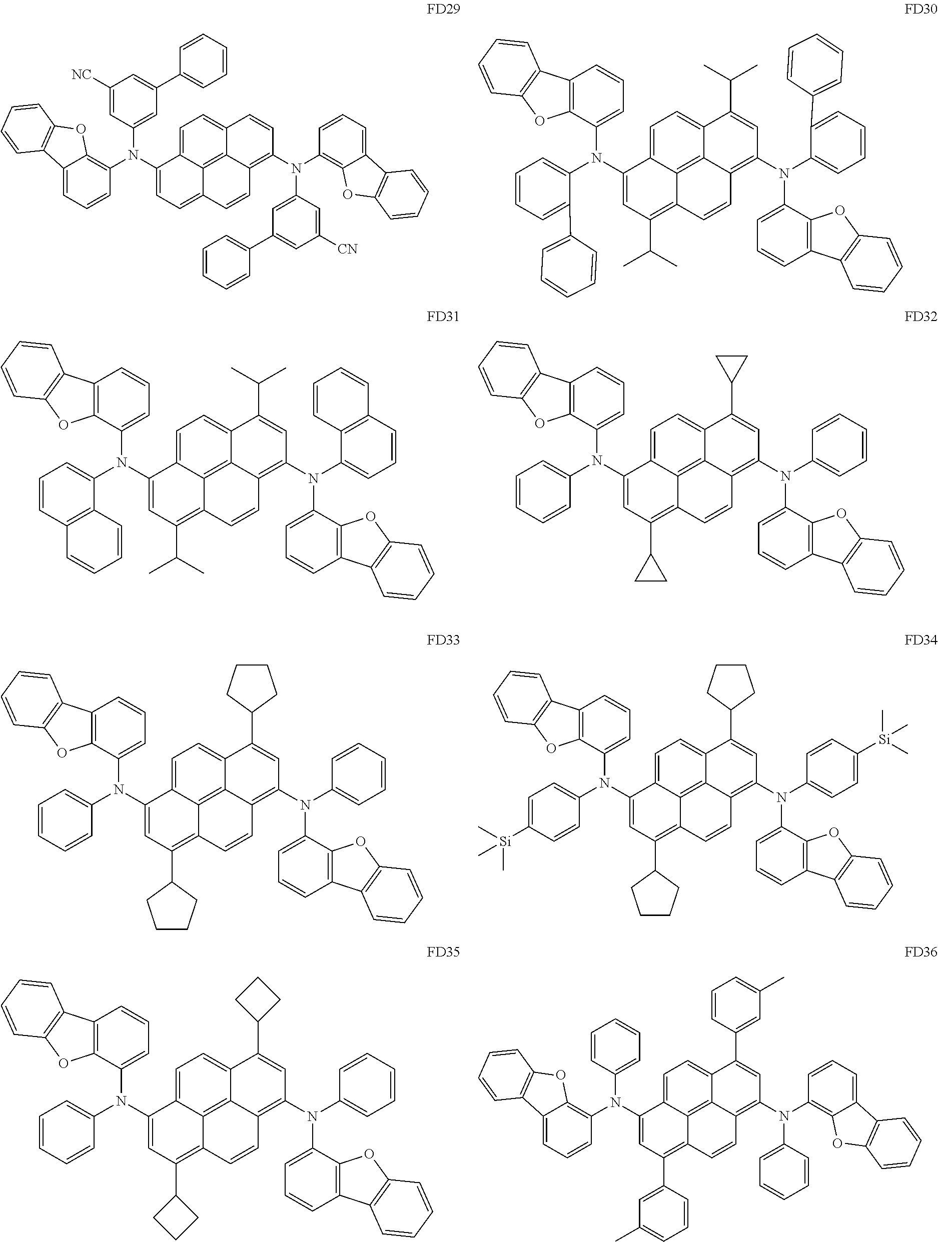

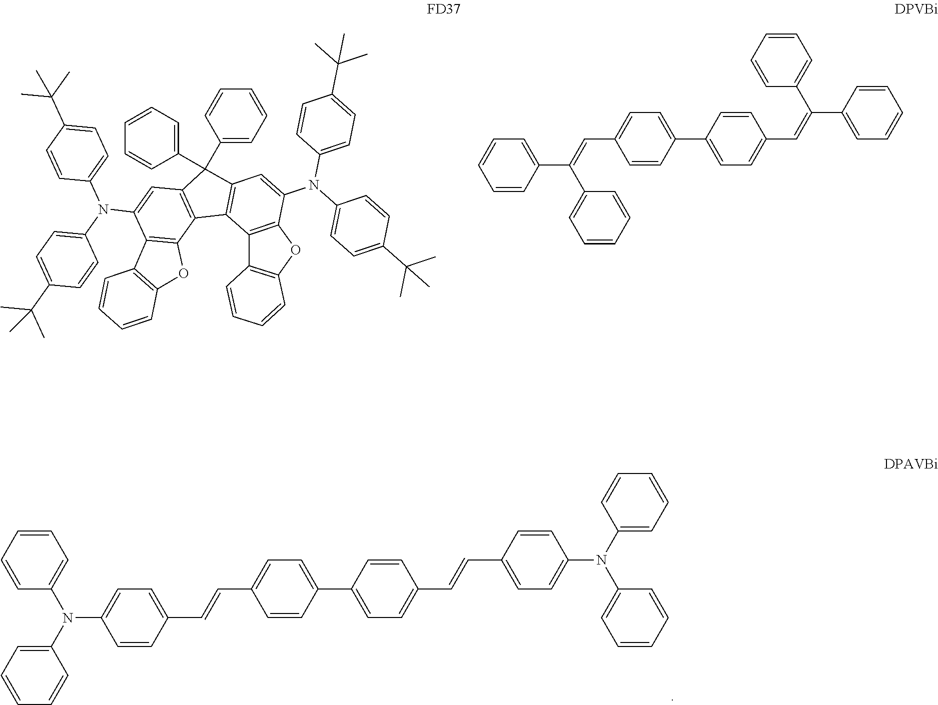

### [Delayed Fluorescence Material]

The emission layer 130 may include a delayed fluorescence material.

The delayed fluorescence material described herein may be selected from compounds capable of emitting delayed fluorescence based on a delayed fluorescence emission mechanism.

The delayed fluorescence material included in the emission layer 130 may serve as a host or as a dopant, depending on the types of other materials included in the emission layer 130.

In an embodiment, a difference between a triplet energy level (eV) of the delayed fluorescence material and a singlet energy level (eV) of the delayed fluorescence material may be in a range of about 0 eV to about 0.5 eV. In case that the difference between a triplet energy level (eV) of the delayed fluorescence material and a singlet energy level (eV) of the delayed fluorescence material is within the above range, up-conversion from the triplet state to the singlet state of the delayed fluorescence materials may effectively occur, and thus, the light-emitting device 10 may have improved luminescence efficiency.

In an embodiment, the delayed fluorescence material may include: a material including at least one electron donor (e.g., a π electron-rich C₃-C₆₀ cyclic group, such as a carbazole group, etc.) and at least one electron acceptor (e.g., a sulfoxide group, a cyano group, a π electron-deficient nitrogen-containing C₁-C₆₀ cyclic group, etc.); or a material including a C₈-C₆₀ polycyclic group including two or more cyclic groups condensed to each other while sharing boron (B), and the like.

Examples of a delayed fluorescence material may include at least one of Compounds DF1 to DF14:

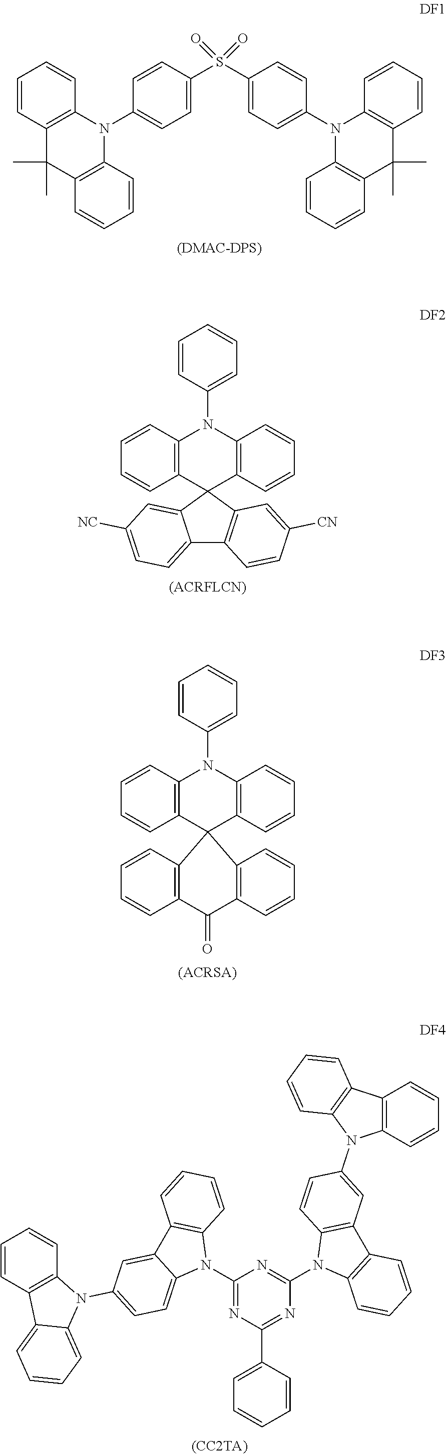

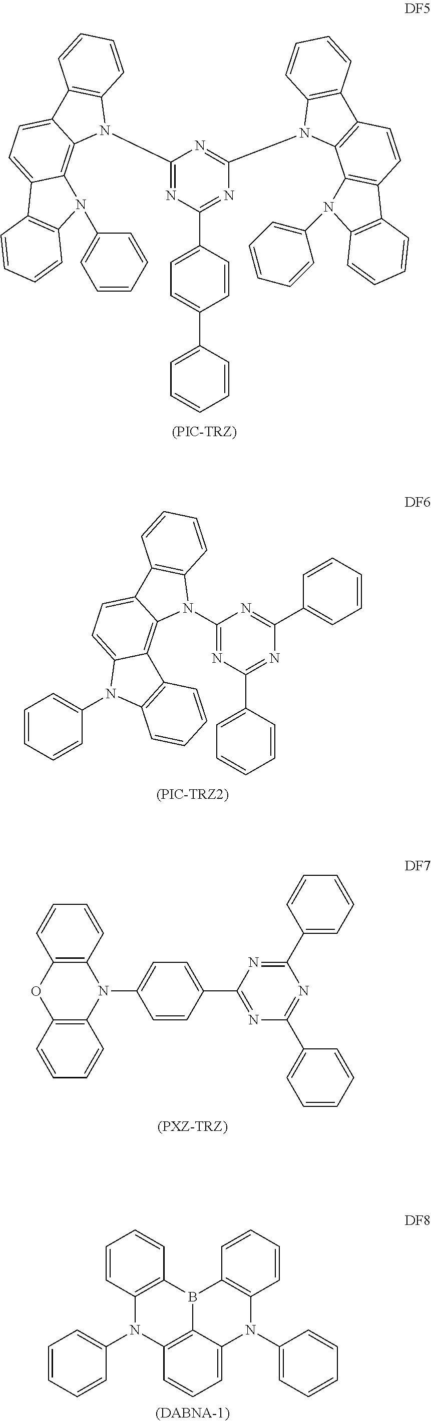

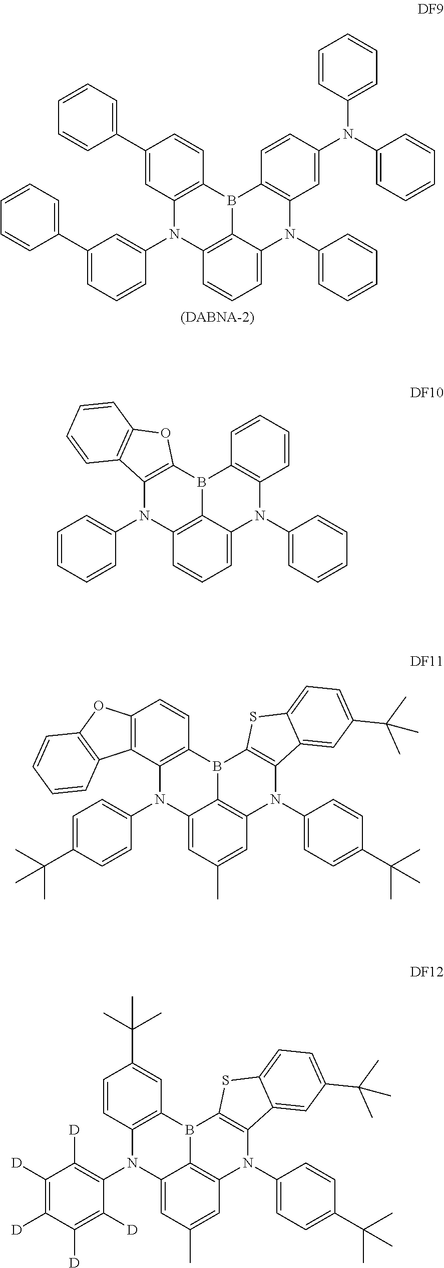

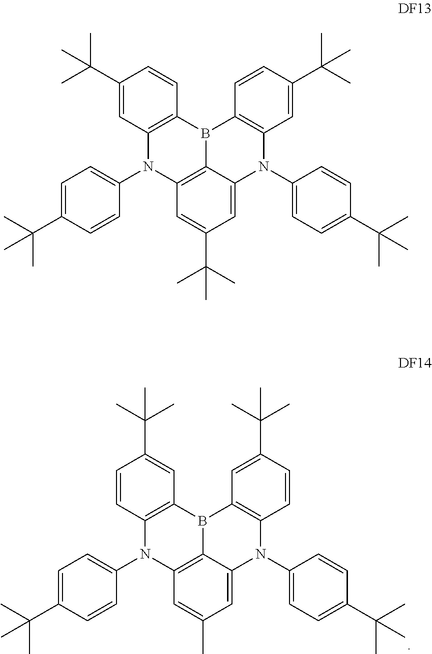

### [Quantum Dot]

The emission layer 130 may include the quantum dot described above.

In the specification, a quantum dot may be a crystal of a semiconductor compound. Quantum dots may emit light of various emission wavelengths according to a size of the crystal. Quantum dots may emit light of various emission wavelengths by adjusting a ratio of elements constituting the quantum dots.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method that includes mixing a precursor material with an organic solvent and growing a quantum dot particle crystal. When the crystal grows, the organic solvent naturally acts as a dispersant coordinated on the surface of the quantum dot crystal and controls the growth of the crystal so that the growth of quantum dot particles can be controlled through a process which costs less, and may be more readily performed than vapor deposition methods, such as metal organic chemical vapor deposition (MOCVD) or molecular beam epitaxy (MBE).

The quantum dot may include a Group II-VI semiconductor compound, a Group II-V semiconductor compound, a Group II-VI semiconductor compound, a Group I-III-VI semiconductor compound, a Group IV-VI semiconductor compound, a Group IV element or compound, or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, MgS, or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or the like; a quaternary compound, such as CdZnSeS, CdZnSeTe, CdZnSTe, CdHgSeS, CdHgSeTe, CdHgSTe, HgZnSeS, HgZnSeTe, HgZnSTe, or the like; or any combination thereof.

Examples of a Group III-V semiconductor compound may include: a binary compound, such as GaN, GaP, GaAs, GaSb, AlN, AIP, AIAs, AISb, InN, InP, InAs, InSb, or the like; a ternary compound, such as GaNP, GaNAs, GaNSb, GaPAs, GaPSb, AlNP, AlNAs, AlNSb, AIPAs, AIPSb, InGaP, InNP, InAIP, InNAs, InNSb, InPAs, InPSb, or the like; a quaternary compound, such as GaAINP, GaAINAs, GaAINSb, GaAIPAs, GaAIPSb, GaInNP, GaInNAs, GalnNSb, GaInPAs, GalnPSb, InAINP, InAINAs, InAINSb, InAIPAs, InAIPSb, or the like; or any combination thereof. In an embodiment, the Group II-V semiconductor compound may further include a Group II element. Examples of a Group III-V semiconductor compound further including a Group II element may include InZnP, InGaZnP, InAIZnP, and the like.

Examples of a Group II-VI semiconductor compound may include: a binary compound, such as GaS, GaSe, Ga₂Se₃, GaTe, InS, InSe, In₂S₃, In₂Se₃, InTe, or the like; a ternary compound, such as InGaS₃, InGaSe₃, or the like; or any combination thereof.

Examples of a Group I-III-VI semiconductor compound may include: a ternary compound, such as AgInS, AgInS₂, AgInSe₂, AgGaS, AgGaS₂, AgGaSe₂, CuInS, CulnS₂, CulnSe₂, CuGaS₂, CuGaSe₂, CuGaO₂, AgGaO₂, AgAIO₂, or the like; a quaternary compound, such as AgInGaS₂, AgInGaSe₂, or the like; or any combination thereof.

Examples of a Group IV-VI semiconductor compound may include: a binary compound, such as SnS, SnSe, SnTe, PbS, PbSe, PbTe, or the like; a ternary compound, such as SnSeS, SnSeTe, SnSTe, PbSeS, PbSeTe, PbSTe, SnPbS, SnPbSe, SnPbTe, or the like; a quaternary compound, such as SnPbSSe, SnPbSeTe, SnPbSTe, or the like; or any combination thereof.

Examples of a Group IV element or compound may include: a single element material, such as Si, Ge, or the like; a binary compound, such as SiC, SiGe, or the like; or any combination thereof.

Each element included in a multi-element compound, such as a binary compound, a ternary compound, and a quaternary compound, may be present in a particle at a uniform concentration or at a non-uniform concentration. For example, the formulae above may indicate types of elements included in the compound, wherein a ratio of elements in the compound may vary. For example, AgInGaS₂ may be AgInₓGa₁₋ₓS₂ (wherein x is a real number between 0 and 1).

In an embodiment, the quantum dot may have a single structure in which the concentration of each element in the quantum dot is uniform, or the quantum dot may have a core-shell structure. In an embodiment in case that the quantum dot has a core-shell structure, a material included in the core and a material included in the shell may be different from each other.

The shell of the quantum dot may serve as a protective layer which prevents chemical denaturation of the core to maintain semiconductor characteristics, and/or may serve as a charging layer which imparts electrophoretic characteristics to the quantum dot. The shell may be single-layered or multi-layered. An interface between the core and the shell may have a concentration gradient in which the concentration of a material that is present in the shell decreases toward the core.

Examples of a shell of the quantum dot may include a metal oxide, a non-metal oxide, a semiconductor compound, or a combination thereof. Examples of a metal oxide or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like; a ternary compound, such as MgAl₂O₄, CoFe₂O₄, NiFe₂O₄, CoMn₂O₄, or the like; or any combination thereof. Examples of a semiconductor compound may include, as described herein: a Group II-VI semiconductor compound; a Group II-VI semiconductor compound; a Group II-V semiconductor compound; a Group II-VI semiconductor compound; a Group 1-II-VI semiconductor compound; a Group IV-VI semiconductor compound; or any combination thereof. Examples of a semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AIAs, AIP, AISb, or any combination thereof.

The quantum dot may have a FWHM of the emission wavelength spectrum of less than or equal to about 45 nm. For example, the quantum dot may have a FWHM of the emission wavelength spectrum of less than or equal to about 40 nm. For example, the quantum dot may have a FWHM of the emission wavelength spectrum of less than or equal to about 30 nm. In case that the FWHM of the quantum dot is within these ranges, the quantum dot may have improved color purity or improved color reproducibility. Light emitted through a quantum dot may be emitted in all directions, so that a wide viewing angle may be improved.

In an embodiment, the quantum dot may be in the form of a spherical particle, a pyramidal particle, a multi-arm particle, a cubic nanoparticle, a nanotube particle, a nanowire particle, a nanofiber particle, a nanoplate particle, or the like.

Since the energy band gap may be controlled by adjusting the size of the quantum dot or the ratio of elements in a quantum dot compound, light of various wavelengths may be obtained from a quantum dot emission layer. Accordingly, by using the quantum dot described above (by using quantum dots of different sizes or by varying the ratio of elements in the quantum dot compound), a light-emitting device emitting light of various wavelengths may be implemented. In an embodiment, the control of a size of the quantum dot or a ratio of elements in the quantum dot compound may be selected to emit red light, green light, and/or blue light. In an embodiment, the size of the quantum dot may be configured to emit white light by a combination of light of various colors.

### [Electron Transport Region 140]

The electron transport region 140 may have a structure consisting of a layer consisting of a single material, a structure consisting of a layer including multiple materials, or a structure including multiple layers including multiple different materials.

The electron transport region 140 may include a buffer layer, a hole blocking layer, an electron control layer, an electron transport layer, an electron injection layer, or any combination thereof.

In an embodiment, the electron transport region 140 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers of each structure may be stacked from the emission layer 130 in its respective stated order, but the structure of the electron transport region is not limited thereto.

The electron transport region 140 (e.g., a buffer layer, a hole blocking layer, an electron control layer, or an electron transport layer in the electron transport region 140) may include a metal-free compound including at least one π electron-deficient nitrogen-containing C₁-C₆₀ cyclic group.

In an embodiment, the electron transport region 140 may include a compound represented by Formula 601:

[Ar₆₀₁]ₓₑ₁₁—[(L₆₀₁)ₓₑ₁—R₆₀₁]ₓₑ₂₁ [Formula 601]

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, in Formula 601, in case that xe11 is 2 or more, two or more of Ar₆₀₁ may be linked to each other via a single bond.

In an embodiment, in Formula 601, Ar₆₀₁ may be an anthracene group unsubstituted or substituted with at least one R₁₀ₐ.

In an embodiment, the electron transport region 140 may include a compound represented by Formula 601-1:

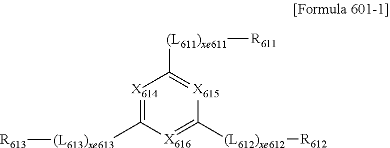

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.
In an embodiment, in Formulae 601 and 601-1, xe1 and xe611 to xe613 may each independently be 0, 1, or 2.
In an embodiment, the electron transport region 140 may include one of Compounds ET1 to ET45, 2,9-dimethyl-4,7-diphenyl-1,10-phenanthroline (BCP), 4,7-diphenyl-1,10-phenanthroline (Bphen), Alq3, BAIq, TAZ, NTAZ, or any combination thereof:

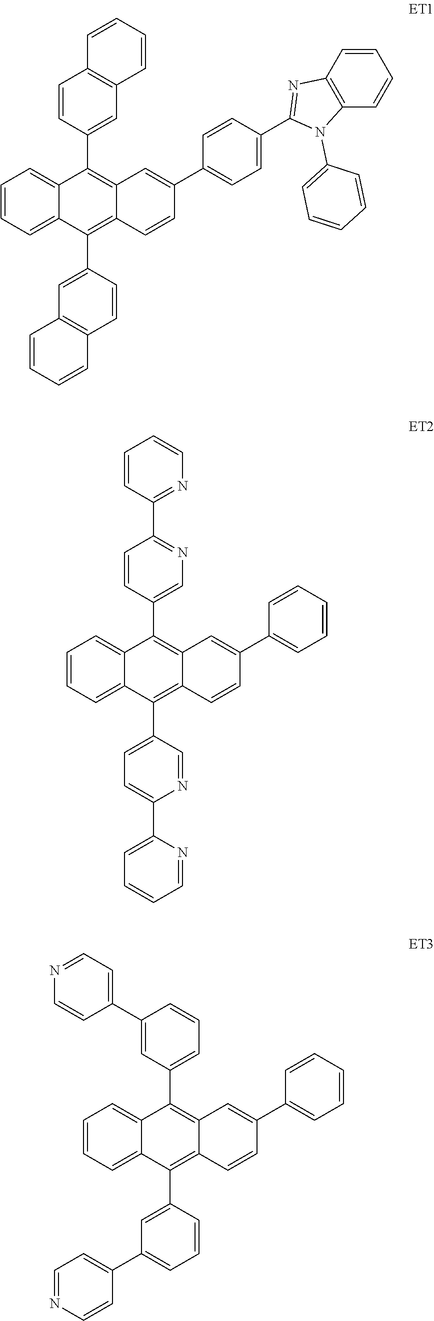 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

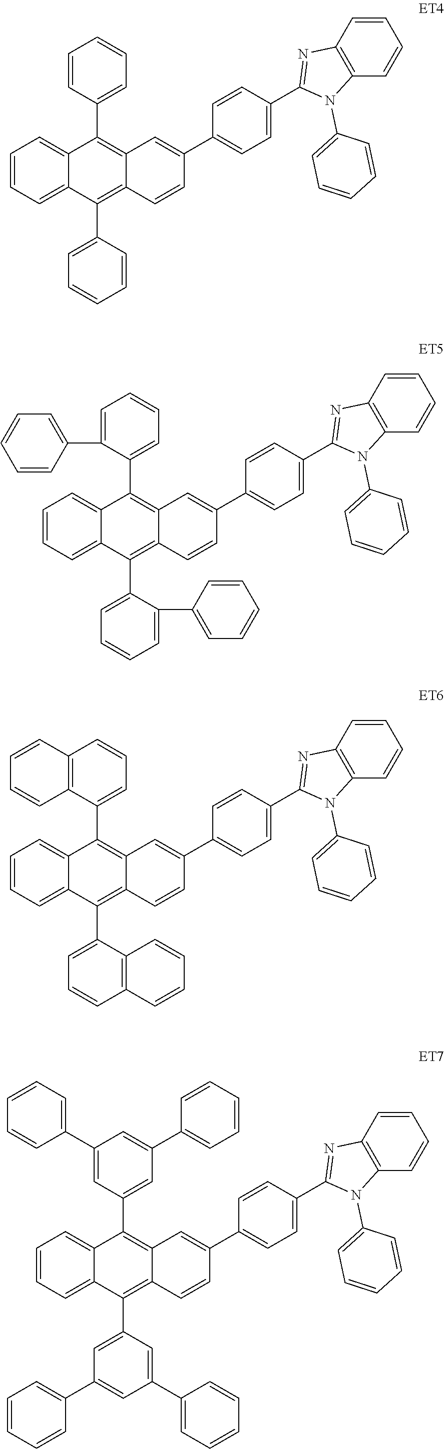 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

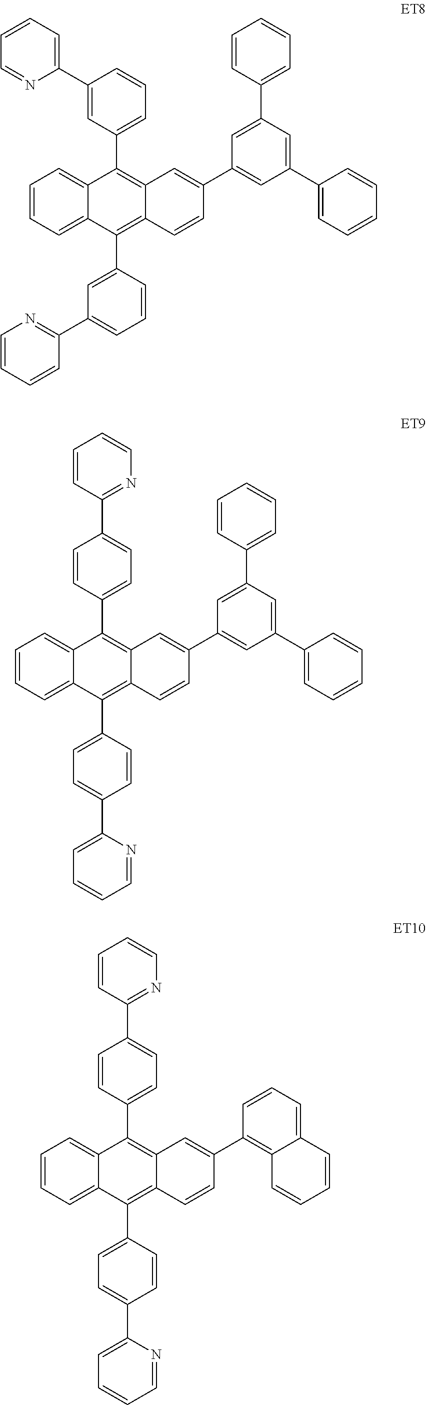

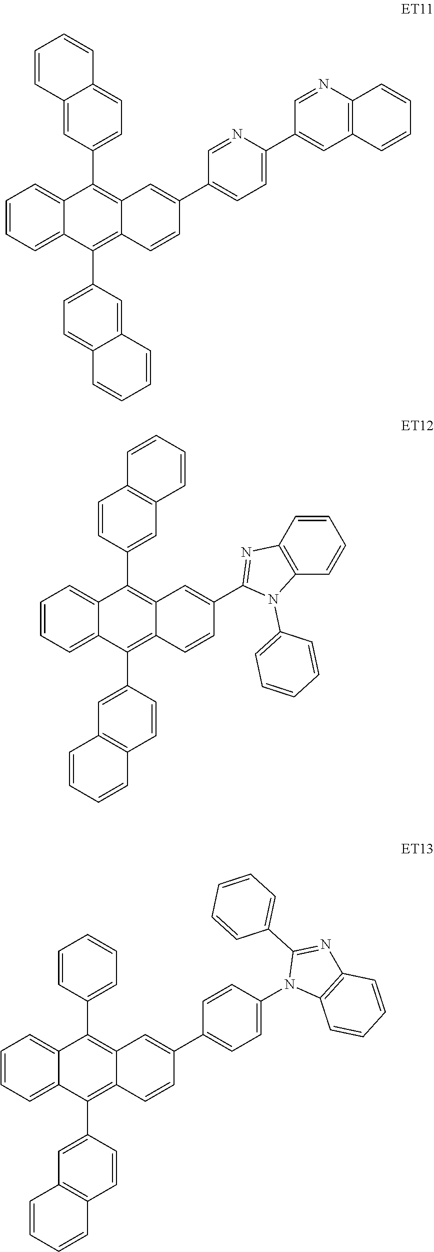 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

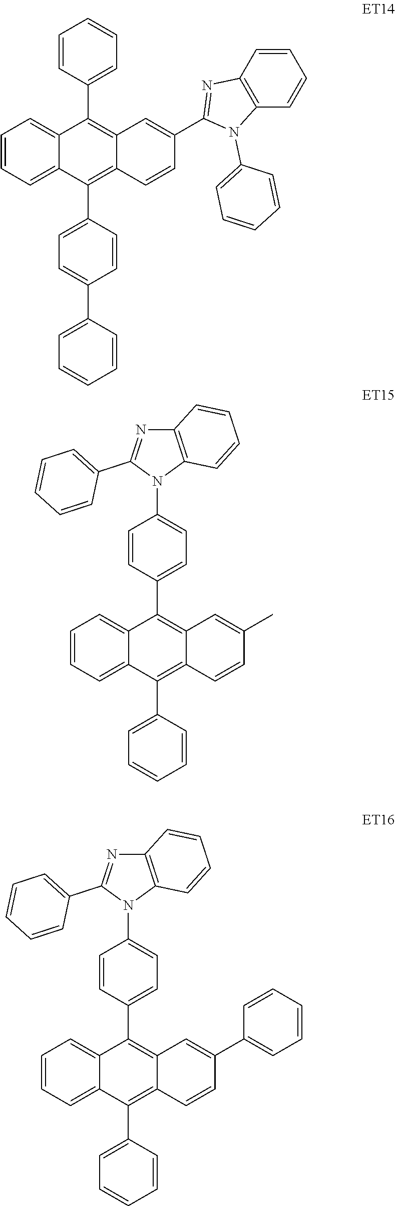 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

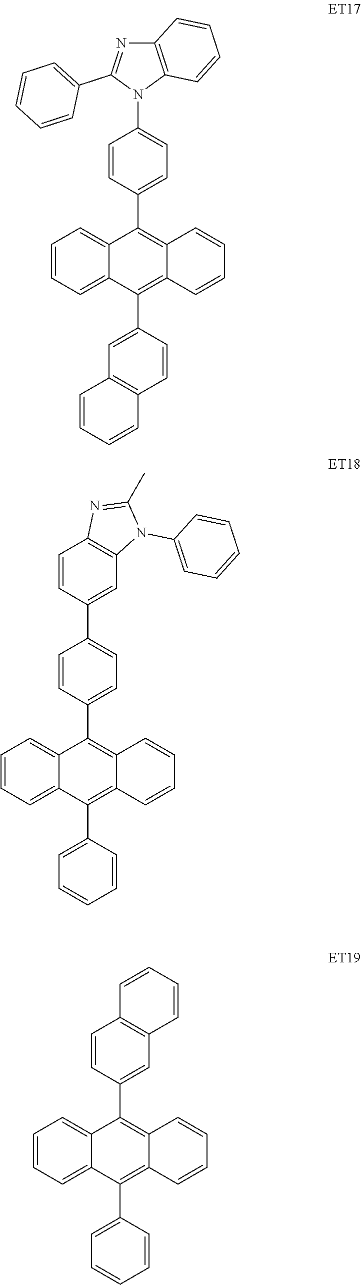

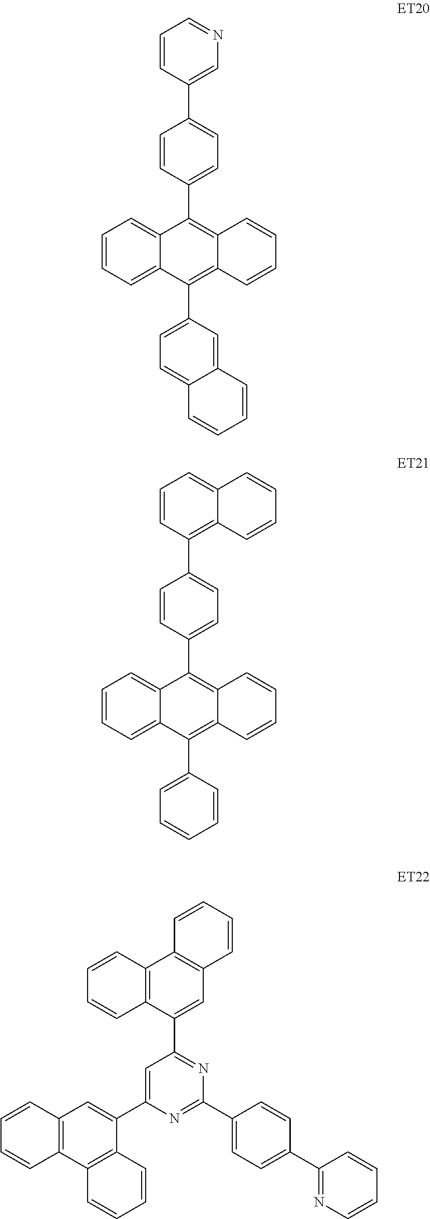

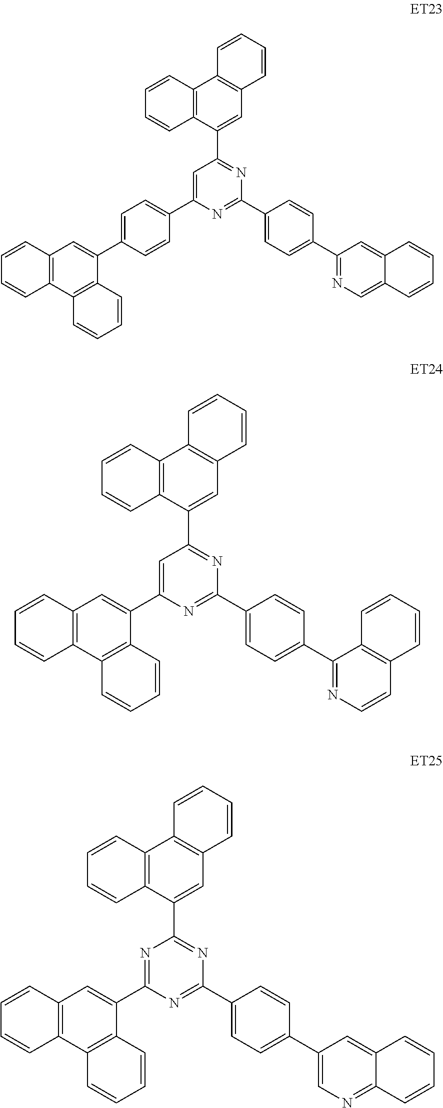 [SMILES: c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

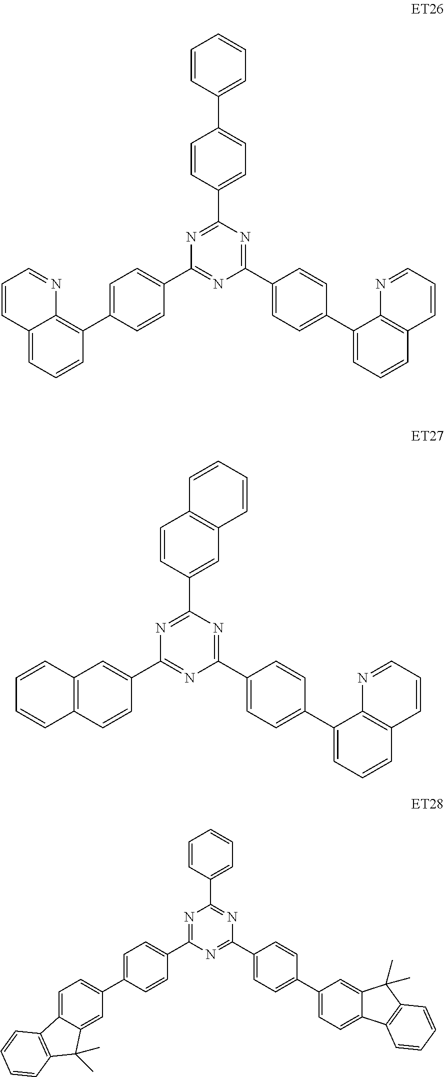 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

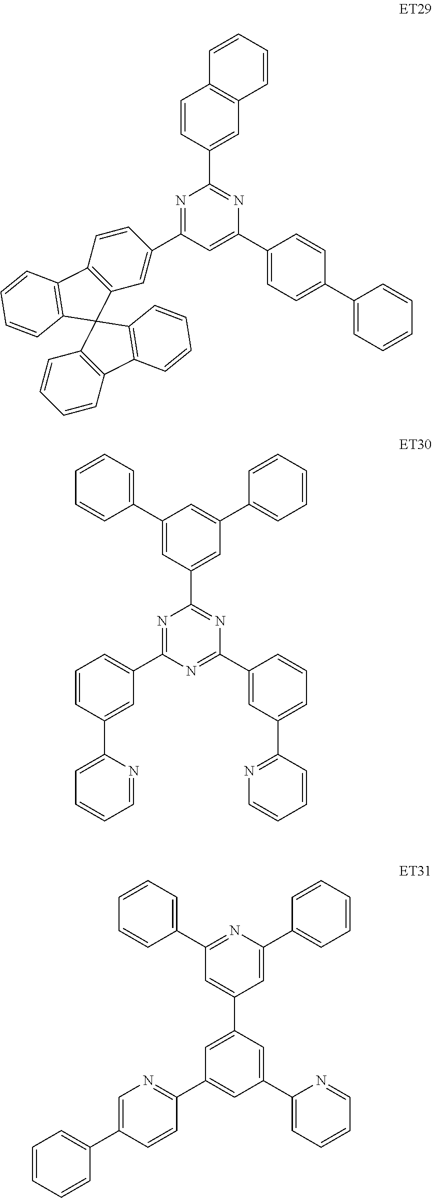 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

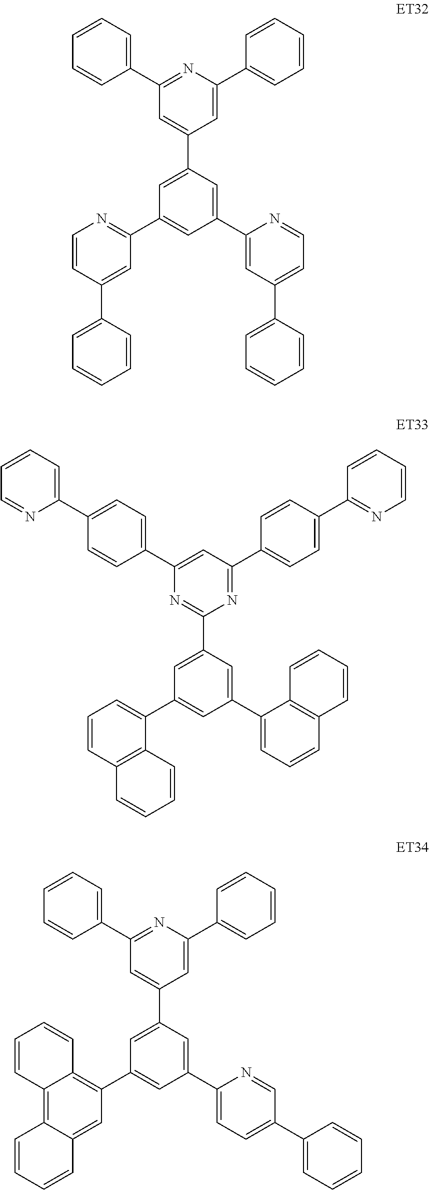 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

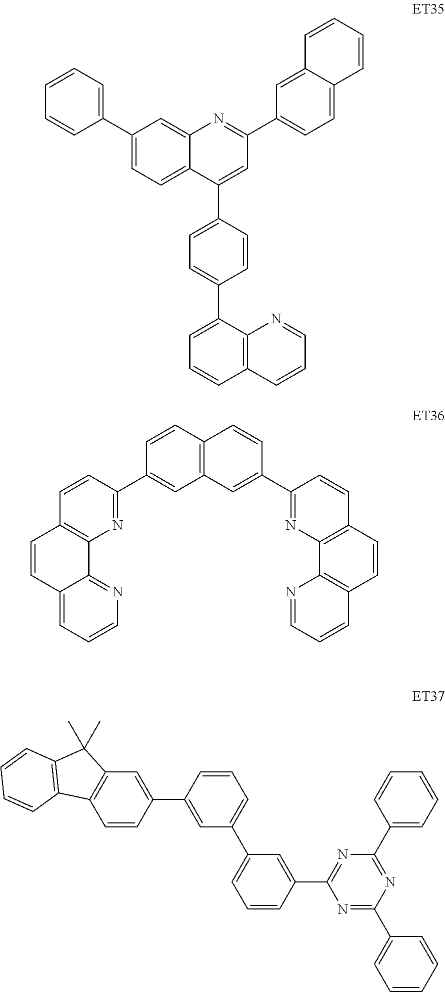

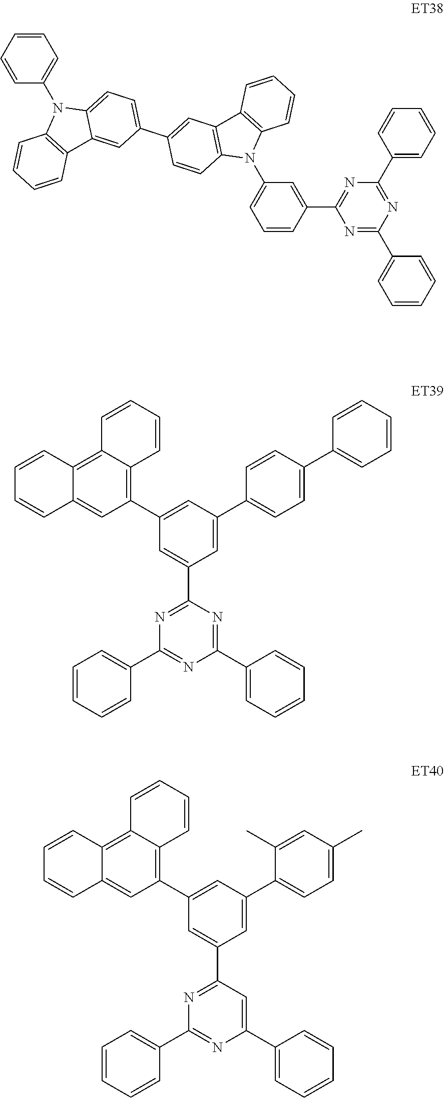 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

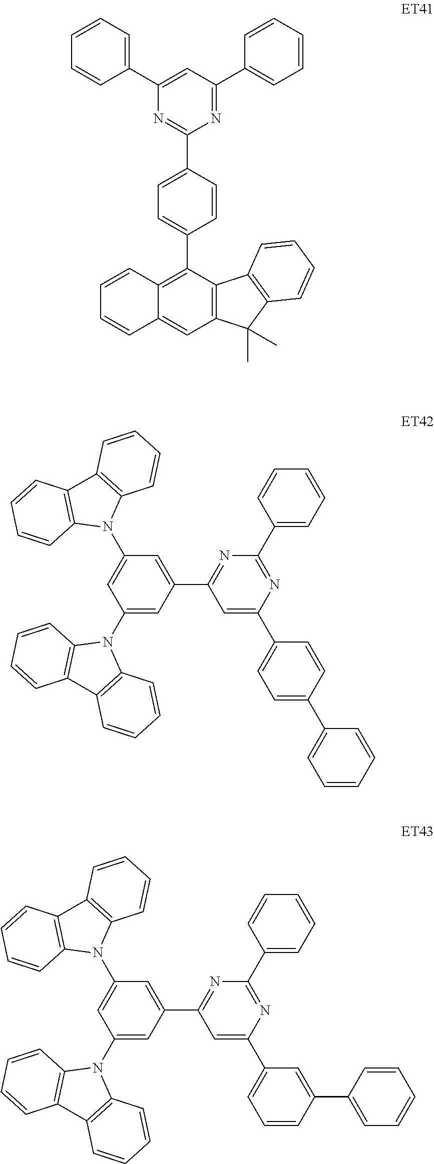 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

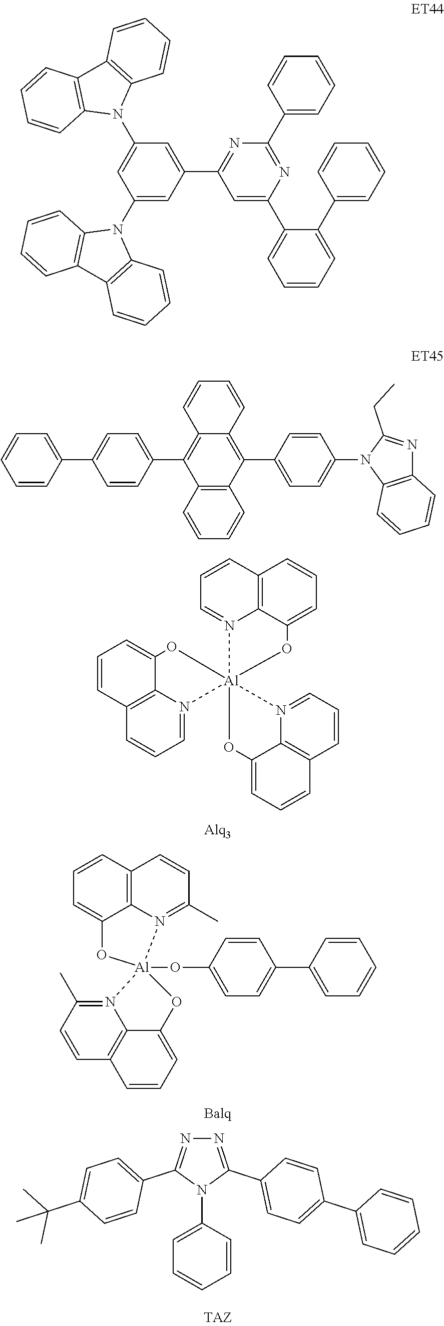

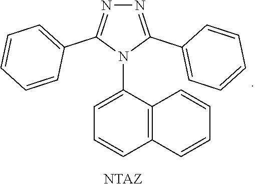 [SMILES: c1ccc(-c2nnc(-c3ccccc3)n2-c2cccc3ccccc23)cc1]

A thickness of the electron transport region 140 may be in a range of about 100 Å to about 5,000 Å. For example, the thickness of the electron transport region 140 may be in a range of about 160 Å to about 4,000 Å. In case that the electron transport region 140 includes a buffer layer, a hole blocking layer, an electron control layer, an electron transport layer, or any combination thereof, a thickness of the buffer layer, the hole blocking layer, or the electron control layer may be in a range of about 20 Å to about 1,000 Å, and the thickness of the electron transport layer may be in a range of about 100 Å to about 1,000 Å. For example, the thickness of the buffer layer, the hole blocking layer, or the electron control layer may each independently be in a range of about 30 Å to about 300 Å. For example, the thickness of the electron transport layer may be in a range of about 150 Å to about 500 Å. In case that the thicknesses of the buffer layer, the hole blocking layer, the electron control layer, the electron transport layer, and/or the electron transport region 140 are within the ranges described above, satisfactory electron transporting characteristics may be obtained without a substantial increase in driving voltage.

The electron transport region 140 (e.g., an electron transport layer in the electron transport region 140) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion.

A ligand coordinated with the metal ion of the alkali metal complex or with the metal ion of the alkaline earth metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

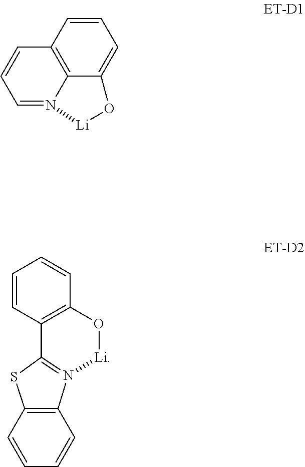

The electron transport region 140 may include an electron injection layer that facilitates injection of electrons from the second electrode 150. The electron injection layer may contact (e.g., directly contact) the second electrode 150.

The electron injection layer may have a structure consisting of a layer consisting of a single material, a structure consisting of a layer including multiple materials, or a structure including multiple layers including multiple materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, iodides, etc.), or tellurides of the alkali metal, the alkaline earth metal, and the rare earth metal, or any combination thereof.

The alkali metal-containing compound may include: an alkali metal oxide, such as Li₂O, Cs₂O, K₂O, or the like; an alkali metal halide, such as LiF, NaF, CsF, KF, Lil, Nal, Csl, KI, or the like; or any combination thereof. The alkaline earth metal-containing compound may include an alkaline earth metal compound, such as BaO, SrO, CaO, BaxSri-xO (wherein x is a real number satisfying 0<x<1), BaxCai-xO (wherein x is a real number satisfying 0<x<1), or the like. The rare earth metal-containing compound may include YbF₃, ScF₃, Sc₂O₃, Y₂O₃, Ce₂O₃, GdF₃, TbF₃, Ybl₃, Scl₃, Tbl₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include an alkali metal ion, an alkaline earth metal ion, or a rare earth metal ion and a ligand bonded to the metal ion, (for example, a hydroxyquinoline, a hydroxyisoquinoline, hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof).

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (e.g., a compound represented by Formula 601).

In an embodiment, the electron injection layer may consist of an alkali metal-containing compound (e.g., an alkali metal halide); or the electron injection layer may consist of an alkali metal-containing compound (e.g., an alkali metal halide), and an alkali metal, an alkaline earth metal, a rare earth metal, or any combination thereof. For example, the electron injection layer may be a KI:Yb co-deposited layer, an Rbl:Yb co-deposited layer, a LiF:Yb co-deposited layer, or the like.

In case that the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. In case that the thickness of the electron injection layer is within the ranges described above, satisfactory electron injection characteristics may be obtained without a substantial increase in driving voltage.

### [Second Electrode 150]

The second electrode 150 may be arranged on the electron transport region 140. The second electrode 150 may be a cathode, which is an electron injection electrode. A material for forming the second electrode 150 may be a material having a low work function, such as a metal, an alloy, an electrically conductive compound, or any combination thereof.

The second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layer structure or a multi-layer structure.

### [Capping Layer]

The light-emitting device 10 may further include a capping layer arranged outside the first electrode 110 and/or the second electrode 150.

In an embodiment, the capping layer may include the quantum dot described above.

In an embodiment, the light-emitting device 10 may further include a first capping layer arranged outside the first electrode 110. The first capping layer may include the quantum dot described above.

In an embodiment, the light-emitting device 10 may further include a second capping layer arranged outside the second electrode 150. The second capping layer may include the quantum dot described above.

In an embodiment, the light-emitting device 10 may further include a first capping layer arranged outside the first electrode 110 and a second capping layer arranged outside the second electrode 150. At least one of the first capping layer and the second capping layer may include the quantum dot described above.

Light generated in the emission layer 130 in the light-emitting device 10 may be extracted toward the outside through the first electrode 110, which may be a transflective electrode or a transmissive electrode, and through the first capping layer.

Light generated in the emission layer 130 in the light-emitting device 10 may be extracted toward the outside through the second electrode 150, which may be a transflective electrode or a transmissive electrode, and through the second capping layer.

The first capping layer and the second capping layer may each increase external emission efficiency according to the principle of constructive interference.

Accordingly, the light extraction efficiency of the light-emitting device 10 may be increased, and thus, the luminescence efficiency of the light-emitting device 10 may be improved.

The first capping layer and the second capping layer may each include a material having a refractive index greater than or equal to about 1.2 (with respect to a wavelength of about 460 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In an embodiment, at least one of the first capping layer and the second capping layer may each independently include one of Compounds HT28 to HT33, one of Compounds CP1 to CP6, p-NPB, or any combination thereof:

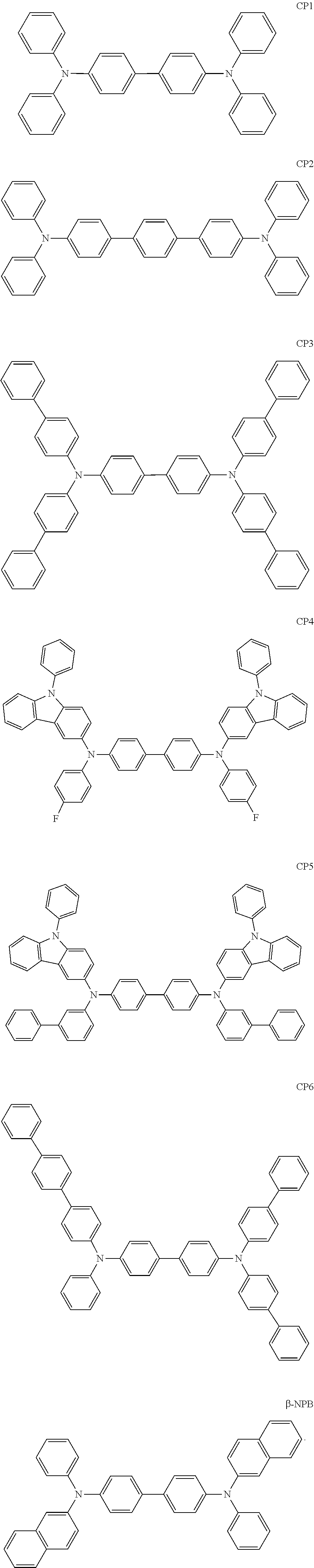

### [Film]

The electronic apparatus may further include a film. The film may be, for example, an optical member (or a light control means) (e.g., a color filter, a color conversion layer, a capping layer, a light extraction efficiency enhancement layer, a selective light absorbing layer, a polarizing layer, a quantum dot-containing layer, etc.), a light blocking member (e.g., a light reflective layer, a light absorbing layer, etc.), a protective member (e.g., an insulating layer, a dielectric layer, etc.), or the like. The quantum dot described above may be included in a color conversion layer, a capping layer, a selective light absorbing layer, a quantum dot-containing layer, and the like.

### [Electronic Apparatus]

The light-emitting device 10 may be included in various electronic apparatuses. In an embodiment, the electronic apparatus including the light-emitting device 10 may be a display apparatus, an authentication apparatus, or the like.

The electronic apparatus (e.g., a display apparatus) may further include, in addition to the light-emitting device 10, a color filter, a color conversion layer, or a color filter and a color conversion layer. The color filter and/or the color conversion layer may be arranged in at least one direction of travel of light emitted from the light-emitting device 10. In an embodiment, the light emitted from the light-emitting device 10 may be blue light or white light. Details on the light-emitting device 10 are the same as described herein. In an embodiment, the color conversion layer may include a quantum dot. The quantum dot may be, for example, the quantum dot as described herein.

The electronic apparatus may include a first substrate. The first substrate may include multiple subpixels, the color filter may include multiple color filter areas respectively corresponding to the subpixels, and the color conversion layer may include multiple color conversion areas respectively corresponding to the subpixels.

A pixel-defining film may be arranged between the subpixels to define each subpixels.

The color filter may further include multiple color filter areas and light-shielding patterns arranged between the color filter areas, and the color conversion layer may further include multiple color conversion areas and light-shielding patterns arranged between the color conversion areas.

The color filter areas (or the color conversion areas) may include a first area emitting first color light, a second area emitting second color light, and/or a third area emitting third color light, wherein the first color light, the second color light, and/or the third color light may have different maximum emission wavelengths from one another. For example, the first color light may be red light, the second color light may be green light, and the third color light may be blue light. For example, the color filter areas (or the color conversion areas) may include quantum dots. For example, the first area may include a red quantum dot, the second area may include a green quantum dot, and the third area may not include a quantum dot. Details on the quantum dots are the same as described herein. The first area, the second area, and/or the third area may each further include a scatter.

In an embodiment, the light-emitting device may emit first light, the first area may absorb the first light to emit first-1 color light, the second area may absorb the first light to emit second-1 color light, and the third area may absorb the first light to emit third-1 color light. In this regard, the first-1 color light, the second-1 color light, and the third-1 color light may have different maximum emission wavelengths from one another. In detail, the first light may be blue light, the first-1 color light may be red light, the second-1 color light may be green light, and the third-1 color light may be blue light.

The electronic apparatus may further include a thin-film transistor, in addition to the light-emitting device 10. The thin-film transistor may include a source electrode, a drain electrode, and an active layer, wherein one of the source electrode and the drain electrode may be electrically connected to one of the first electrode and the second electrode of the light-emitting device 10.

The thin-film transistor may further include a gate electrode, a gate insulating film, and the like.

The active layer may include crystalline silicon, amorphous silicon, an organic semiconductor, an oxide semiconductor, or the like.

The electronic apparatus may further include a sealing portion for sealing the light-emitting device 10. The sealing portion may be arranged between the color filter and/or the color conversion layer and the light-emitting device 10. The sealing portion may allow light from the light-emitting device 10 to be extracted to the outside, and may simultaneously prevent ambient air and moisture from penetrating into the light-emitting device 10. The sealing portion may be a sealing substrate including a transparent glass substrate or a plastic substrate. The sealing portion may be a thin-film encapsulation layer including an organic layer and/or an inorganic layer. In case that the sealing portion is a thin-film encapsulation layer, the electronic apparatus may be flexible.

Various functional layers may be further included on the sealing portion, in addition to the color filter and/or the color conversion layer, according to the use of the electronic apparatus. Examples of a functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (e.g., fingertips, pupils, etc.).

The authentication apparatus may further include, in addition to the light-emitting device described above, a biometric information collector.

The electronic apparatus may be applied to various displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (e.g., meters for a vehicle, an aircraft, and a vessel), projectors, and the like.

### [Electronic Equipment]

The light-emitting device 10 may be included in various electronic equipment. For example, the electronic apparatus including the light-emitting device 10 may be included in various electronic equipment.

In an embodiment, an electronic equipment including the light-emitting device 10 may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a PDA, a wearable device, a laptop computer, a digital camera, a camcorder, a viewfinder, a micro display, a 3D display, a virtual reality display, an augmented reality display, a vehicle, a video wall with multiple displays tiled together, a theater screen, a stadium screen, a phototherapy device, or a signboard.

Since the quantum dot has excellent blue light absorption rate, small emission FWHM, long decay time, and high stability, an electronic equipment including the light-emitting device 10 may have characteristics such as high luminance, high resolution, and low power consumption.

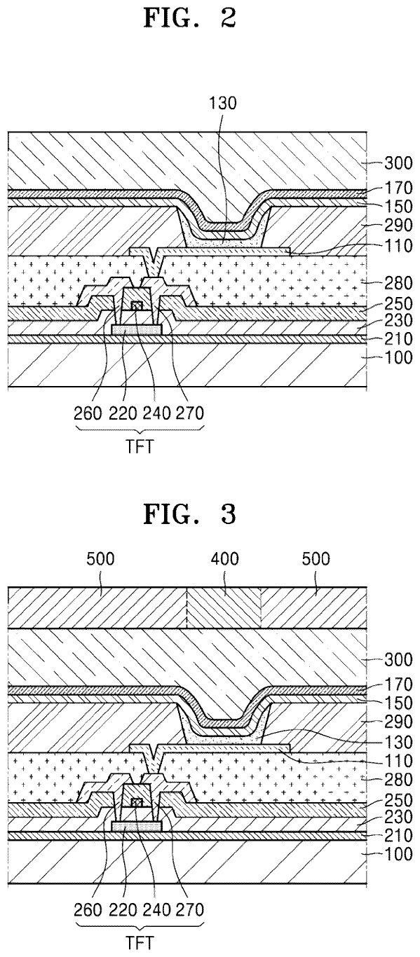

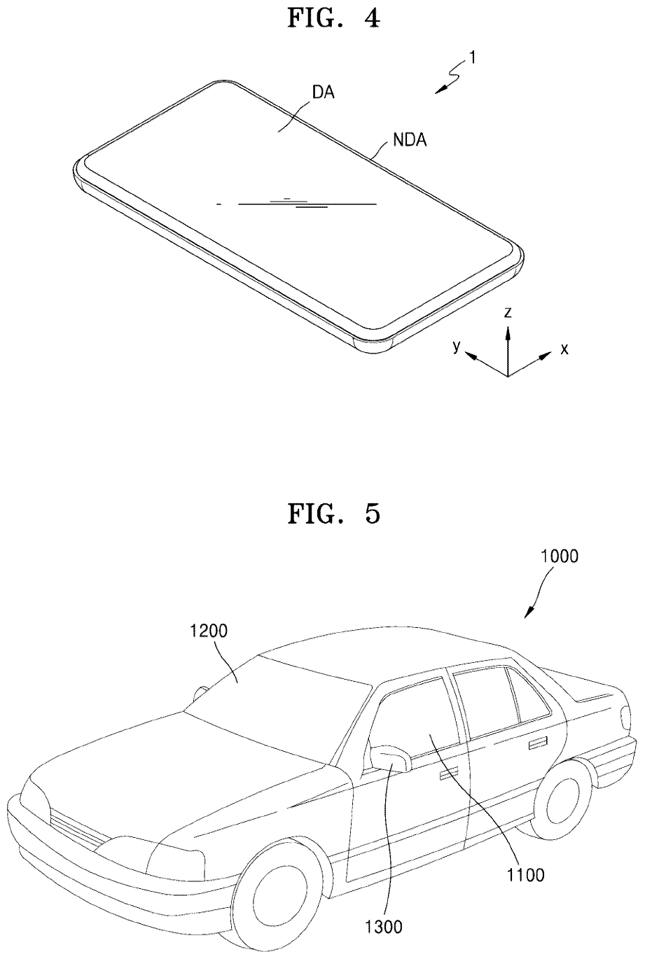

### [Descriptions of FIGS. 2 and 3]

FIG. 2 is a schematic cross-sectional view of an electronic apparatus according to an embodiment.

The electronic apparatus of FIG. 2 may include a substrate 100, a thin-film transistor (TFT), a light-emitting device, and an encapsulation portion 300.

The substrate 100 may be a flexible substrate, a glass substrate, or a metal substrate. A buffer layer 210 may be arranged on the substrate 100. The buffer layer 210 may prevent penetration of impurities through the substrate 100, and may provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 and between the gate electrode 240 and the drain electrode 270, to insulate from one another.

The source electrode 260 and the drain electrode 270 may be arranged on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided on the passivation layer 280. The light-emitting device may include the first electrode 110, the interlayer, and the second electrode 150.

The first electrode 110 may be arranged on the passivation layer 280. The passivation layer 280 may be arranged to expose a portion of the drain electrode 270, not fully covering the drain electrode 270. The first electrode 110 may be electrically connected to the exposed portion of the drain electrode 270.

A pixel-defining film 290 including an insulating material may be arranged on the first electrode 110. The pixel-defining film 290 may expose a certain region of the first electrode 110, and the interlayer may be formed in the exposed region of the first electrode 110. The pixel-defining film 290 may be a polyimide-based organic film or a polyacrylic organic film. Although not shown in FIG. 2, at least some layers of the interlayer may extend beyond the upper portion of the pixel-defining film 290 to be provided in the form of a common layer.

The second electrode 150 may be arranged on the interlayer, and a capping layer 170 may be further included on the second electrode 150. The capping layer 170 may cover the second electrode 150.

The encapsulation portion 300 may be arranged on the capping layer 170. The encapsulation portion 300 may be arranged on a light-emitting device to protect the light-emitting device from moisture and/or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy-based resin (e.g., aliphatic glycidyl ether (AGE), etc.), or any combination thereof; or any combination of the inorganic film and the organic film.

FIG. 3 is a schematic cross-sectional view of an electronic apparatus according to another embodiment.

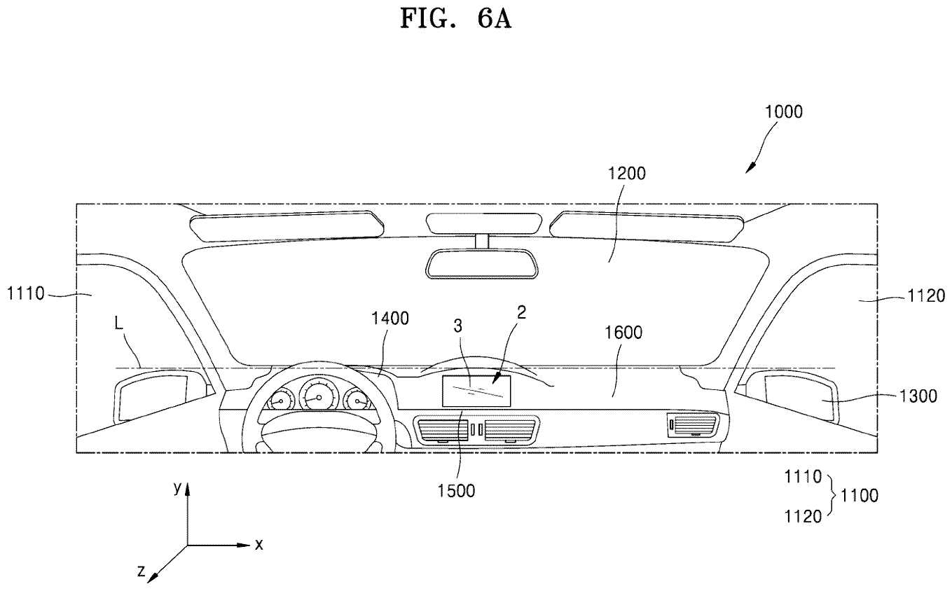

The electronic apparatus of FIG. 3 may differ from the electronic apparatus of FIG. 2, at least in that a light-shielding pattern 500 and a functional region 400 are further included on the encapsulation portion 300. The functional region 400 may be a color filter area, a color conversion area, or a combination of the color filter area and the color conversion area. In an embodiment, the light-emitting device included in the electronic apparatus of FIG. 3 may be a tandem light-emitting device.

[Description of FIG. 4]

FIG. 4 is a schematic perspective view of electronic equipment 1 including a light-emitting device according to an embodiment. The electronic equipment 1 may be, as an apparatus that displays a moving image or a still image, not only portable electronic equipment, such as a mobile phone, a smartphone, a tablet personal computer (PC), a mobile communication terminal, an electronic notebook, an electronic book, a portable multimedia player (PMP), a navigation, or a ultra-mobile PC (UMPC), but may also be various products, such as a television, a laptop computer, a monitor, a billboard, or an Internet of things (loT) device. The electronic equipment 1 may be such a product above or a part thereof. The electronic equipment 1 may be a wearable device, such as a smart watch, a watch phone, a glasses-type display, or a head mounted display (HMD), or a part of the wearable device. However, embodiments are not limited thereto. For example, the electronic equipment 1 may be a center information display (ClD) on an instrument panel and a center fascia or dashboard of a vehicle, a room mirror display instead of a side mirror of a vehicle, an entertainment display for a rear seat of a vehicle, a display arranged on the back of a front seat, a head up display (HUD) installed in the front of a vehicle or projected on a front window glass, or a computer generated hologram augmented reality head up display (CGH AR HUD). FIG. 4 illustrates an embodiment in which the electronic equipment 1 is a smartphone for convenience of explanation.

The electronic equipment 1 may include a display area DA and a non-display area NDA outside the display area DA. The electronic equipment 1 may implement an image through a two-dimensional array of pixels that are arranged in the display area DA.

The non-display area NDA is an area that does not display an image, and may surround the display area DA. In the non-display area NDA, a driver for providing electrical signals or power to display devices arranged on the display area DA may be arranged. In the non-display area NDA, a pad, which is an area to which an electronic element or a printed circuit board may be electrically connected, may be arranged.

In the electronic equipment 1, a length in the x-axis direction and a length in the y-axis direction may be different from each other. In an embodiment, as shown in FIG. 4, the length in the x-axis direction may be less than the length in the y-axis direction. In an embodiment, the length in the x-axis direction may be the same as the length in the y-axis direction. In an embodiment, the length in the x-axis direction may be greater than the length in the y-axis direction.

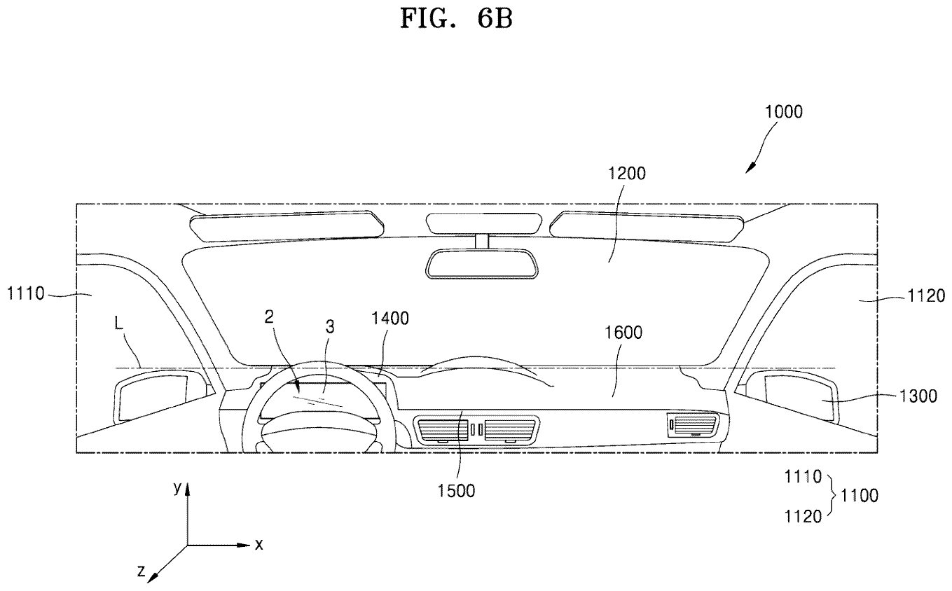

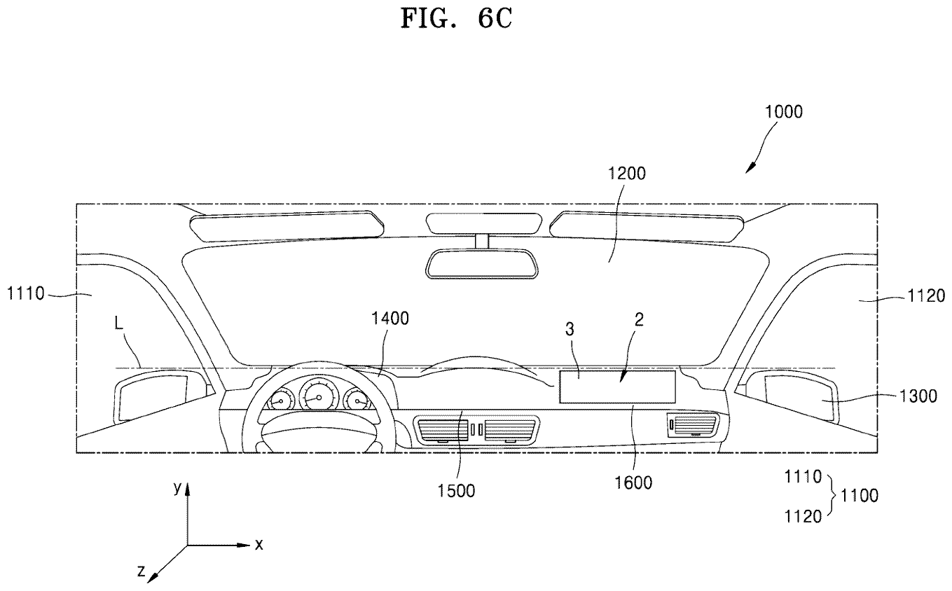

### [Descriptions of FIGS. 5 and 6A to 6C]

FIG. 5 is a schematic perspective view of an exterior of a vehicle 1000 as electronic equipment including a light-emitting device according to an embodiment. FIGS. 6A to 6C are each a schematic diagram of an interior of a vehicle 1000 according to embodiments.

Referring to FIGS. 5, 6A, 6B, and 6C, the vehicle 1000 may refer to various apparatuses for moving a subject to be transported, such as a human, an object, or an animal, from a departure point to a destination point. Examples of the vehicle 1000 may include a vehicle traveling on a road or track, a vessel moving over a sea or river, an airplane flying in the sky using the action of air, and the like.

The vehicle 1000 may travel on a road or a track. The vehicle 1000 may move in a given direction according to the rotation of at least one wheel. Examples of the vehicle 1000 may include a three-wheeled or four-wheeled vehicle, a construction machine, a two-wheeled vehicle, a prime mover device, a bicycle, and a train running on a track.

The vehicle 1000 may include a body of the vehicle 1000 having an interior and an exterior, and a chassis that is a portion excluding the body in which mechanical apparatuses for driving are installed. The exterior of the body of the vehicle 1000 may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front and rear wheels, left and right wheels, and the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on the side of the vehicle 1000. In an embodiment, the side window glass 1100 may be installed in a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400, and the second side window glass 1120 may be arranged adjacent to the passenger seat dashboard 1600.

In an embodiment, the side window glasses 1100 may be spaced apart from each other in an x-direction or an −x-direction. For example, the first side window glass 1110 and the second side window glass 1120 may be spaced apart from each other in the x-direction or in the −x-direction. For example, an imaginary straight line L connecting the side window glasses 1100 may extend in the x-direction or in the −x-direction. For example, an imaginary straight line L connecting the first side window glass 1110 and the second side window glass 1120 to each other may extend in the x-direction or in the −x-direction.

The front window glass 1200 may be installed on the front of the vehicle 1000. The front window glass 1200 may be arranged between the side window glasses 1100 facing each other.

The side mirror 1300 may provide a rear view of the vehicle 1000. The side mirror 1300 may be installed on the exterior of the body of the vehicle 1000. In an embodiment, multiple side mirrors 1300 may be provided. One of the side mirrors 1300 may be arranged outside the first side window glass 1110. Another one of the side mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which buttons for adjusting an audio device, an air conditioning device, and a seat heater are arranged. The center fascia 1500 may be arranged on a side of the cluster 1400.

The passenger seat dashboard 1600 may be spaced apart from the cluster 1400, and the center fascia 1500 may be arranged between the cluster 1400 and the passenger seat dashboard 1600. In an embodiment, the cluster 1400 may be arranged to correspond to a driver seat (not shown), and the passenger seat dashboard 1600 may be arranged to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display apparatus 2 may include a display panel 3, and the display panel 3 may display an image. The display apparatus 2 may be arranged inside the vehicle 1000. In an embodiment, the display apparatus 2 may be arranged between the side window glasses 1100 facing each other. The display apparatus 2 may be arranged in at least one of the cluster 1400, the center fascia 1500, and the passenger seat dashboard 1600.

The display apparatus 2 may include an organic light-emitting display apparatus, an inorganic light-emitting display apparatus, a quantum dot display apparatus, or the like. Hereinafter, as the display apparatus 2 according to an embodiment, an organic light-emitting display apparatus including the light-emitting device according to an embodiment will be described as an example, but various types of display apparatuses as described herein may be used as embodiments.

Referring to FIG. 6A, the display apparatus 2 may be arranged in the center fascia 1500. In an embodiment, the display apparatus 2 may display navigation information. In an embodiment, the display apparatus 2 may display information regarding audio settings, video settings, or vehicle settings.

Referring to FIG. 6B, the display apparatus 2 may be arranged on the cluster 1400. In an embodiment, the cluster 1400 may display driving information and the like through the display apparatus 2. For example, the cluster 1400 may digitally implement driving information and the like. The cluster 1400 may digitally display vehicle information and driving information as images. For example, a needle and a gauge of a tachometer and various warning lights or icons may be displayed by a digital signal.

Referring to FIG. 6C, the display apparatus 2 may be arranged in the passenger seat dashboard 1600. The display apparatus 2 may be embedded in the passenger seat dashboard 1600 or arranged on the passenger seat dashboard 1600. In an embodiment, the display apparatus 2 arranged on the passenger seat dashboard 1600 may display an image related to information displayed on the cluster 1400 and/or information displayed on the center fascia 1500. In an embodiment, the display apparatus 2 arranged on the passenger seat dashboard 1600 may display information that is different from information displayed on the cluster 1400 and/or information displayed on the center fascia 1500.

### [Manufacturing Method]

The layers constituting the hole transport region 120, the emission layer 130, and the layers constituting the electron transport region 140 may be formed in a selected region by using various methods such as vacuum deposition, spin coating, casting, Langmuir-Blodgett (LB) deposition, ink-jet printing, laser-printing, laser-induced thermal imaging, and the like.

In case that the layers constituting the hole transport region 120, the emission layer 130, and the layers constituting the electron transport region 140 are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/see, depending on a material to be included in a layer to be formed and the structure of a layer to be formed.

[Definition of Terms]

The term “C₃-C₆₀ carbocyclic group” as used herein may be a cyclic group consisting of carbon atoms as the only ring-forming atoms and having 3 to 60 carbon atoms.

The term “C₁-C₆₀ heterocyclic group” as used herein may be a cyclic group that has 1 to 60 carbon atoms and further has, in addition to a carbon atom, at least one heteroatom as a ring-forming atom.

The C₃-C₆₀ carbocyclic group and the C₁-C₆₀ heterocyclic group may each be a monocyclic group consisting of one ring or a polycyclic group in which two or more rings are condensed with each other. For example, a number of ring-forming atoms of the C₁-C₆₀ heterocyclic group may be from 3 to 61.

The term “cyclic group” as used herein may be a C₃-C₆₀ carbocyclic group or a C₁-C₆₀ heterocyclic group.

The term “π electron-rich C₃-C₆₀ cyclic group” as used herein may be a cyclic group that has 3 to 60 carbon atoms and may not include *—N═*′ as a ring-forming moiety.

The term “π electron-deficient nitrogen-containing C₁-C₆₀ cyclic group” as used herein may be a heterocyclic group that has 1 to 60 carbon atoms and may include *—N═*′ as a ring-forming moiety.

In an embodiment,

a C₃-C₆₀ carbocyclic group may be a T1 Group or a group in which two or more T1 Groups are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group), and

a C₁-C₆₀ heterocyclic group may be a T2 Group, a group in which two or more T2 Groups are condensed with each other, or a group in which at least one T2 Group and at least one T1 Group are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, a xanten group, etc.).

A π electron-rich C₃-C₆₀ cyclic group may be a T1 Group, a group in which two or more T1 Groups are condensed with each other, a T3 Group, a group in which two or more T3 Groups are condensed with each other, or a group in which at least one T3 Group and at least one T1 Group are condensed with each other (e.g., a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.).

A π electron-deficient nitrogen-containing C₁-C₆₀ cyclic group may be a T4 Group, a group in which two or more T4 Groups are condensed with each other, a group in which at least one T4 Group and at least one T1 Group are condensed with each other, a group in which at least one T4 Group and at least one T3 Group are condensed with each other, or a group in which at least one T4 Group, at least one T1 Group, and at least one T4 Group are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.).

T1 Group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

T2 Group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

T3 Group may be a furan group, a thiophene group, a 1H-pyrrole group, a silole group, or a borole group.

T4 Group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group,” “C₃-C₆₀ carbocyclic group,” “C₁-C₆₀ heterocyclic group,” “π electron-rich C₃-C₆₀ cyclic group,” and “π electron-deficient nitrogen-containing C₁-C₆₀ cyclic group” as used herein may each be to a group condensed to any cyclic group, a monovalent group, or a polyvalent group (for example, a divalent group, a trivalent group, a tetravalent group, or the like) according to the structure of a formula for which the corresponding term is used.

For example, a “benzene group” may be a benzo group, a phenyl group, a phenylene group, or the like, which may be readily understood by one of ordinary skill in the art according to the structure of a formula including the “benzene group.”

Examples of a monovalent C₃-C₆₀ carbocyclic group and a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched aliphatic hydrocarbon monovalent group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like.

The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like.

The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like.

The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —OA₁₀₁ (wherein A₁₀₁ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like.

The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group of 1 to 10 carbon atoms, further including, in addition to a carbon atom, at least one heteroatom as a ring-forming atom, and examples thereof may include a 1,2,3,4-oxatriazolidinyl group, a tetrahydrofuranyl group, a tetrahydrothiophenyl group, and the like.

The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms and at least one carbon-carbon double bond in the ring thereof and no aromaticity, and examples thereof may include a cyclopentenyl group, a cyclohexenyl group, a cycloheptenyl group, and the like.

The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group that has 1 to 10 carbon atoms, further includes, in addition to a carbon atom, at least one heteroatom as a ring-forming atom, and has at least one double bond in the ring thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like.

The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms.

The term “C₆-C₆₀ arylene group” as used herein may be a divalent group having a carbocyclic aromatic system of 6 to 60 carbon atoms.

Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like.

In case that the C₆-C₆₀ aryl group and the C₆-C₆₀ arylene group each include two or more rings, the respective two or more rings may be condensed with each other.

The term “C₁-C₆₀ heteroaryl group” as used herein may be a monovalent group having a heterocyclic aromatic system of 1 to 60 carbon atoms, further including, in addition to carbon atoms, at least one heteroatom, as ring-forming atoms.

The term “C₁-C₆₀ heteroarylene group” as used herein may be a divalent group having a heterocyclic aromatic system of 1 to 60 carbon atoms, further including, in addition to carbon atoms, at least one heteroatom, as ring-forming atoms.

Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like.

In case that the C₁-C₆₀ heteroaryl group and the C₁-C₆₀ heteroarylene group each include two or more rings, the respective two or more rings may be condensed with each other.

The term “monovalent non-aromatic condensed polycyclic group” as used herein may be a monovalent group (e.g., having 8 to 60 carbon atoms) having two or more rings condensed to each other, only carbon atoms as ring-forming atoms, and no aromaticity in its entire molecular structure. Examples of a monovalent non-aromatic condensed polycyclic group may include an indenyl group, a fluorenyl group, a spiro-bifluorenyl group, a benzofluorenyl group, an indenophenanthrenyl group, an indenoanthracenyl group, and the like.

The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group (e.g., having 1 to 60 carbon atoms) having two or more rings condensed to each other, further including, in addition to a carbon atom, at least one heteroatom as a ring-forming atom, and having no aromaticity in its entire molecular structure. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like.

The term “divalent non-aromatic condensed heteropolycyclic group” as used herein may be a divalent group having a same structure as the monovalent non-aromatic condensed heteropolycyclic group.

The term “C₆-C₆o aryloxy group” as used herein may be a group represented by —O(A₁₀₂) (wherein A₁₀₂ may be a C₆-C₆₀ aryl group).

The term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by —(A₁₀₄)(A₁₀₅) (wherein A₁₀₄ may be a C₁-C₅₄ alkylene group, and A₁₀₅ may be a C₆-C₅₉ aryl group).

The term “C₂-C₆₀ heteroarylalkyl group” as used herein may be a group represented by —(A₁₀₆)(A₁₀₇) (wherein A₁₀₆ may be a C₁-C₅₉ alkylene group, and A₁₀₇ may be a C₁-C₅₉ heteroaryl group).

In the specification, “R₁₀ₐ” may be:
Deuterium (—D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; C₁-C₆₀ alkyl group; C₂-C₆₀ alkenyl group; C₂-C₆₀ alkynyl group; C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, or any combination thereof.

The term “third-row transition metal” as used herein may be hafnium (Hf), tantalum (Ta), tungsten (W), rhenium (Re), osmium (Os), iridium (Ir), platinum (Pt), gold (Au), or the like.

The term “D” may be deuterium, the term “Ph” may be a phenyl group, the term “Me” may be a methyl group, the term “Et” may be an ethyl group, the terms “tert-Bu,” “^{t}Bu,” or “Bu^{t}” may each be a tert-butyl group, and the term “OMe” may be a methoxy group.

The term “biphenyl group” as used herein may be a “phenyl group substituted with a phenyl group.” For example, the “biphenyl group” may be a substituted phenyl group having a C₆-C₆₀ aryl group as a substituent.

The term “terphenyl group” as used herein may be a “phenyl group substituted with a biphenyl group.” The “terphenyl group” may be a “substituent phenyl group“which is a” C₆-C₆₀ aryl group in which a substituent is substituted with a C₆-C₆₀ aryl group”, or a “substituted phenyl group” having two substituents, each of which is a “C₆-C₆₀ aryl group.”

The symbols * *′ and *″ as used herein, unless defined otherwise, each refer to a binding site to a neighboring atom in a corresponding formula or moiety.

In the specification, the terms “x-axis,” “y-axis,” and “z-axis” are not limited to three axes in an orthogonal coordinate system (e.g., a Cartesian coordinate system), and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, quantum dots according to embodiments will be described in detail with reference to the Preparation Examples and the Examples.

### Preparation Example 1 (CuInGaS/CuAIS₂ Quantum Dot A)

### Synthesis Example 1 (Synthesis of CuInGaS core)

0.4 mmol of Cul (first-first precursor), 0.5 mmol of Gal₃ (first-second precursor), 0.4 mmol of InIs (first-fourth precursor), 10 mL of oleylamine (first solvent), 1.7 mmol of trioctylphosphine oxide (TOPO), and 10 mL of trioctylamine (TOA) were mixed. 2 mL of 1 M sulfur-containing oleylamine (S-oleylamine) (first-third precursor) was added to the reaction mixture, and the reaction mixture was heated to 230° C. After 10 minutes, the reaction mixture was cooled and purified to synthesize a CuInGaS core. The energy band gap of the core was in a range of about 1.0 eV to about 3.0 eV. For example, the energy band gap of the core was about 2.0 eV. As a result of analyzing the amounts of elements included in the core by using inductively coupled plasma (ICP), Equations 1-1′ to 1-3′ were satisfied:

$$1 \leq {In}_{C} / {Cu}_{C} \leq 10 \qquad [ Equation 1 - {1}^{′} ]$$

$$1 \leq {Ga}_{C} / {Cu}_{C} \leq 10 \qquad [ Equation 1 - {2}^{′} ]$$

$$0.05 \leq {In}_{C} / {Ga}_{C} \leq 20 \qquad [ Equation 1 - {3}^{′} ]$$

In Equations 1-1′ to 1-3′,

In_{c} indicates the number of moles of In included in the core,

Cu_{c} indicates the number of moles of Cu included in the core, and

Ga_{c} indicates the number of moles of Ga included in the core.

Synthesis Example 2 (Synthesis of CuAIS₂ shell)

Oleylamine was subjected to vacuum treatment at 120° C. to prepare a solvent (second solvent) substantially free of moisture. The CuInGaS core synthesized in Synthesis Example 1, 0.4 mmol of CuCl₃ (second-first precursor), 1.6 mmol of aluminum isopropoxide (AI(O—i—Pr)₃) (second-second precursor), and 0.8 L of 1 M S-oleylamine (second-third precursor) were injected into the oleylamine, and the temperature was raised to 280° C. After 20 minutes, the reaction mixture was cooled and purified to synthesize a shell surrounding the core, thereby preparing a quantum dot. The energy band gap of the prepared quantum dot was in a range of about 3.0 eV to about 5.0 eV. For example, the energy band gap of the prepared quantum dot was about 3.5 eV.

### Preparation Example 2 (CuInGaS/CuAIS₂/AlOₓ Quantum Dot B)

After forming the shell synthesized according to the Synthesis Example 2 on the core synthesized in the Synthesis Example 1, the shell was exposed to the air to synthesize a surface layer (AIOₓ) surrounding the shell, thereby preparing a quantum dot including a core, shell, and a surface layer. The energy band gap of the prepared quantum dot was in a range of about 5.0 eV to about 8.0 eV. For example, the energy band gap of the prepared quantum dot was about 7.0 eV.

### Comparative Preparation Examples

Quantum dots shown in Table 1 were prepared.

TABLE 1

| No. | Core | Shell | Surface layer |
|---|---|---|---|
| Quantum Dot CE1 | AgInGaS | GaS | — |
| Quantum Dot CE2 | AgInGaS | ZnS | — |
| Quantum Dot CE3 | CuInGaS | ZnS | — |
| Quantum Dot CE4 | CuInGaS | ZnS | AlOₓ |
| Quantum Dot CE5 | CuInGaS | HgS | — |
| Quantum Dot CE6 | CuInGaS | HgS | AlOₓ |
| Quantum Dot CE7 | CuInGaSeS | CuAlS₂ | — |
| Quantum Dot CE8 | CuInGaSeS | CuAlS₂ | AlOₓ |

### Example 1

After mixing PMMA in CH₂Cl₂ solution and Quantum Dot A (4 wt % relative to PMMA), the mixture was applied onto a quartz substrate by using a spin coater. Heat treatment was performed thereon in an oven at 80° C., followed by cooling at room temperature, thereby preparing a film having a thickness of 40 nm.

### Example 2

A film was prepared in the same manner as in the Example 1, except that Quantum Dot B (CuInGaS/CuAIS₂/AIOₓ) according to the Preparation Example 2 was used instead of Quantum Dot A (CuInGaS/CuAIS₂) according to the Preparation Example 1.

### Comparative Examples 1 to 8

Respective films were prepared in the same manner as in the Example 1, except that the quantum dots shown in Table 1 were each used instead of Quantum Dot A.

### Evaluation Example 1 (Evaluation according to quantum dot type)

### Evaluation Example 1-1

The photoluminescence (PL) spectrum of each of the films according to the Example 1, the Example 2, and the Comparative Examples 1 to 8 was measured by using a Quantaurus-QY absolute PL quantum yield spectrometer manufactured by Hamamatsu Company (equipped with a xenon light source, a monochromator, a photonic multichannel analyzer, and an integrating sphere, and using a PLQY measurement software (Hamamatsu Photonics, Ltd., Shizuoka, Japan)). During the measurement, a spectrum measured by scanning blue light having a wavelength in a range of 450 nm to 460 nm at 100,000 nit was taken to obtain the maximum emission wavelength (emission peak wavelength) and emission FWHM of the quantum dot included in each film, and the results are summarized in Table 2.

The PLOY measured at the maximum emission wavelength of each film was taken to obtain the PLOY of the quantum dot included in each film, and the results are also summarized in Table 2.

TABLE 2

| | | Maximum | | |
|---|---|---|---|---|
| | | emission | | |
| | Film composition | wavelength | FWHM | PLQY |
| No. | (4 wt % in PMMA) | (nm) | (nm) | (%) |
| Example 1 | Quantum Dot A | 621 | 65 | 79 |
| | (CuInGaS/CuAlS₂) | | | |
| Example 2 | Quantum Dot B | 626 | 65 | 85 |
| | (CuInGaS/CuAlS₂/AlOₓ) | | | |
| Comparative | Quantum Dot CE1 | 532 | 39 | 79 |
| Example 1 | (AgInGaS/GaS) | | | |
| Comparative | Quantum Dot CE2 | 531 | 86 | 50 |
| Example 2 | (AgInGaS/ZnS) | | | |
| Comparative | Quantum Dot CE3 | 622 | 105 | 85 |
| Example 3 | (CuInGaS/ZnS) | | | |
| Comparative | Quantum Dot CE4 | 626 | 98 | 68 |
| Example 4 | (CuInGaS/ZnS/AlOₓ) | | | |
| Comparative | Quantum Dot CE5 | 631 | 87 | 64 |
| Example 5 | (CuInGaS/HgS) | | | |
| Comparative | Quantum Dot CE6 | 628 | 79 | 59 |
| Example 6 | (CuInGaS/HgS/AlOₓ) | | | |
| Comparative | Quantum Dot CE7 | 636 | 59 | 67 |
| Example 7 | (CuInGaSeS/CuAlS₂) | | | |
| Comparative | Quantum Dot CE8 | 638 | 61 | 70 |
| Example 8 | (CuInGaSeS/CuAlS₂/ | | | |
| | AlOₓ | | | |

As shown in Table 2, it may be confirmed that the quantum dots according to the Examples 1 and 2 have a maximum emission wavelength in the red light region and simultaneously have a small FWHM and a large PLOY. Accordingly, it may be confirmed that the quantum dots according to the Examples 1 and 2 exhibit excellent color purity and high efficiency. It may be also confirmed that the quantum dot of the Example 2, which has a surface layer of AlOₓ, has an excellent PLOY.

### Evaluation Example 1-2

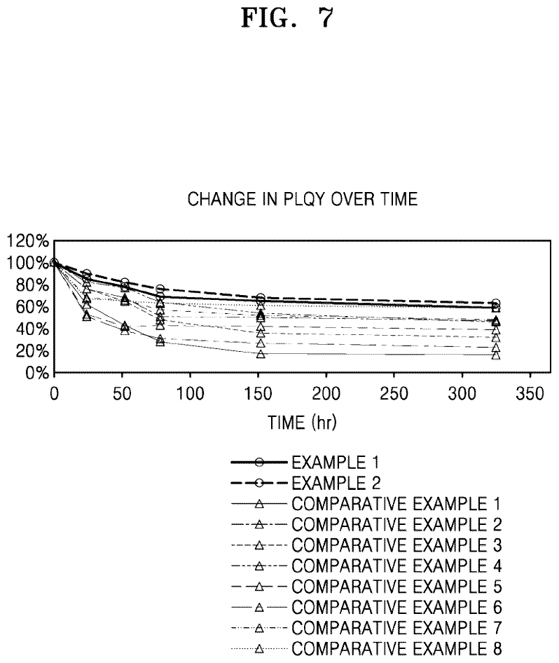

For each of the films according to the Example 1, the Example 2, and the Comparative Examples 1 to 8, the initially measured PLOY was set to 100%, and the degree of change in PLOY of each film was measured over 325 hours. The results are summarized in FIG. 7 and Table 3.

TABLE 3

| | Film composition | PLQY over time relative to initial PLQY | | | | | |
|---|---|---|---|---|---|---|---|
| No. | (4 wt % in PMMA) | 0 hr | 24 hr | 52 hr | 78 hr | 152 hr | 325 hr |
| Example 1 | Quantum Dot A | 100% | 85% | 78% | 69% | 65% | 59% |
| | (CuInGaS/CuAlS₂) | | | | | | |
| Example 2 | Quantum Dot B | 100% | 90% | 82% | 76% | 68% | 63% |
| | (CuInGaS/CuAlS₂/ | | | | | | |
| | AlOₓ) | | | | | | |
| Comparative | Quantum Dot CE1 | 100% | 62% | 43% | 28% | 17% | 16% |
| Example 1 | (AgInGaS/GaS) | | | | | | |
| Comparative | Quantum Dot CE2 | 100% | 76% | 68% | 51% | 50% | 47% |
| Example 2 | (AgInGaS/ZnS) | | | | | | |
| Comparative | Quantum Dot CE3 | 100% | 76% | 65% | 48% | 36% | 32% |
| Example 3 | (CuInGaS/ZnS) | | | | | | |
| Comparative | Quantum Dot CE4 | 100% | 82% | 77% | 64% | 54% | 46% |
| Example 4 | (CuInGaS/ZnS/ | | | | | | |
| | AlOₓ) | | | | | | |
| Comparative | Quantum Dot CE5 | 100% | 53% | 42% | 43% | 42% | 39% |
| Example 5 | (CuInGaS/HgS) | | | | | | |
| Comparative | Quantum Dot CE6 | 100% | 51% | 38% | 31% | 27% | 23% |
| Example 6 | (CuInGaS/HgS/ | | | | | | |
| | AlOₓ) | | | | | | |
| Comparative | Quantum Dot CE7 | 100% | 68% | 66% | 57% | 52% | 48% |
| Example 7 | (CuInGaSeS/ | | | | | | |
| | CuAlS₂) | | | | | | |
| Comparative | Quantum Dot CE8 | 100% | 67% | 65% | 63% | 61% | 59% |
| Example 8 | (CuInGaSeS/ | | | | | | |
| | CuAlS₂/AlOₓ) | | | | | | |

As shown in FIG. 7 and Table 3, it may be confirmed that the quantum dots according to the Examples 1 and 2 have an excellent PLQY even after a long period of time, compared to the quantum dots according to the Comparative Examples 1 to 8. Accordingly, it may be confirmed that the quantum dots according to the Examples 1 and 2 exhibit high stability. It may be also confirmed that the quantum dot of the Example 2, which has a surface layer of AIOₓ, has excellent stability.

Referring to Tables 2 and 3 together, a quantum dot including a combination of CuInGaS as a core and CuAIS₂ as a shell, such that a lattice mismatch between the core and the shell is relatively small, may simultaneously exhibit higher color purity, higher efficiency, and higher stability than a quantum dot including a different core and/or shell in a specific emission color region.

### Preparation Example 3 (AI(O—i—Pr)₃ input amount changed)

A core was synthesized according to the Synthesis Example 1. Quantum Dots B1 to B6 each including a core, a shell, and a surface layer were prepared in the same manner as in the Preparation Example 2 by forming a shell on the core and exposing the shell to the air to synthesize a surface layer (AlOₓ) surrounding the shell, except that the input amount of AI(O—i—Pr)₃ in the Synthesis Example 2 was changed as shown in Table 4.

TABLE 4

| | | | | Al(O-i-Pr)₃ | Shell |
|---|---|---|---|---|---|
| | Quantum dot composition | | | input | thickness + |
| | | | Surface | amount | surface layer |
| No. | Core | Shell | layer | (mmol) | thickness (nm) |
| Quantum | CuInGaS | CuAlS₂ | AlOₓ | 0.05 | 0.1 |
| Dot B1 | | | | | |
| Quantum | | | | 0.1 | 0.3 |
| Dot B2 | | | | | |
| Quantum | | | | 0.9 | 1.2 |
| Dot B3 | | | | | |
| Quantum | | | | 1.6 | 1.6 |
| Dot B4 | | | | | |
| Quantum | | | | 5.0 | 2.8 |
| Dot B5 | | | | | |
| Quantum | | | | 7.0 | 3.3 |
| Dot B6 | | | | | |

Referring to Table 4, it may be confirmed that the range of the sum of the thicknesses of a shell and a surface layer of a quantum dot of CuInGaS/CuAIS₂/AlOₓ (core/shell/surface layer) changes depending on the input amount of AI(O—i—Pr)₃. It may be confirmed that each of Quantum Dots B1 to B6 satisfies Equation 2:

$$0.1 nm \leq {T}_{S} + {T}_{L} \leq 4.0 nm \qquad [ Equation 2 ]$$

In Equation 2,

T_{S} indicates the thickness of the shell, and

T_{L} indicates the thickness of the surface layer.

### Evaluation Example 2 (Element amount analysis)

The amounts of elements included in each of Quantum Dots B1 to B6 according to the Preparation Example 3 was analyzed by using ICP, and the results are shown in Table 5.

TABLE 5

| | Composition in quantum dot (molar ratio) | | | | | (A_{III} + B_{III})/ |
|---|---|---|---|---|---|---|
| No. | Cu | In | Ga | Al | S | (X_{III} +Y_{III}) |
| Quantum | 0.322 | 0.155 | 0.141 | 0.009 | 0.373 | 0.03 |
| Dot B1 | | | | | | |
| Quantum | 0.392 | 0.085 | 0.105 | 0.018 | 0.400 | 0.09 |
| Dot B2 | | | | | | |
| Quantum | 0.392 | 0.065 | 0.075 | 0.115 | 0.353 | 0.82 |
| Dot B3 | | | | | | |
| Quantum | 0.293 | 0.078 | 0.071 | 0.271 | 0.287 | 1.82 |
| Dot B4 | | | | | | |
| Quantum | 0.253 | 0.034 | 0.032 | 0.415 | 0.266 | 6.29 |
| Dot B5 | | | | | | |
| Quantum | 0.204 | 0.019 | 0.026 | 0.483 | 0.268 | 10.7 |
| Dot B6 | | | | | | |

Referring to Table 5, the molar ratio of each element included in a quantum dot may be confirmed. In this regard, since each of Quantum Dots B1 to B6 includes a CuInGaS core, a CuAIS₂ shell, and an AlOₓ surface layer, it may be confirmed that In and Ga as Group III elements (i.e. the first-second Group III element and the first-fourth Group III element) are included in the core, and Al as a Group III element (i.e. the second-second Group III element and the third-first Group III element) is included in the shell and the surface layer. For example, the sum of the number of moles of the second-second Group III element included in the shell and the number of moles of the third-first Group III element included in the surface layer is equal to the total number of moles of Al included in the quantum dot, and the number of moles of the Group II element (i.e. the first-second Group II element and the first-fourth Group II element) included in the core is equal to the sum of the number of moles of In and the number of moles of Ga included in the quantum dot. In case that the number of moles of the second-second Group II element included in the shell (i.e., Al) is expressed as A_{III}, the number of moles of the third-first Group III element included in the surface layer (i.e., Al) is expressed as B_{III}, the number of moles of one of the Group II elements (e.g. the first-second Group II element) included in the core (e.g., In) is expressed as X_{III}, and the number of moles of another one of the Group II elements (e.g. the first-fourth Group II element) included in the core (e.g., Ga) is expressed as Y_{III}, it may be confirmed that each of Quantum Dots B2 to B5 satisfies Equations 1-3′ and 3-1 to 3-3:

$$0.8 \leq {X}_{III} / {Y}_{III} \leq 1.2 \qquad [ Equation 1 - {3}^{′} ]$$

$$0.05 \leq [ ( {A}_{III} + {B}_{III} ) / ( {X}_{III} + {Y}_{III} ) ] \leq 8. \qquad [ Equation 3 - 1 ]$$

$$0.1 \leq ( {A}_{III} + {B}_{III} ) / {X}_{III} \leq 15 \qquad [ Equation 3 - 2 ]$$

$$0.1 \leq ( {A}_{III} + {B}_{III} ) / {Y}_{III} \leq 15 . \qquad [ Equation 3 - 3 ]$$

### Examples 3 to 8

Respective films were prepared in the same manner as in the Example 1, except that the quantum dots according to the Preparation Example 3 were each used instead of Quantum Dot A.

### Evaluation Example 3-1

The maximum emission wavelength (emission peak wavelength), emission FWHM, and PLQY of each of the films according to the Examples 3 to 8 and the Comparative Examples 1 to 8 were obtained in the same manner as in the Evaluation Example 1-1. Also, the initially measured PLQY was set to 100%, and the degree of change in PLQY of each of the films after 325 hours was measured in the same manner as in the Evaluation Example 1-2. The results are summarized in Table 6.

### Evaluation Example 3-2

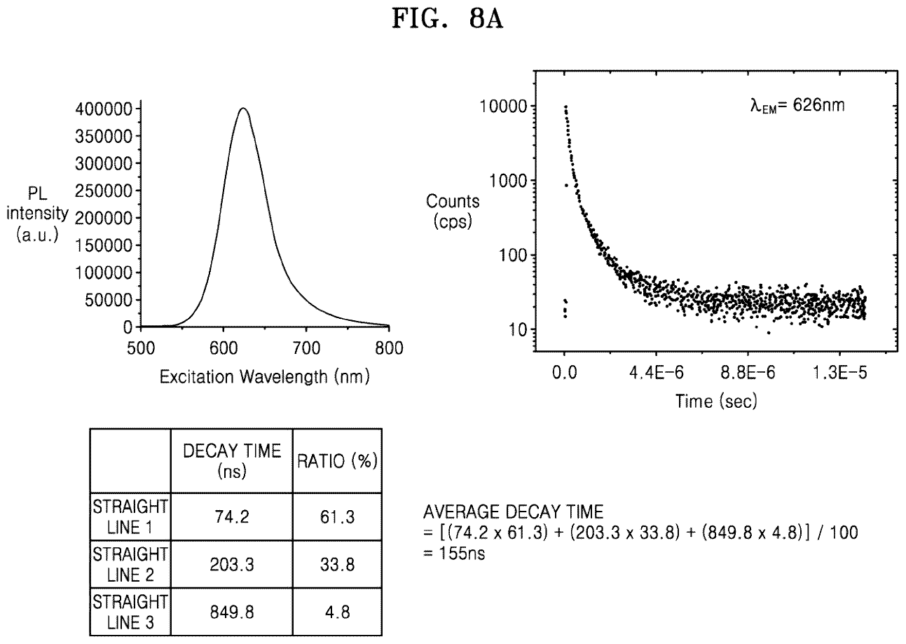

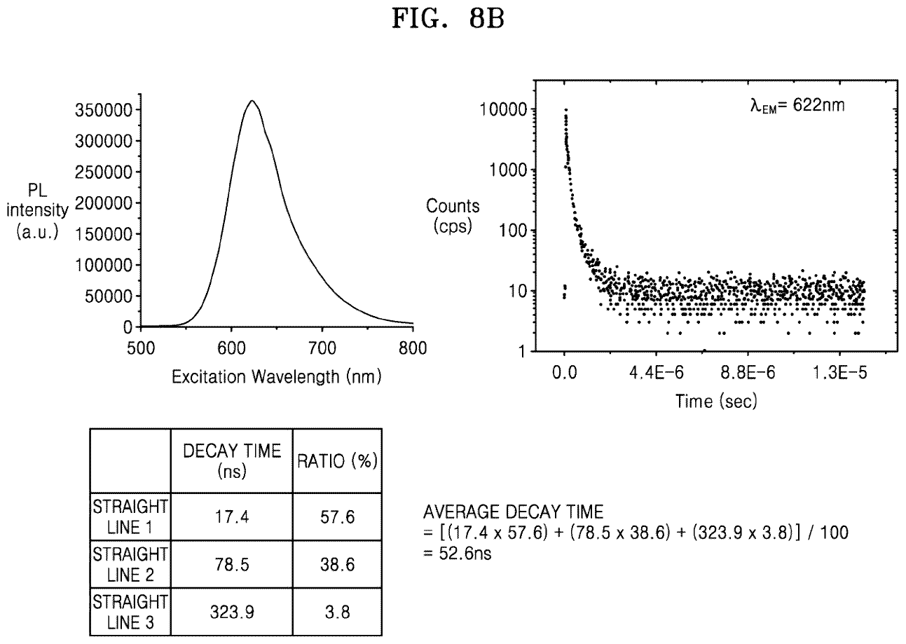

For each of the films according to the Examples 3 to 8 and the Comparative Examples 1 to 8, the number of photons emitted at the wavelength of the main peak in the PL spectrum according to the Evaluation Example 3-1 was repeatedly measured based on time-correlated single photon counting (TCSPC) over time, to obtain a time-resolved PL (TRPL) curve sufficient for fitting. Three or more straight lines approximating exponential decay functions, which represent respective TRPL curves, were obtained, and the decay time for each straight line was calculated as the time taken until the number of photons emitted became half of the number of photons initially emitted. The average of the three or more decay times obtained was calculated to obtain the average decay time, and the results are summarized in Table 6. For example, the process of calculating the average decay time of the Example 6 using Quantum Dot B4 is shown in FIG. 8A, and the process of calculating the average decay time of the Comparative Example 3 using Quantum Dot CE3 is shown in FIG. 8B.

TABLE 6

| | | | | | PLQY | | |
|---|---|---|---|---|---|---|---|
| | | | | | after | | |
| | | | | | 325 hr | | |
| | Film | Maximum | | | relative | | Average |
| | composition | emission | | | to | | decay |
| | (4 wt % in | wavelength | FWHM | PLQY | initial | Al_{Q}/ | time |
| No. | PMMA) | (nm) | (nm) | (%) | PLQY | (In_{Q} + Ga_{Q} | (ns) |
| Example 3 | Quantum | 621 | 72 | 53 | 35% | 0.03 | 98.6 |
| | Dot B1 | | | | | | |
| Example 4 | Quantum | 623 | 69 | 76 | 52% | 0.09 | 113.2 |
| | Dot B2 | | | | | | |
| Example 5 | Quantum | 621 | 66 | 75 | 58% | 0.82 | 149.6 |
| | Dot B3 | | | | | | |
| Example 6 | Quantum | 626 | 65 | 85 | 63% | 1.82 | 155 |
| | Dot B4 | | | | | | |
| Example 7 | Quantum | 621 | 66 | 78 | 67% | 6.29 | 132.7 |
| | Dot B5 | | | | | | |
| Example 8 | Quantum | 619 | 94 | 65 | 82% | 10.7 | 63.7 |
| | Dot B6 | | | | | | |
| Comparative | Quantum | 532 | 39 | 79 | 16% | — | 46.3 |
| Example | Dot CE1 | | | | | | |
| 1 | (AgInGaS/ | | | | | | |
| | GaS) | | | | | | |
| Comparative | Quantum | 531 | 86 | 50 | 47% | — | 65.3 |
| Example | Dot CE2 | | | | | | |
| 2 | (AgInGaS/ | | | | | | |
| | ZnS) | | | | | | |
| Comparative | Quantum | 622 | 105 | 85 | 32% | — | 52.6 |
| Example | Dot CE3 | | | | | | |
| 3 | (CuInGaS/ | | | | | | |
| | ZnS) | | | | | | |
| Comparative | Quantum | 626 | 98 | 68 | 46% | 0.05 | 87.6 |
| Example | Dot CE4 | | | | | | |
| 4 | (CuInGaS/ | | | | | | |
| | ZnS/AlOₓ) | | | | | | |
| Comparative | Quantum | 631 | 87 | 64 | 39% | — | 67.8 |
| Example | Dot CE5 | | | | | | |
| 5 | (CuInGaS/ | | | | | | |
| | HgS) | | | | | | |
| Comparative | Quantum | 628 | 79 | 59 | 23% | 0.11 | 95.1 |
| Example | Dot CE6 | | | | | | |
| 6 | (CuInGaS/ | | | | | | |
| | HgS/AlOₓ) | | | | | | |
| Comparative | Quantum | 636 | 59 | 67 | 48% | — | 110.2 |
| Example | Dot CE7 | | | | | | |
| 7 | (CuInGaSeS/ | | | | | | |
| | CuAlS₂) | | | | | | |
| Comparative | Quantum | 638 | 61 | 70 | 59% | 0.09 | 132.1 |
| Example | Dot CE8 | | | | | | |
| 8 | (CuInGaSeS/ | | | | | | |
| | CuAlS₂/ | | | | | | |
| | AlOₓ) | | | | | | |

In Table 6, AIQ indicates the number of moles of Al included in a quantum dot, InQ indicates the number of moles of In included in a quantum dot, and GaQ indicates the number of moles of Ga included in a quantum dot. Accordingly, in the quantum dots according to the Examples 3 to 8, which have a structure of CuInGaS /CuAIS₂/AIOₓ, a value of AIQ/(InQ+GaQ) is equal to a value of [(A_{III}+B_{III})/(X_{III}+Y_{III})] of Equation 3-1.

Referring to Table 6, it may be confirmed that Quantum Dot CE1, which has an amorphous crystal structure, has a significantly low PLQY after a long period of time, so that the stability thereof is not secured. It may be confirmed that Quantum Dot CE2, which has a large lattice mismatch between the core and the shell, has a large emission FWHM and a low PLQY due to defects occurring at the interface between the core and the shell. It may be also confirmed that each of Quantum Dots CE3 to CE8 has at least one of a large emission FWHM, a low PLQY, and a significantly low PLQY retention rate after a long period of time. In contrast, it may be confirmed that, in the Examples 3 to 8 each using a quantum dot of CuInGaS/CuAIS₂/AlOₓ (core/shell/surface layer) with a relatively small lattice mismatch between the core and the shell, the quantum dots have equal or improved emission FWHM, PLQY, and/or average decay time compared to those of the Comparative Examples 1 to 8, or maintain a high PLQY even after a long period of time. For example, it may be confirmed that, in case that a value of AIQ/(InQ+GaQ) is in a range of about 0.05 to about 8.0 (i.e., in case that Equation 3-1 is satisfied), a quantum dot has a small emission FWHM of less than or equal to about 70 nm and a high PLQY of greater than or equal to about 75%, and simultaneously has high stability and a long average decay time.

By including the core described above, the quantum dot may have an excellent blue light absorption rate. By reducing a lattice mismatch between the core and the shell to reduce surface defects, the quantum dot may have an improved PLQY, and may simultaneously exhibit a narrow emission FWHM and a relatively long decay time of longer than or equal to about 100 ns. By including the surface layer described above, the quantum dot may have further improvement in the characteristics described above, and may exhibit a high PLQY retention rate, thereby having high stability.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A quantum dot comprising:
a quaternary core including a first-first Group I element, a first-second Group II element, and a first-third Group VI element and not including Se; and
a ternary shell surrounding at least a portion of the quaternary core.

2. The quantum dot of claim 1, wherein
the quaternary core further includes a first-fourth Group II element, and
the first-second Group II element and the first-fourth Group II element in the quaternary core are different from each other.

3. The quantum dot of claim 1, wherein the quaternary core does not include Ag.

4. The quantum dot of claim 1, wherein the ternary shell includes a second-first Group I element, a second-second Group II element, and a second-third Group VI element.

5. The quantum dot of claim 4, wherein the first-first Group I element of the quaternary core and the second-first Group I element of the ternary shell are identical to each other.

6. The quantum dot of claim 4, wherein the first-second Group III element of the quaternary core and the second-second Group II element of the ternary shell are different from each other.

7. The quantum dot of claim 1, wherein the ternary shell includes Al.

8. The quantum dot of claim 1, wherein the quantum dot absorbs blue light and emit light having a wavelength in a range of about 520 nm to about 750 nm.

9. The quantum dot of claim 1, further comprising:
a surface layer surrounding at least a portion of the ternary shell.

10. The quantum dot of claim 9, wherein the surface layer is a binary layer including a third-first Group II element and a third-second Group VI element.

11. The quantum dot of claim 9, wherein the surface layer includes an oxide of a third-first Group II element.

12. The quantum dot of claim 9, wherein a sum of a thickness of the ternary shell and a thickness of the surface layer is in a range of about 0.1 nm to about 4.0 nm.

13. The quantum dot of claim 10, wherein the second-second Group III element in the ternary shell and the third-first Group III element in the surface layer are identical to each other.

14. The quantum dot of claim 13, wherein a value obtained by dividing a sum of a number of moles of the second-second Group II element included in the ternary shell and a number of moles of the third-first Group II element included in the surface layer by a number of moles of the first-second Group II element included in the quaternary core is in a range of about 0.05 to about 8.0.

15. A method of preparing a quantum dot, the method comprising:
mixing a first-first precursor including a first-first Group I element, a first-second precursor including a first-second Group III element, a first-third precursor including a first-third Group VI element, and a first solvent to obtain a mixture;
heating the mixture to a first temperature to obtain a quaternary core;
mixing the quaternary core with a second-first precursor including a second-first Group I element, a second-second precursor including a second-second Group III element, a second-third precursor including a second-third Group VI element, and a second solvent; and
heating the quaternary core and a shell surrounding at least a portion of the quaternary core to a second temperature to obtain a ternary shell,
wherein the first-second Group II element included in the first-second precursor does not include Se.

16. The method of claim 15, further comprising:
exposing the ternary shell to air.

17. The method of claim 15, wherein a number of moles of the second-second precursor is in a range of about 0.1 mmol to about 5.0 mmol.

18. A light-emitting device comprising:
a first electrode;
a second electrode facing the first electrode;
an interlayer arranged between the first electrode and the second electrode and including an emission layer; and
the quantum dot of claim 1.

19. An electronic apparatus comprising:
the light-emitting device of claim 18; and
a thin-film transistor electrically connected to the light-emitting device.

20. Electronic equipment comprising the electronic apparatus of claim 19, wherein the electronic equipment is one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, and a signboard.
